(19) United States
(12) Patent Application Publication
(10) Pub. No.: US 2026/0293131 A1
(43) Pub. Date: Sep. 24, 2026

(54) MEMORY DEVICE

(71) Applicant: Kioxia Corporation, Tokyo (JP)

(72) Inventors: Masakazu KATAOKA, Yokkaichi (JP); Manabu SAKAMOTO, Yokkaichi (JP); Masato CHINO, Yokkaichi (JP); Takaaki KONDO, Yokkaichi (JP); Kinya TOGAWA, Yokkaichi (JP)

(73) Assignee: Kioxia Corporation, Tokyo (JP)

(21) Appl. No.: 19/288,317

(22) Filed: Aug. 1, 2025

(30) Foreign Application Priority Data
Mar. 19, 2025 (JP) 2025-045366

(51) Int. Cl. H10B 43/27; H01L 23/528; H10B 43/10; H10B 43/35; H10D 30/01

(52) U.S. Cl. CPC H10B 43/27; H10B 43/10; H10B 43/35; H10W 20/435; H10D 30/0413

(57) ABSTRACT

A memory device according to one embodiment includes conductive layers, a memory pillar, an insulating film, and contact plugs. The conductive layers are arranged over first and second tiers. The conductive layer includes a first high dielectric film. The insulating film has step differences along a staircase shape formed by first conductive layers included in the first tier. The insulating film is provided thicker than the first conductive layer. The insulating film includes a second high dielectric film that is a same in material as the first high dielectric film. The contact plugs include first contact plugs respectively connected to first conductive layers. The first contact plug includes first and second sub-contact plugs. The first sub-contact plug has a portion that passes through the first tier including the insulating film in the first tier. The second sub-contact plug has a portion that passes through the second tier.

### CROSS-REFERENCE TO RELATED APPLICATION

This application is based upon and claims the benefit of priority from Japanese Patent Application No. 2025-045366, filed Mar. 19, 2025, the entire contents of which are incorporated herein by reference.

### FIELD

Embodiments described herein relate generally to a memory device.

### BACKGROUND

A NAND flash memory capable of storing data in a nonvolatile manner is known.

### BRIEF DESCRIPTION OF DRAWINGS

FIG. 1 is a block diagram showing an example of an overall configuration of a memory system including a memory device according to a first embodiment.

FIG. 2 is a circuit diagram showing an example of a circuit configuration of a memory cell array included in the memory device according to the first embodiment.

FIG. 3 is a plan view showing an example of a planar layout of the memory cell array included in the memory device according to the first embodiment.

FIG. 4 is a cross-sectional view showing an example of a cross-sectional structure of a memory area of the memory cell array included in the memory device according to the first embodiment.

FIG. 5 is a cross-sectional view taken along line V-V of FIG. 4, showing an example of a cross-sectional structure of a memory pillar included in the memory device according to the first embodiment.

FIGS. 6, 7, and 8 are cross-sectional views showing examples of detailed cross-sectional structures of a contact area of the memory cell array included in the memory device according to the first embodiment.

FIG. 9 is a cross-sectional view taken along line IX-IX of FIG. 8, showing an example of a cross-sectional structure of a contact plug included in the memory device according to the first embodiment.

FIG. 10 is a cross-sectional view taken along line X-X of FIG. 8, showing an example of a cross-sectional structure of the contact plug included in the memory device according to the first embodiment.

FIG. 11 is a cross-sectional view taken along line XI-XI of FIG. 8, showing an example of a cross-sectional structure of the contact plug included in the memory device according to the first embodiment.

FIG. 12 is a flowchart showing an example of a method of manufacturing the memory device according to the first embodiment.

FIGS. 13, 14, 15, 16, 17, 18, 19, 20, 21, 22, 23, 24, 25, and 26 are cross-sectional views showing examples of cross-sectional structures in the manufacturing process of the memory device according to the first embodiment.

FIGS. 27, 28, 29, 30, and 31 are cross-sectional views showing examples of cross-sectional structures in the manufacturing process of the memory device in step ST107.

FIGS. 32, 33, 34, and 35 are cross-sectional views showing examples of cross-sectional structures in the manufacturing process of the memory device in step ST113.

FIGS. 36 and 37 are cross-sectional views showing examples of cross-sectional structures in the manufacturing process of the memory device in step ST115.

FIG. 38 is a cross-sectional view showing an example of a cross-sectional structure of a contact area of a memory cell array in a first modification example of the first embodiment.

FIGS. 39 and 40 are cross-sectional views showing examples of cross-sectional structures in the manufacturing process of a memory device in a second modification example of the first embodiment.

FIG. 41 is a cross-sectional view showing an example of a cross-sectional structure of a contact area of a memory cell array in the second modification example of the first embodiment.

FIGS. 42 and 43 are cross-sectional views showing examples of cross-sectional structures in the manufacturing process of a memory device in a third modification example of the first embodiment.

FIG. 44 is a cross-sectional view showing an example of a cross-sectional structure of a contact area of a memory cell array in the third modification example of the first embodiment.

FIG. 45 is a cross-sectional view showing an example of a cross-sectional structure of a contact area of a memory cell array in a fourth modification example of the first embodiment.

FIG. 46 is a cross-sectional view showing an example of a cross-sectional structure of a memory area of a memory cell array included in a memory device according to a second embodiment.

FIG. 47 is a cross-sectional view showing an example of a cross-sectional structure of a contact area of the memory cell array included in the memory device according to the second embodiment.

FIG. 48 is a flowchart showing an example of a method of manufacturing the memory device according to the second embodiment.

FIGS. 49, 50, 51, 52, 53, 54, 55, and 56 are cross-sectional views showing examples of cross-sectional structures in the manufacturing process of the memory device according to the second embodiment.

FIG. 57 is a cross-sectional view showing an example of a cross-sectional structure of a contact area of a memory cell array included in a memory device according to a third embodiment.

FIG. 58 is a flowchart showing an example of a method of manufacturing the memory device according to the third embodiment.

FIGS. 59, 60, 61, and 62 are cross-sectional views showing examples of cross-sectional structures in the manufacturing process of the memory device according to the third embodiment.

FIG. 63 is a cross-sectional view showing an example of a cross-sectional structure of a contact area of a memory cell array included in a memory device according to a fourth embodiment.

FIG. 64 is a flowchart showing an example of a method of manufacturing the memory device according to the fourth embodiment.

FIGS. 65, 66, 67, 68, 69, 70, 71, and 72 are cross-sectional views showing examples of cross-sectional structures in the manufacturing process of the memory device according to the fourth embodiment.

FIG. 73 is cross-sectional views showing examples of cross-sectional structures of the vicinity of a boundary of a layer stack in the manufacturing process of a memory device according to a first comparative example.

FIG. 74 is cross-sectional views showing examples of cross-sectional structures of the vicinity of a boundary of a layer stack in the manufacturing process of the memory device according to the fourth embodiment.

FIG. 75 is a plan view showing an example of a planar layout of a memory cell array included in a memory device according to a fifth embodiment.

FIG. 76 is a cross-sectional view showing an example of a cross-sectional structure of a memory area of the memory cell array included in the memory device according to the fifth embodiment.

FIG. 77 is a cross-sectional view showing an example of a cross-sectional structure of a contact area of the memory cell array included in the memory device according to the fifth embodiment.

FIG. 78 is a flowchart showing an example of a method of manufacturing the memory device according to the fifth embodiment.

FIGS. 79, 80, 81, 82, and 83 are cross-sectional views showing examples of cross-sectional structures in the manufacturing process of the memory device according to the fifth embodiment.

FIGS. 84, 85, 86, 87, 88, and 89 are cross-sectional views showing examples of cross-sectional structures in the manufacturing process of a memory device according to a second comparative example.

FIG. 90 is a cross-sectional view showing an example of a cross-sectional structure of the memory area of the memory cell array included in a memory device according to a modification example of the fifth embodiment.

FIG. 91 is a cross-sectional view showing an example of a cross-sectional structure that includes a memory pillar and is located in the vicinity of a boundary.

FIG. 92 is a cross-sectional view showing an example of a cross-sectional structure that includes contact plugs and is located in the vicinity of a boundary.

### DETAILED DESCRIPTION

In general, according to one embodiment, a memory device includes a plurality of conductive layers, a memory pillar, an insulating film, and a plurality of contact plugs. The plurality of conductive layers are provided in a first area and a second area arranged in a first direction. The conductive layers are provided apart from each other in a second direction intersecting the first direction. The conductive layers are arranged over a plurality of tiers including a first tier and a second tier above the first tier. Each of the conductive layers has a terrace portion that does not overlap a conductive layer arranged in an upper layer in a same tier among the conductive layers in the second area. Each of the conductive layers includes a first high dielectric film.

The memory pillar is provided to pass through the conductive layers in the second direction in the first area. A portion where the memory pillar and one of the conductive layers intersect each other functions as a memory cell. An upper surface of the insulating film has step differences along a staircase shape formed by terrace portions of a plurality of first conductive layers included in the first tier among the conductive layers. The insulating film is provided thicker than each of the first conductive layers. The insulating film includes a second high dielectric film that is a same in material as the first high dielectric film. The plurality of contact plugs are respectively connected to the terrace portions included in the conductive layers in the second area. The contact plugs include a plurality of first contact plugs respectively connected to the first conductive layers. Each of the first contact plugs includes a first sub-contact plug and a second sub-contact plug. The first sub-contact plug has a portion that passes through the first tier including the insulating film in the first tier. The second sub-contact plug has a portion that passes through the second tier.

Hereinbelow, embodiments are described with reference to the drawings. Each embodiment gives examples of a device and a method for embodying the technical idea of the invention. The drawings are schematic or conceptual ones. The dimensions, ratios, etc. of drawings are not necessarily the same as the actual ones. The illustration of the configuration is omitted as appropriate. The hatching added to the plan view is not necessarily related to the material or characteristics of the component. In the present specification, components having substantially the same function and configuration are marked with the same reference signs. The numerals, characters, etc. added to reference signs are referred to by the same reference signs, and are used to distinguish between similar elements.

### <1> First Embodiment

A memory device 1 according to a first embodiment is a kind of three-dimensional stacked NAND flash memory having a structure in which memory cell transistors MT are three-dimensionally stacked above a semiconductor substrate. Details of the memory device 1 according to the first embodiment will now be described.

### <1-1> Configuration

First, a configuration of the memory device 1 according to the first embodiment is described.

### <1-1-1> Overall Configuration of the Memory Device 1

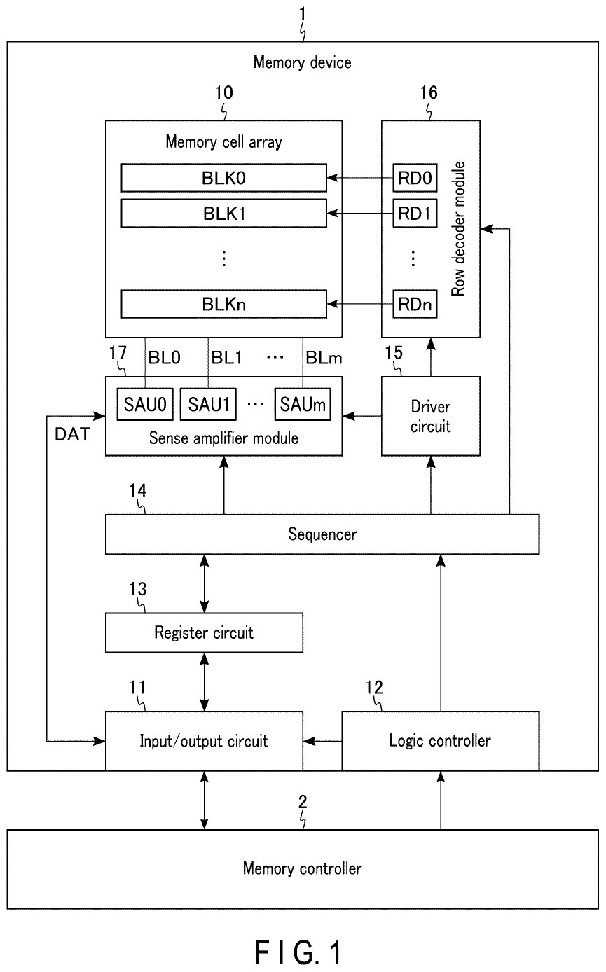

FIG. 1 is a block diagram showing an example of an overall configuration of a memory system including the memory device 1 according to the first embodiment. As shown in FIG. 1, the memory device 1 is controlled by a memory controller 2 in the outside. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). The block BLK is a set of memory cells. The block BLK corresponds to, for example, a unit of data erasure. The block BLK includes a plurality of pages. The page corresponds to a unit in which reading and writing of data are executed. Although illustration is omitted, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that takes charge of transmission and reception of input/output signals with the memory controller 2. The input/output signal includes, for example, data DAT, status information, address information, a command, etc. The input/output circuit 11 can input and output data DAT between the sense amplifier module 17 and the memory controller 2. The input/output circuit 11 can output, to the memory controller 2, status information transferred from the register circuit 13. The input/output circuit 11 can output, to the register circuit 13, each of address information and a command transferred from the memory controller 2.

The logic controller 12 controls each of the input/output circuit 11 and the sequencer 14 based on a control signal inputted from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 orders the input/output circuit 11 to input or output an input/output signal.

The register circuit 13 temporarily stores status information, address information, and a command. The status information is updated based on the control of the sequencer 14, and is transferred to the input/output circuit 11. The address information includes a block address, a page address, a column address, and the like. The command includes orders regarding various operations of the memory device 1.

The sequencer 14 controls the entire operation of the memory device 1. The sequencer 14 executes a read operation, a write operation, an erase operation, or the like based on a command and address information stored in the register circuit 13.

The driver circuit 15 generates voltage used for a read operation, a write operation, an erase operation, or the like. Then, the driver circuit 15 supplies the generated voltage to the row decoder module 16, the sense amplifier module 17, or the like.

The row decoder module 16 is a circuit used to select a block BLK to be operated and transfer voltage to a wiring line such as a word line WL. The row decoder module 16 includes a plurality of row decoders RD0 to RDn. The row decoders RD0 to RDn are associated with the blocks BLK0 to BLKn, respectively, and are used to select the block BLK. Each row decoder RD transfers voltage generated by the driver circuit 15 to various wiring lines provided in the memory cell array 10.

The sense amplifier module 17 is a circuit used to transfer voltage to each bit line BL and read data. The sense amplifier module 17 includes a plurality of sense amplifier units SAU0 to SAUm. The sense amplifier units SAU0 to SAUm are associated with the bit lines BL0 to BLm, respectively. Each sense amplifier unit SAU includes a sense amplifier capable of determining data based on the voltage of the associated bit line BL, a latch circuit that temporarily holds data, etc.

Note that a combination of the memory device 1 and the memory controller 2 may constitute one semiconductor device. Examples of such a semiconductor device include a memory card such as an SD™ card, an SSD (solid-state drive), and the like. The memory device 1 may include a plurality of memory cell arrays 10. The memory device 1 may include a row decoder module 16 and a sense amplifier module 17 for each memory cell array 10. A set of the memory cell array 10, the row decoder module 16, and the sense amplifier module 17 is referred to as, for example, a “plane”. That is, the memory device 1 may include a plurality of planes.

### <1-1-2> Circuit Configuration of the Memory Cell Array 10

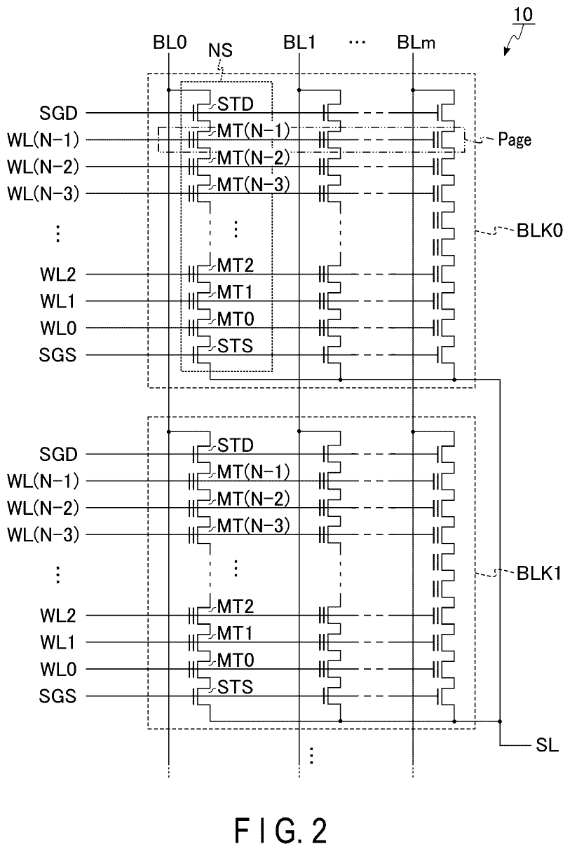

FIG. 2 is a circuit diagram showing an example of a circuit configuration of the memory cell array 10 included in the memory device 1 according to the first embodiment. FIG. 2 shows two blocks BLK0 and BLK1 among the blocks BLK included in the memory cell array 10. As shown in FIG. 2, in the memory cell array 10, select gate lines SGD and SGS and word lines WL0 to WL(N−1) (N is an integer of 2 or more) are provided for each block BLK. Bit lines BL0 to BLm and a source line SL are shared by, for example, a plurality of blocks BLK.

Each block BLK includes a plurality of NAND strings NS. The NAND strings NS are individually associated with the bit lines BL0 to BLm. Each NAND string NS is connected between the associated bit line BL and the source line SL. Each NAND string NS includes, for example, N memory cell transistors MT0 to MT(N−1) and select transistors STD and STS. Each memory cell transistor MT is a memory cell including a control gate and a charge storage layer, and holds (stores) data in a nonvolatile manner. Each of the select transistors STD and STS is used to select the block BLK.

In each NAND string NS, the select transistor STD, the memory cell transistors MT(N−1) to MT0, and the select transistor STS are connected in series in this order. Specifically, the drain end and the source end of the select transistor STD are connected to the associated bit line BL and the drain end of the memory cell transistor MT(N−1), respectively. The drain end and the source end of the select transistor STS are connected to the source end of the memory cell transistor MT0 and the source line SL, respectively.

Each select gate line SGD is connected to the gate end of each of the select transistors STD included in the associated block BLK. The select gate line SGS is connected to the gate end of each of the select transistors STS included in the associated block BLK. The word lines WL0 to WL(N−1) are connected to the control gate ends of the memory cell transistors MT0 to MT(N−1) included in the associated block BLK, respectively.

The “page” corresponds to a set of memory cell transistors MT connected to a common word line WL in the same block BLK. The set of memory cell transistors MT connected to a common word line WL in the same block BLK can have a storage capacity of two-page data or more according to the number of bits stored in the memory cell transistors MT.

Note that the circuit configuration of the memory cell array 10 may be another circuit configuration. For example, a plurality of independently controllable select gate lines SGD may be provided in each block BLK. In this case, each block BLK is configured such that selection can be performed in units of a plurality of units individually associated with the select gate lines SGD.

In the following, for the memory device 1 according to the first embodiment, a case where each NAND string NS includes ten memory cell transistors MT0 to MT9 connected to ten word lines WL0 to WL9, respectively, (that is, a case where N=10) is described as an example.

### <1-1-3> Structure of the Memory Device 1

A structure of the memory device 1 according to the first embodiment will now be described.

In the drawings referred to below, a three-dimensional orthogonal coordinate system is used. The X direction corresponds to the extending direction of the word line WL, for example. The Y direction corresponds to the extending direction of the bit line BL, for example. The Z direction corresponds to a vertical direction with respect to a substrate of the memory device 1. The “up and down” is defined based on a direction along the Z direction. The up (upper side) direction corresponds to a direction away from the reference configuration (for example, source line SL). The down (lower side) direction corresponds to a direction approaching to the reference configuration (for example, source line SL). The XY plane (cross section) corresponds to a plane (cross section) parallel to each of the X direction and the Y direction. The YZ cross section corresponds to a cross section parallel to each of the Y direction and the Z direction. The XZ cross section corresponds to a cross section parallel to each of the X direction and the Z direction. The “XY cross-sectional area” corresponds to a cross-sectional area of the object in the XY cross section.

In the memory device 1, the memory cell array 10 includes a plurality of wiring layers (for example, word lines WL0 to WL9 and select gate lines SGD and SGS) stacked apart from each other in the Z direction. Hereinafter, a plurality of wiring layers (conductive layers) stacked apart from each other in the Z direction are referred to also as “stacked wiring lines”. As a method for forming stacked wiring lines, a method in which a structure corresponding to each wiring layer is formed with a sacrificial member, the sacrificial member is removed to form a vacant space, and the vacant space is embedded with a conductive material is known. Hereinafter, a method of forming stacked wiring lines by thus replacing a sacrificial member with a conductive material is referred to as “WL replacement”.

### (1: Planar Layout of the Memory Cell Array 10)

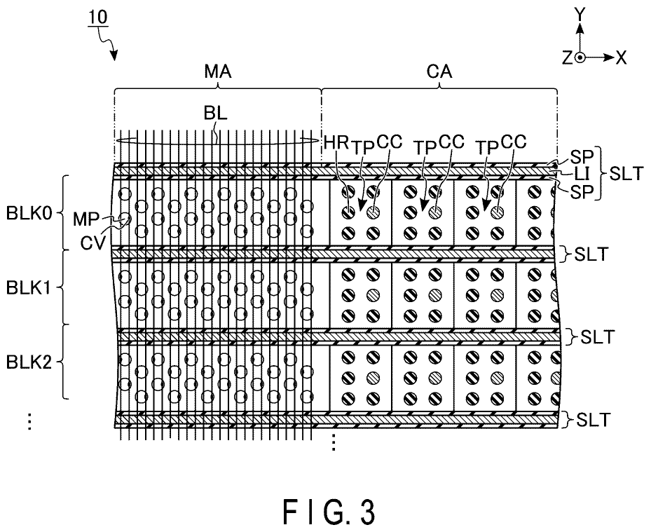

FIG. 3 is a plan view showing an example of a planar layout of the memory cell array 10 included in the memory device 1 according to the first embodiment. As shown in FIG. 3, the memory cell array 10 includes, for example, a plurality of members SLT. Further, the memory cell array 10 includes a memory area MA and a contact area CA arranged in the X direction.

Each of the members SLT has a portion provided to extend along the X direction. Each of the members SLT crosses the memory area MA and the contact area CA along the X direction. The members SLT are arranged in the Y direction. Each of the members SLT divides the stacked wiring lines for each block BLK. That is, in the memory cell array 10, each of the areas partitioned along the Y direction by the slits SLT corresponds to one block BLK. Each of the members SLT includes, for example, a conductive member LI and a spacer SP. The spacer SP is an insulator provided on a side surface of the conductive member LI, and separates the conductive member LI from the stacked wiring lines. The conductive member LI is insulated from the stacked wiring lines by the spacer SP and functions as a part of the source line SL. Note that each of the members SLT may contain an insulator wholly.

The memory area MA is used to store data and includes a plurality of memory pillars MP and a plurality of contact plugs CV. Each memory pillar MP is, for example, a substantially cylindrical member functioning as one NAND string NS. A plurality of memory pillars MP are arranged, for example, in a lattice configuration for each block BLK. At least one bit line BL is placed to overlap each memory pillar MP. Then, one bit line BL is electrically connected to each memory pillar MP via the contact plug CV. Each contact plug CV includes a substantially cylindrical conductor provided to extend in the Z direction. The bit lines BL each have a portion provided to extend in the Y direction, and are arranged in the X direction. In the present example, two bit lines BL are arranged to overlap one memory pillar MP.

The contact area CA is used for connection between the stacked wiring lines provided for each block BLK and the row decoder module 16. In the contact area CA, each wiring layer (conductive layer) included in the stacked wiring lines has a terrace portion TP. The terrace portion TP corresponds to a portion of the wiring layer that does not overlap one or more upper wiring layers. In the contact area CA, for example, a plurality of terrace portions TP corresponding to the select gate line SGD, the word lines WL9 to WL0, and the select gate line SGS are arranged in order from the memory area MA toward the end in the X direction (the right side in the drawing sheet). Thus, the terrace portions TP of the wiring layers included in the stacked wiring lines can be provided in a staircase shape in one row. Note that the terrace portions TP of the wiring layers included in the stacked wiring lines may be provided in a staircase shape in two or more rows. It is not necessarily required that two terrace portions TP adjacent in a planar view be associated with two wiring layers adjacent in the Z direction.

In addition, the contact area CA includes a plurality of contact plugs CC and a plurality of support pillars HR for each block BLK. Each contact plug CC includes a substantially cylindrical conductor provided to extend in the Z direction. Each contact plug CC is electrically connected to the terrace portion TP of any one wiring layer of the stacked wiring lines, and is not electrically connected to the other wiring layers. The plurality of contact plugs CC of each block BLK are arranged in a line in the X direction in the contact area CA, for example. Each support pillar HR includes a substantially cylindrical insulator provided to extend in the Z direction. Each support pillar HR is used as a pillar that supports a stacked structure having a void in the WL replacement. Each support pillar HR is appropriately arranged in a portion that does not overlap the contact plug CC in the contact area CA.

Note that the number and arrangement of the memory pillars MP can be freely designed in the memory cell array 10. Associated memory pillars MP and bit lines BL may be connected via two or more contact plugs. The number and arrangement of the contact plugs CC of each block BLK can be freely designed. The number of contact plugs CC connected to the terrace portion TP of each wiring layer may be one or more. The plurality of contact plugs CC of each block BLK may be arranged in a lattice pattern in the contact area CA. The number and arrangement of the support pillars HR of each block BLK can be freely designed. The memory cell array 10 may include two contact areas CA arranged so as to sandwich the memory area MA in the X direction. The contact area CA may be arranged so as to divide the memory area MA in the X direction.

### (2: Cross-Sectional Structure of the Memory Area MA)

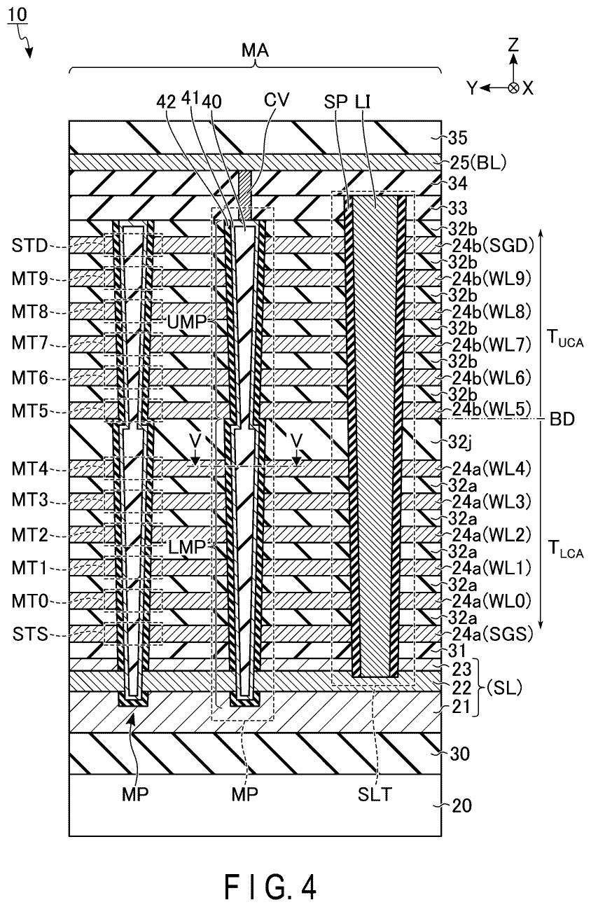

FIG. 4 is a cross-sectional view showing an example of a cross-sectional structure of the memory area MA of the memory cell array 10 included in the memory device 1 according to the first embodiment. FIG. 4 shows a YZ cross section including two memory pillars MP and one member SLT in the memory area MA of the memory cell array 10. As shown in FIG. 4, the memory cell array 10 includes, for example, a substrate 20, semiconductor layers 21 to 23, conductive layers 24 and 25, and insulating layers 30 to 35.

The substrate 20 is, for example, a silicon substrate. An insulating layer 30 is provided on the substrate 20. The insulating layer 30 contains, for example, silicon oxide. Circuits such as the row decoder module 16 and the sense amplifier module 17 may be provided in the area where the insulating layer 30 is provided. Note that, in a case where the memory device 1 has a structure in which a chip provided with the memory cell array 10 and a chip provided with circuits and the like other than the memory cell array 10 are bonded to each other, the substrate 20 provided under the insulating layer 30 may be discarded.

The semiconductor layers 21, 22, and 23 are stacked in this order on the insulating layer 30. A set of the semiconductor layers 21, 22, and 23 functions as a source line SL. Each of the semiconductor layers 21, 22, and 23 contains, for example, silicon. Further, each of the semiconductor layers 21, 22, and 23 contains, for example, phosphorus (P) as an impurity of an n-type semiconductor. The semiconductor layer 22 is formed by, for example, replacing a sacrificial member provided between the semiconductor layers 21 and 23 with a semiconductor material. Hereinafter, a method of forming the semiconductor layer 22 by replacing a sacrificial member with a semiconductor material in this manner is referred to as “SL replacement”. Note that, although not shown, the semiconductor layers 21 and 23 are provided from the memory area MA to the contact area CA. Then, in the present example, the semiconductor layer 22 is provided in the memory area MA, and is not provided in the contact area CA. Depending on the structure of the memory cell array 10, the semiconductor layer 22 may be provided in the contact area CA.

The insulating layer 31 is provided on the semiconductor layer 23. The insulating layer 31 contains, for example, silicon oxide. On the insulating layer 31, for example, the conductive layer 24 of twelve layers (wiring layers) and the insulating layer 32 of twelve layers are alternately stacked one by one. The conductive layer 24 is, for example, formed in a plate shape spreading along the XY plane. The conductive layer 24 includes, for example, a stacked structure of titanium nitride (TiN)/tungsten (W) as a conductive material. In this case, titanium nitride (nitrogen and titanium) is formed to cover tungsten. Titanium nitride included in the conductive layer 24 has a function as a barrier layer for suppressing oxidation of tungsten or an adhesion layer for improving adhesion of tungsten when tungsten is formed by, for example, chemical vapor deposition (CVD). In addition, the conductive layer 24 may contain a high dielectric constant material such as aluminum oxide (oxygen and aluminum). In this case, the high dielectric constant material is formed to cover the conductive material of the conductive layer 24. For example, in the conductive layer 24, the high dielectric constant material is provided to be in contact with the insulating layer 31 or 32 provided above and below the conductive layer 24 and the side surface of the memory pillar MP. In the conductive layer 24, for example, titanium nitride is provided to be in contact with the high dielectric constant material, and tungsten is provided to be in contact with titanium nitride and to be embedded in an inside of the conductive layer 24.

The insulating layer 33 is provided on the uppermost insulating layer 32. The insulating layer 34 is provided on the insulating layer 33. Each of the insulating layers 33 and 34 contains, for example, silicon oxide. The conductive layer 25 is provided on the insulating layer 34. The conductive layer 25 functions as the bit line BL. The conductive layer 25 has, for example, a portion provided to extend in the Y direction. Although not shown, a plurality of conductive layers 25 are arranged in the X direction. The conductive layer 25 contains, for example, copper (Cu). The insulating layer 35 is provided on the conductive layer 25. The insulating layer 35 contains, for example, silicon oxide.

The member SLT has a portion spreading along the XZ plane. The member SLT has, for example, a tapered shape in which the width in the Y direction of the upper end is larger than the width in the Y direction of the lower end. The member SLT divides the semiconductor layer 23, the insulating layer 31, the alternately stacked conductive layers 24 and insulating layers 32, and the insulating layer 33. In other words, the member SLT separates the semiconductor layer 23, the insulating layer 31, the alternately stacked conductive layers 24 and insulating layers 32, and the insulating layer 33 provided in adjacent blocks BLK. The lower end of the member SLT reaches the semiconductor layer 22. In the member SLT, each of the conductive member LI and the spacer SP has a portion spreading along the XZ plane. Each of the conductive member LI and the spacer SP is continuously provided in the member SLT. The conductive member LI has a portion facing each of the conductive layers 24 in the Y direction via the spacer SP. The lower end of the conductive member LI is electrically connected to the semiconductor layer 22 (the source line SL). The conductive member LI contains, for example, tungsten and titanium nitride, or silicon. The spacer SP contains, for example, silicon oxide.

Each memory pillar MP is provided to extend along the Z direction, and penetrates (passes through) the semiconductor layers 22 and 23, the insulating layer 31, and the conductive layers 24 and the insulating layers 32 alternately stacked. For example, a lower portion of each memory pillar MP is covered with the semiconductor layers 21, 22, and 23. Each memory pillar MP includes, for example, a core member 40, a semiconductor film 41, and a stacked film 42. The core member 40 is a substantially cylindrical insulator extending along the Z direction. The upper end of the core member 40 is positioned above the uppermost conductive layer 24. The lower end of the core member 40 is located, for example, in the same layer as the semiconductor layer 21. The semiconductor film 41 is provided to extend along the Z direction and covers the periphery of the core member 40. The semiconductor film 41 has a portion connected to the semiconductor layer 22 (source line SL) via a part of the side surface of the memory pillar MP. The stacked film 42 covers the side surface and the bottom surface of the semiconductor film 41 except for a portion where the semiconductor film 41 and the semiconductor layer 22 are connected. The semiconductor film 41 faces each of the conductive layers 24 arranged in the Z direction in a planar direction (for example, the Y direction) with the stacked film 42 interposed therebetween.

A contact plug CV is provided on the semiconductor film 41 of each memory pillar MP. The contact plug CV penetrates (passes through) the insulating layers 33 and 34. The semiconductor film 41 (the memory pillar MP) and the conductive layer 25 (the bit line BL) are electrically connected via the contact plug CV.

Note that the number of conductive layers 24 corresponds to the number of wiring layers included in the stacked wiring line (the conductive layers 24 arranged in the Z direction). In the present example, the conductive layer 24 of twelve layers is used as the select gate line SGS, the word lines WL0 to WL9, and the select gate line SGD in this order from the source line SL side. A portion where the conductive layer 24 used as the select gate line SGS and the memory pillar MP cross each other functions as a select transistor STS. A portion where the conductive layer 24 used as the word line WL and the memory pillar MP cross each other functions as a memory cell transistor MT. A portion where the conductive layer 24 used as the select gate line SGD and the memory pillar MP cross each other functions as a select transistor STD. The semiconductor film 41 in each memory pillar MP is used as channels (current paths) of the memory cell transistors MT0 to MT9 and the select transistors STD and STS included in a NAND string NS. In a case where the conductive layer 24 contains aluminum oxide as the high dielectric constant material, the memory cell transistor MT is also referred to as a metal-aluminum-nitride-oxide-silicon (MANOS) type memory cell.

### (3: Tier Structure of the Memory Cell Array 10)

Next, the tier structure of the memory cell array 10 will be described with reference to FIG. 4. The memory cell array 10 has stacked wiring lines formed separately in two tiers.

In the first embodiment, the tier on the lower side of the two tiers of the stacked wiring lines is referred to as a “lower tier T_{LCA}”. The tier on the upper side of the two tiers of the stacked wiring lines is referred to as an “upper tier T_{UCA}”. The boundary between the lower tier T_{LCA} and the upper tier T_{UCA} is referred to as a “boundary BD”. The conductive layers 24 and the insulating layers 32 are arranged over the lower tier T_{LCA} and the upper tier T_{UCA}. In the first embodiment, the conductive layer 24 and the insulating layer 32 included in the lower tier T_{LCA} are referred to as a conductive layer 24a and an insulating layer 32a, respectively. The conductive layer 24 and the insulating layer 32 included in the upper tier T_{UCA} are referred to as a conductive layer 24b and an insulating layer 32b, respectively. In the present example, the boundary BD is located between the conductive layer 24a functioning as the word line WL4 and the conductive layer 24b functioning as the word line WL5. In other words, the boundary BD is located between the uppermost conductive layer 24a and the lowermost conductive layer 24b.

Further, in the first embodiment, the insulating layer 32 (32a) corresponding to a position between the uppermost conductive layer 24a and the lowermost conductive layer 24b, that is, the boundary BD between the lower tier T_{LCA} and the upper tier T_{UCA} is referred to as an “insulating layer 32j”. In the first embodiment, the thickness in the Z direction of the insulating layer 32j is larger than that of each of the other insulating layers 32. Therefore, the distance in the Z direction between the conductive layers 24a and 24b adjacent via the boundary BD is larger than the distance in the Z direction between two conductive layers 24 not adjacent via the boundary BD. In other words, the distance in the Z direction between the uppermost conductive layer 24a and the lowermost conductive layer 24b is larger than the distance between two conductive layers 24a or 24b adjacent in the Z direction among the conductive layers 24a or 24b. Note that the insulating layer 32j may include a plurality of insulating layers.

In the first embodiment, each memory pillar MP is formed separately in two tiers. Specifically, each memory pillar MP includes a lower memory pillar LMP and an upper memory pillar UMP connected in the Z direction. The lower memory pillar LMP and the upper memory pillar UMP are included in the lower tier T_{LCA} and the upper tier T_{UCA}, respectively. The position of the boundary between the lower memory pillar LMP and the upper memory pillar UMP substantially coincides with the boundary BD. The upper memory pillar UMP penetrates (passes through), for example, the six conductive layers 24b (the word lines WL5 to WL9 and the select gate line SGD) and the six insulating layers 32b, and the bottom of the upper memory pillar UMP is connected to the upper end of the lower memory pillar LMP. The lower memory pillar LMP penetrates (passes through), for example, the six conductive layers 24a (the select gate line SGS and the word lines WL0 to WL4), the five insulating layers 32a, the insulating layers 31 and 32j, and the semiconductor layers 22 and 23, and the bottom of the lower memory pillar LMP is located in the semiconductor layer 21.

Each of the core member 40, the semiconductor film 41, and the stacked film 42 is continuously provided in the lower memory pillar LMP and the upper memory pillar UMP. Each of the lower memory pillar LMP and the upper memory pillar UMP has, for example, a tapered shape (forward tapered shape) in which the diameter (XY cross-sectional area) of the upper end is larger than the diameter (XY cross-sectional area) of the lower end. In other words, each of the lower memory pillar LMP and the upper memory pillar UMP has, for example, a truncated cone shape in which the lower portion is smaller than the upper portion. Thus, the boundary BD can be found by observing the cross-sectional shape of the memory pillar MP. Each of the lower memory pillar LMP and the upper memory pillar UMP may be referred to as a sub-pillar of the memory pillar MP. The lower memory pillar LMP may have a shape in which the width is widened in a portion crossing the insulating layer 32j.

In the first embodiment, a stacked structure corresponding to the six conductive layers 24a, the five insulating layers 32a, and the insulating layer 32j included in the lower tier T_{LCA} is referred to as a “lower layer stack”. A stacked structure corresponding to the six conductive layers 24b and the six insulating layers 32b included in the upper tier T_{UCA} is referred to as an “upper layer stack”.

### (4: Cross-Sectional Structure of the Memory Pillar MP)

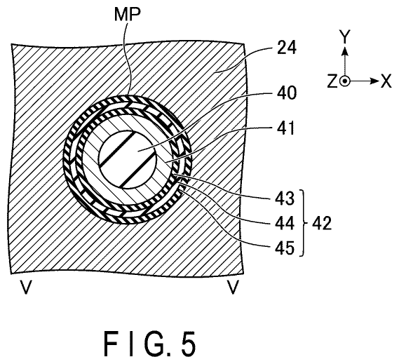

FIG. 5 is a cross-sectional view taken along line V-V of FIG. 4, showing an example of a cross-sectional structure of the memory pillar MP included in the memory device 1 according to the first embodiment. FIG. 5 shows an XY cross section including the memory pillar MP and the conductive layer 24. As shown in FIG. 5, the stacked film 42 includes, for example, a tunnel insulating film 43, a charge storage film 44, and a block insulating film 45. The tunnel insulating film 43 surrounds the side surface of the semiconductor film 41. The charge storage film 44 surrounds the side surface of the tunnel insulating film 43. The block insulating film 45 surrounds the side surface of the charge storage film 44. The conductive layer 24 surrounds the side surface of the block insulating film 45. The core member 40 contains, for example, an insulator such as silicon oxide. The semiconductor film 41 contains, for example, silicon. Each of the tunnel insulating film 43 and the block insulating film 45 contains, for example, silicon oxide. The charge storage film 44 functions as a charge storage layer of the memory cell transistor MT, and contains, for example, silicon nitride.

### (5: Cross-Sectional Structure of the Contact Area CA)

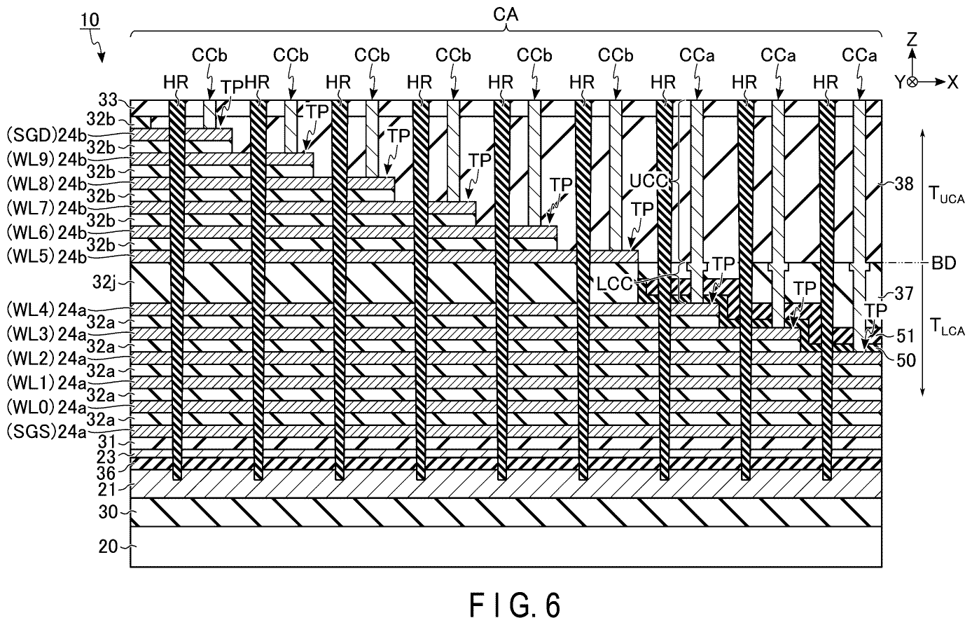

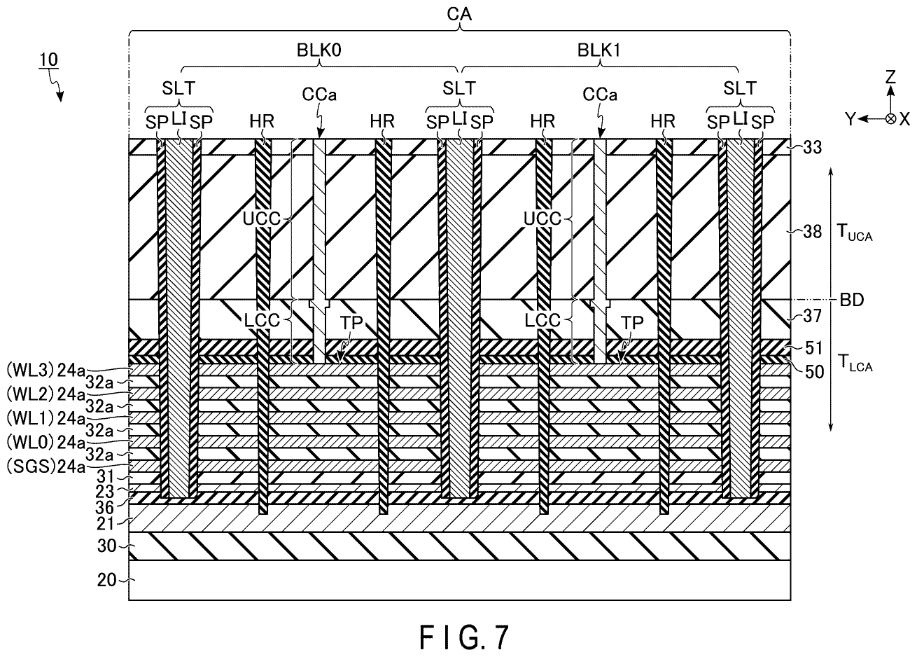

Each of FIGS. 6 and 7 is a cross-sectional view showing an example of a cross-sectional structure of the contact area CA of the memory cell array 10 included in the memory device 1 according to the first embodiment. FIG. 6 shows an XZ cross section including the contact area CA of the memory cell array 10. FIG. 7 shows a YZ cross section including the terrace portion TP of the word line WL3 in the contact area CA of the memory cell array 10. As shown in FIG. 6, in the contact area CA, the memory cell array 10 includes, for example, insulating layers 36, 37, and 38 and insulating films 50 and 51. Further, the contact plugs CC included in the memory cell array 10 include a plurality of contact plugs CCa and a plurality of contact plugs CCb for each block BLK.

In the contact area CA, the insulating layer 36 is provided between the semiconductor layer 21 and the semiconductor layer 23. The insulating layer 36 of the contact area CA is not removed but remains in SL replacement. The insulating layer 36 contains, for example, silicon oxide.

In the contact area CA, the insulating layer 37 is provided to fill the staircase portion formed by the terrace portions TP included in the lower tier T_{LCA}. In other words, in the contact area CA, the insulating layer 37 is provided to fill the staircase portion formed by the terrace portions TP of the lower layer stack. By the insulating layer 37, the step differences based on the staircase portion corresponding to the lower layer stack can be flattened from the memory area MA to the contact area CA. The insulating layer 37 contains, for example, silicon oxide.

In the contact area CA, the insulating layer 38 is provided to fill the staircase portion formed by the terrace portions TP included in the upper tier T_{UCA}. In other words, in the contact area CA, the insulating layer 38 is provided to fill the staircase portion formed by the terrace portions TP of the upper layer stack. By the insulating layer 38, the step differences based on the staircase portion corresponding to the upper layer stack can be flattened from the memory area MA to the contact area CA. The insulating layer 38 contains, for example, silicon oxide.

The insulating film 50 is provided to cover the terrace portions TP of the conductive layers 24a included in the lower tier T_{LCA}. In other words, the insulating film 50 is provided along the staircase shape formed by the terrace portions TP of the conductive layers 24a included in the lower tier T_{LCA}. The insulating film 50 is located below the boundary BD. The insulating film 50 is continuously provided between adjacent two terrace portions TP. The insulating film 50 contains, for example, silicon oxide.

The insulating film 51 is provided on the insulating film 50. The insulating film 51 overlaps the terrace portions TP of the conductive layers 24a included in the lower tier T_{LCA} in the Z direction. Further, the insulating film 51 is continuously provided between adjacent two terrace portions TP. The upper surface of the insulating film 51 has step differences along the staircase shape formed by the terrace portions TP of the conductive layers 24a included in the lower tier T_{LCA}. The insulating film 51 has a structure in which a member used as a stopper film in hole processing for contact plugs CC is replaced with an insulator. The insulating film 51 contains, for example, silicon oxide.

The contact plugs CCa are electrically connected respectively to the terrace portions TP of the conductive layers 24a included in the lower tier T_{LCA}. Each contact plug CCa is provided to extend along the Z direction. Each contact plug CCa penetrates (passes through) the insulating layers 33, 37, and 38 and the insulating films 50 and 51, and the bottom of the contact plug CCa is connected to the terrace portion TP of the associated conductive layer 24a. The contact plug CCa contains, for example, tungsten or copper.

The contact plugs CCb are electrically connected respectively to the terrace portions TP of the conductive layers 24b included in the upper tier T_{UCA}. Each contact plug CCb is provided to extend along the Z direction. Each contact plug CCb penetrates (passes through) the insulating layers 33 and 38, and the bottom of the contact plug CCb is connected to the terrace portion TP of the associated conductive layer 24b. The contact plug CCb contains, for example, tungsten or copper.

In the first embodiment, each contact plug CCa is formed separately in two tiers. Specifically, each contact plug CCa includes a lower contact plug LCC and an upper contact plug UCC connected in the Z direction. The lower contact plug LCC and the upper contact plug UCC are included in the lower tier T_{LCA} and the upper tier T_{UCA}, respectively. The position of the boundary between the lower contact plug LCC and the upper contact plug UCC substantially coincides with the boundary BD. The upper contact plug UCC penetrates (passes through) the insulating layers 33 and 38, and the bottom of the upper contact plug UCC is connected to the upper end of the lower contact plug LCC. The lower contact plug LCC penetrates (passes through) the insulating layer 37 and the insulating films 50 and 51, and the bottom of the lower contact plug LCC is connected to the terrace portion TP of the associated conductive layer 24a. The lower contact plug LCC may have a shape in which the width is widened in the vicinity of the boundary BD.

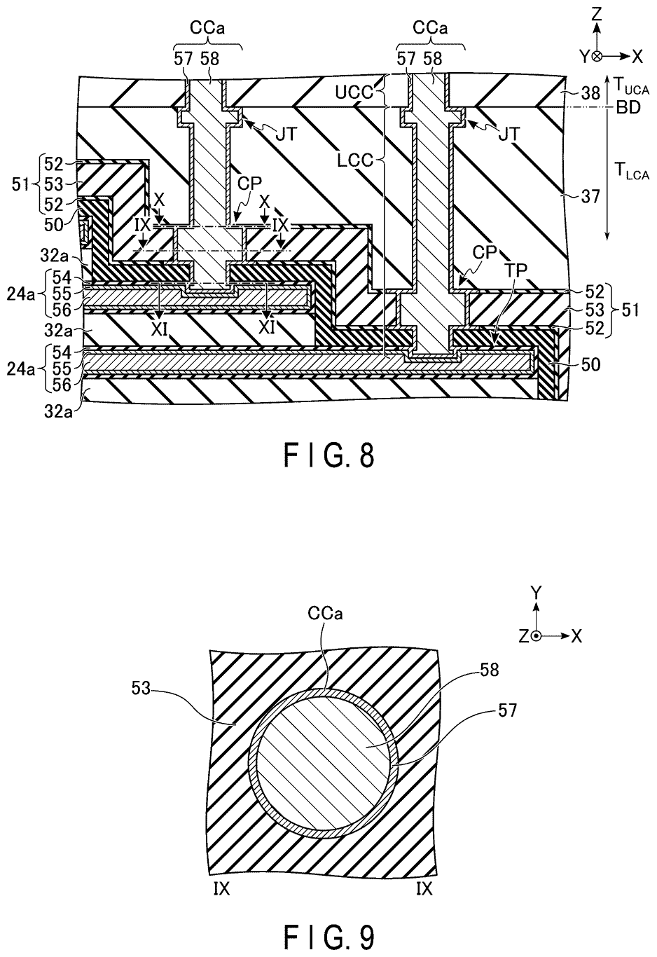

Each support pillar HR penetrates (passes through) the insulating layers 31, 32a, 32b, 32j, 33, and 36, the semiconductor layer 23, and at least one conductive layer 24 (24a and 24b) arranged to overlap in a planar view. The upper end of each support pillar HR is located above the uppermost conductive layer 24b. The lower end of each support pillar HR is, for example, located in the same layer as the semiconductor layer 21. The support pillar HR contains, for example, silicon oxide. Note that each support pillar HR may have a structure formed separately in a plurality of tiers. In FIG. 8 and subsequent drawings referred to in the present specification, illustration of the support pillar HR is omitted for simplification of the drawings. In a method of manufacturing the memory device 1 described later, it is sufficient for each support pillar HR to be formed before SL replacement and WL replacement.

As shown in FIG. 7, in the same layer, two conductive layers 24a provided in adjacent two blocks BLK (for example, BLK0 and BLK1) are separated and insulated from each other by a member SLT provided therebetween. Thereby, the voltage of each of the conductive layers 24a can be controlled on a block BLK basis via the associated contact plug CCa. Similarly, although illustration is omitted, in the same layer, two conductive layers 24b provided in adjacent two blocks BLK are separated and insulated from each other by a member SLT provided therebetween. Thereby, the voltage of each of the conductive layers 24b can be controlled on a block BLK basis via the associated contact plug CCb. The side surface of each member SLT is in contact with the insulating films 50 and 51.

### (6: Detailed Cross-Sectional Structure of the Contact Area CA)

FIG. 8 is a cross-sectional view showing an example of a detailed cross-sectional structure of the contact area CA of the memory cell array 10 included in the memory device 1 according to the first embodiment. As shown in FIG. 8, the insulating film 51 includes, for example, high dielectric films 52 and an insulating member 53. The conductive layer 24a includes, for example, a high dielectric film 54, a barrier metal 55, and a conductive member 56. The contact plug CCa includes, for example, a barrier metal 57 and a conductive member 58. Note that, although illustration is omitted, the configuration in the conductive layer 24b is similar to that of the conductive layer 24a, and the configuration in the contact plug CCb is similar to that of the contact plug CCa.

The high dielectric films 52 are provided in outer peripheral portions of the insulating film 51. Specifically, the high dielectric films 52 are provided in, of the insulating film 51, a portion where the insulating layer 37 and the insulating film 51 are in contact with each other and a portion where the insulating film 50 and the insulating film 51 are in contact with each other. The high dielectric film 52 contains, for example, aluminum oxide. The insulating member 53 is provided to fill an inside of the high dielectric films 52 in the insulating film 51 (for example, a portion sandwiched by the high dielectric films 52 in the Z direction). In the vicinity of a portion of the insulating film 51 penetrated by the contact plug CCa, the insulating member 53 can have a portion not sandwiched by the high dielectric films 52 in the Z direction. The insulating member 53 contains, for example, silicon oxide. The film thickness in the Z direction of the insulating film 51 is larger than the thickness in the Z direction of the conductive layer 24. In other words, the thickness in the Z direction of a portion of the insulating film 51 provided above the terrace portion TP of the conductive layer 24a is larger than the thickness in the Z direction of the terrace portion TP of the same conductive layer 24a.

The high dielectric film 54 is provided in an outer peripheral portion of the conductive layer 24a. Specifically, the high dielectric film 54 is provided in a portion where each of the two insulating layers 32a adjacent in the Z direction and the conductive layer 24a are in contact with each other and a portion where the insulating film 50 and the conductive layer 24a are in contact with each other. The high dielectric film 54 contains the same material as the high dielectric film 52, for example, contains aluminum oxide. The film thickness of the high dielectric film 54 is substantially equal to that of the high dielectric film 52. The barrier metal 55 is provided on an inside of the high dielectric film 54. The barrier metal 55 has a portion provided to cover a lower portion of the contact plug CCa connected to the conductive layer 24a. The barrier metal 55 contains, for example, titanium nitride. The conductive member 56 is provided to fill an inside of the barrier metal 55 in the conductive layer 24a. The conductive member 56 contains, for example, tungsten.

Each of the barrier metal 57 and the conductive member 58 is continuously provided between the lower contact plug LCC and the upper contact plug UCC. The barrier metal 57 is provided in an outer peripheral portion of the contact plug CCa excluding the upper surface. The barrier metal 57 contains, for example, titanium nitride. The conductive member 58 is provided to fill an inside of the barrier metal 57 of the contact plug CCa. The conductive member 58 contains, for example, tungsten. Hereinafter, a portion of the lower contact plug LCC of the contact plug CCa in the vicinity of the boundary BD is referred to as a “joint portion JT”. A portion of the contact plug CCa crossing the insulating film 51 is referred to as a “crossing portion CP”.

The diameter (XY cross-sectional area) of the joint portion JT of the contact plug CCa (the lower contact plug LCC), that is, the diameter (XY cross-sectional area) of an end portion on the boundary BD side of the lower contact plug LCC is larger than the diameter (XY cross-sectional area) of an end portion on the boundary BD side of the upper contact plug UCC. By the joint portion JT being formed, the degree of difficulty of superimposition of the lower contact plug LCC and the upper contact plug UCC in the manufacturing process of the memory device 1 can be reduced.

The diameter (XY cross-sectional area) of the crossing portion CP of the contact plug CCa (the lower contact plug LCC) is larger than the diameter (XY cross-sectional area) of an end portion of the lower contact plug LCC that penetrates (passes through) the insulating layer 37 and that is located on the crossing portion CP side. Further, the diameter (XY cross-sectional area) of the crossing portion CP of the contact plug CCa (the lower contact plug LCC) is larger than the diameter (XY cross-sectional area) of a portion of the lower contact plug LCC that penetrates (passes through) the insulating film 50.

The barrier metal 57 of the contact plug CCa further has, on each of the upper side and the lower side of the crossing portion CP, a portion spreading in a planar direction (for example, the X direction) along the insulating member 53. The barrier metal 57 of the contact plug CCa further has, in a portion crossing the high dielectric film 54 of the conductive layer 24a, a portion spreading in a planar direction (for example, the X direction) along the barrier metal 55 of the conductive layer 24a. Hereinafter, out of the barrier metal 57, a portion provided on the upper side of the crossing portion CP is referred to as a “first portion”, a portion provided on the lower side of the crossing portion CP is referred to as a “second portion”, a portion between the first portion and the second portion is referred to as a “third portion”, and a portion spreading in a planar direction along the barrier metal 55 is referred to as a “fourth portion”. The first portion and the second portion of the barrier metal 57 sandwich part of the conductive member 58 and part of the insulating member 53 in the Z direction. Part of the fourth portion of the barrier metal 57 is sandwiched between the insulating film 50 and the barrier metal 55 of the conductive layer 24a in the Z direction. The XY cross-sectional area of a portion of the contact plug CCa including the fourth portion of the barrier metal 57 is larger than the XY cross-sectional area of the bottom of the contact plug CCa.

### (7: Cross-Sectional Structure of the Contact Plug CCa)

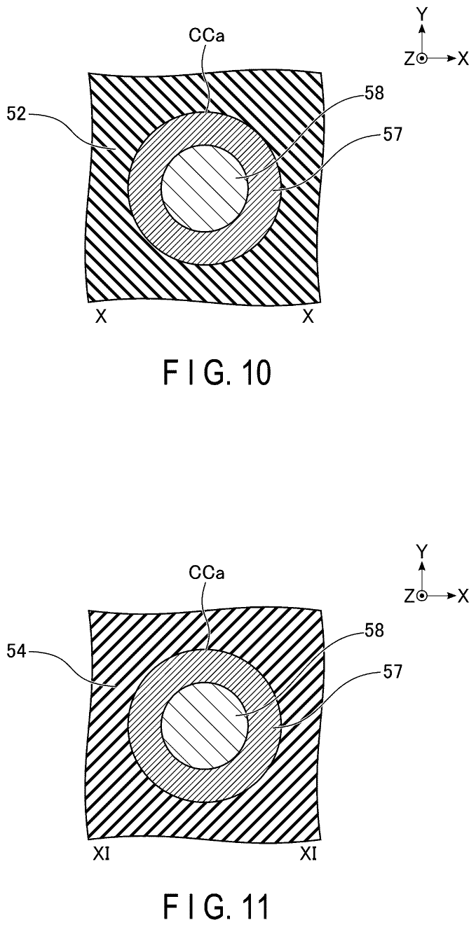

Each of FIGS. 9, 10, and 11 is a cross-sectional view showing an example of a cross-sectional structure of the contact plug CCa included in the memory device 1 according to the first embodiment. FIG. 9 shows a cross section taken along line IX-IX of FIG. 8, and shows an XY cross section including the third portion of the barrier metal 57 of the contact plug CCa and the insulating member 53 in the insulating film 51. FIG. 10 shows a cross section taken along line X-X of FIG. 8, and shows an XY cross section including the first portion of the barrier metal 57 of the contact plug CCa and the high dielectric film 52 in the insulating film 51. FIG. 11 shows a cross section taken along line XI-XI of FIG. 8, and shows an XY cross section including the fourth portion of the barrier metal 57 of the contact plug CCa and the high dielectric film 54 in the conductive layer 24a.

As shown in FIG. 9, in the XY cross section including the third portion of the barrier metal 57 of the contact plug CCa, the conductive member 58 is provided in a central portion of the contact plug CCa. The barrier metal 57 surrounds the side surface of the conductive member 58. In the XY cross section including the contact plug CCa and the insulating member 53 in the insulating film 51, the side surface of the barrier metal 57 is surrounded by the insulating member 53. As shown in FIG. 10, in the XY cross section including the first portion of the barrier metal 57 of the contact plug CCa, the side surface of the barrier metal 57 is surrounded by the high dielectric film 52. In XY cross sections of the barrier metal 57, the film thickness of the first portion is larger than that of the third portion. Similarly, although illustration is omitted, in XY cross sections of the barrier metal 57, the film thickness of the second portion is larger than that of the third portion. As shown in FIG. 11, in the XY cross section including the fourth portion of the barrier metal 57 of the contact plug CCa, the side surface of the barrier metal 57 is surrounded by the high dielectric film 54. In XY cross sections of the barrier metal 57, the film thickness of the fourth portion is larger than that of the third portion. Thus, the barrier metal 57 of the contact plug CCa has a fin shape in each of the first portion, the second portion, and the fourth portion.

### <1-2> Manufacturing Method

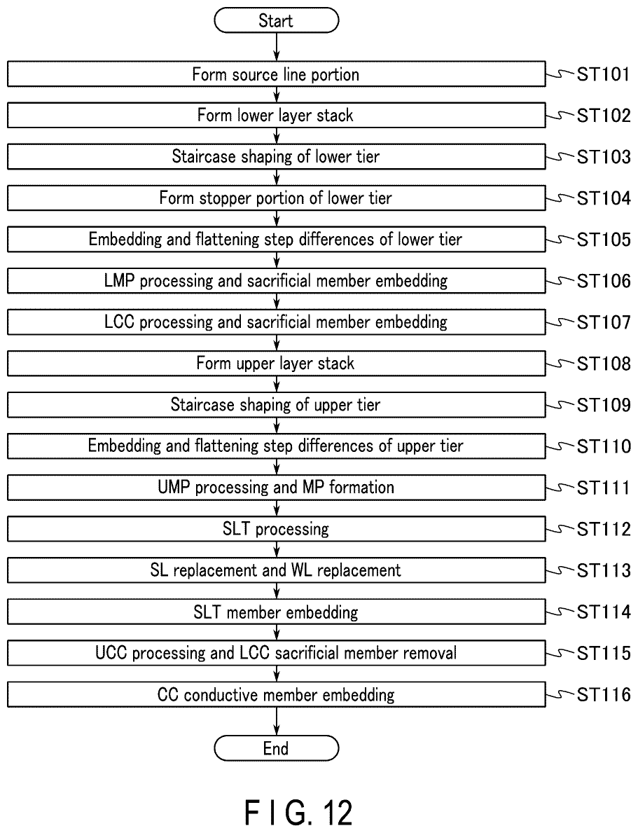

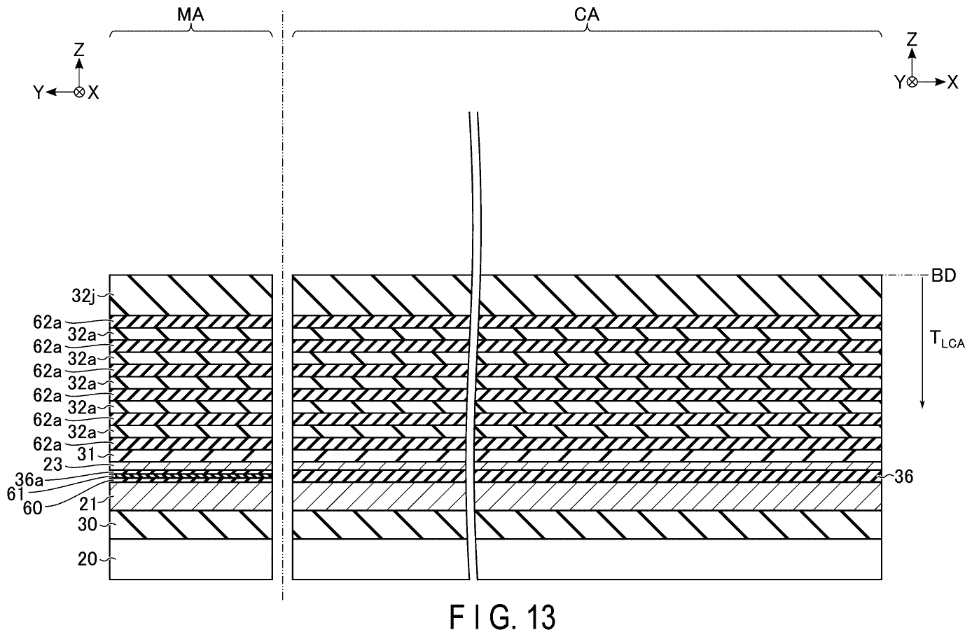

Next, as a method of manufacturing the memory device 1 according to the first embodiment, a method of forming stacked wiring lines and contact plugs CC corresponding to the memory cell array 10 is described with reference to FIG. 12 as appropriate. FIG. 12 is a flowchart showing an example of a method of manufacturing the memory device 1 according to the first embodiment. Each of FIGS. 13, 14, 15, 16, 17, 18, 19, 20, 21, 22, 23, 24, 25, and 26 is a cross-sectional view showing an example of a cross-sectional structure in the manufacturing process of the memory device 1 according to the first embodiment. Each of FIGS. 13 to 26 shows an area where the memory pillar MP and the member SLT are formed and part of the contact area CA.

First, the structure shown in FIG. 13 is formed by the pieces of processing of steps ST101 and ST102 being executed in this order.

In the processing of step ST101, a source line portion is formed. The source line portion is a structure for forming semiconductor layers 21 to 23 functioning as a source line SL in the memory area MA. Specifically, first, an insulating layer 60 and a sacrificial member 61 are stacked in this order on a semiconductor layer 21. The insulating layer 60 contains, for example, silicon oxide. The sacrificial member 61 contains, for example, silicon nitride. Then, the sacrificial member 61 in the contact area CA is removed. Then, an insulating layer 36 is formed, and the upper surface of the insulating layer 36 is flattened. Hereinafter, a portion of the flattened insulating layer 36 included in the memory area MA is referred to as an insulating layer 36a. After that, a semiconductor layer 23 and an insulating layer 31 are formed on the insulating layers 36 and 36a.

In the processing of step ST102, a lower layer stack is formed. Specifically, as a lower layer stack, a plurality of sacrificial members 62a associated with a plurality of conductive layers 24a and a plurality of insulating layers 32a are alternately stacked one by one on the insulating layer 31. The sacrificial member 62a contains, for example, silicon nitride. Then, an insulating layer 32j is formed on the uppermost sacrificial member 62a. On the insulating layer 32j, a member to be used as a hard mask (protective film) in the subsequent staircase shaping may be provided.

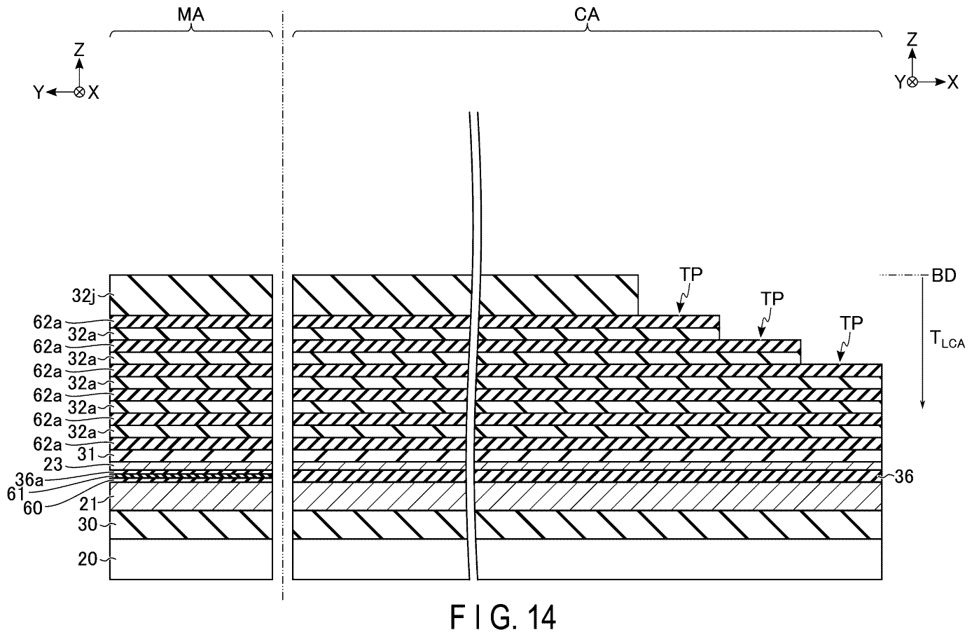

Next, as shown in FIG. 14, staircase shaping of the lower tier T_{LCA} is executed (step ST103). By the processing of step ST103, a staircase structure including a plurality of terrace portions TP of a plurality of sacrificial members 62a of the lower tier T_{LCA} is formed. The terrace portion TP of a sacrificial member 62a corresponds to a portion that does not overlap one or more upper sacrificial members 62a among the sacrificial members 62a. Note that the staircase shaping in the present specification includes a set of photolithography processing and etching processing.

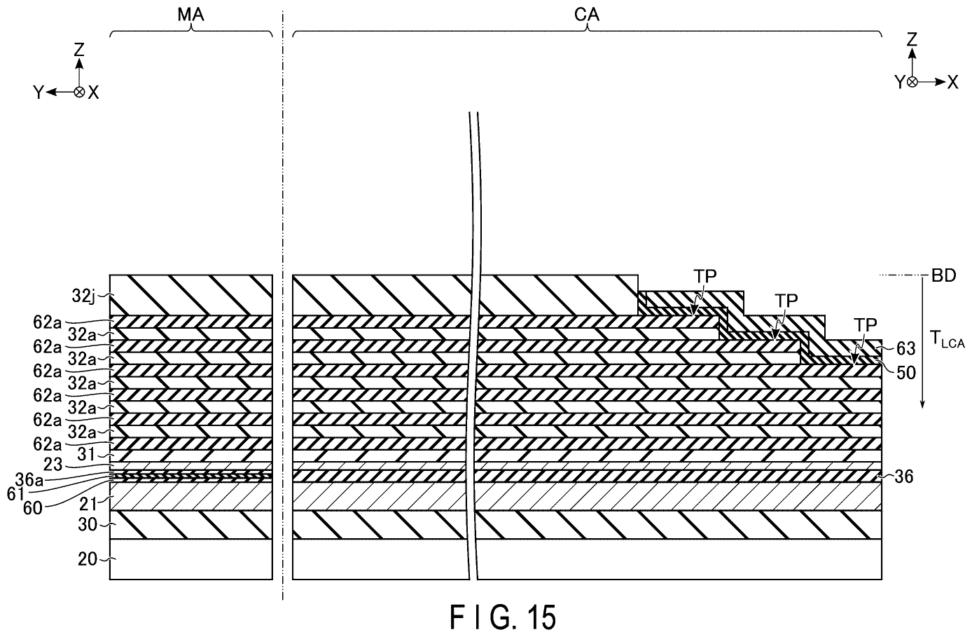

Next, as shown in FIG. 15, a stopper portion of the lower tier T_{LCA} is formed (step ST104). The stopper portion of the lower tier T_{LCA} includes a stopper film to be used in a step of forming a plurality of holes for forming lower contact plugs LCC described later. Specifically, first, an insulating film 50 and a sacrificial member 63 are formed in this order. Then, the insulating film 50 and the sacrificial member 63 are processed (removed) such that a portion covering the terrace portions TP of the sacrificial members 62a of the lower tier T_{LCA} remains. At this time, the insulating film 50 and the sacrificial member 63 formed in the memory area MA are removed, and the insulating film 50 and the sacrificial member 63 on the insulating layer 32j are removed. The shape of the sacrificial member 63 corresponds to the shape of the insulating film 51 shown in FIGS. 6 to 8. The sacrificial member 63 can be used as a stopper film. For example, the sacrificial member 63 contains a material that is the same as the sacrificial member 62a and that is different from the insulating layer 37 or 38, and is formed thicker than the sacrificial member 62a. The sacrificial member 63 contains, for example, silicon nitride.

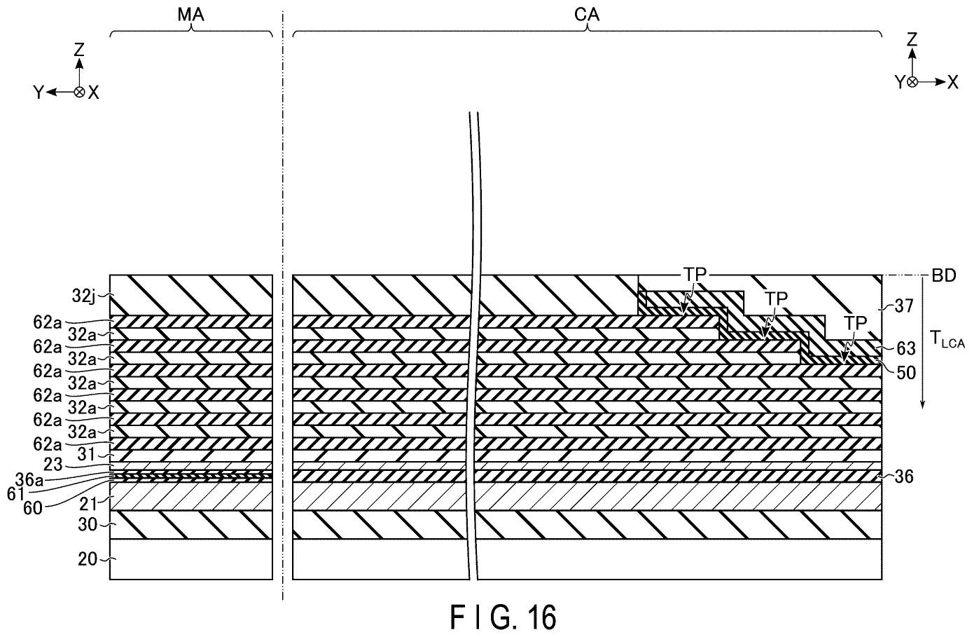

Next, as shown in FIG. 16, embedding and flattening step differences of the lower tier T_{LCA} are executed (step ST105). Specifically, an insulating layer 37 is formed such that the staircase structure included in the lower tier T_{LCA} is embedded. Then, part of the insulating layer 37 is removed by, for example, CMP (chemical mechanical polishing) processing. Thereby, the upper surface of the insulating layer 32j and the upper surface of the insulating layer 37 are aligned (flattened). In a case where a member to be used as a hard mask was provided in the processing of step ST102, this member (hard mask) is removed by the processing of step ST105.

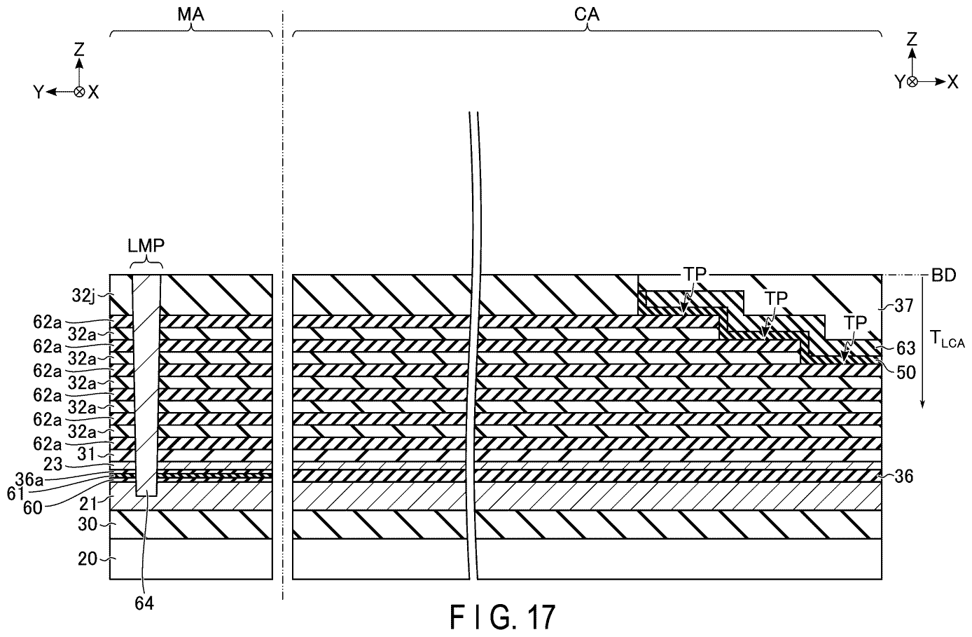

Next, as shown in FIG. 17, LMP processing and sacrificial member embedding are executed (step ST106). Specifically, first, a plurality of holes corresponding to the lower memory pillars LMP are formed such that the hole penetrates the sacrificial members 61 and 62a and the insulating layers 31, 32a, 32j, 36a, and 60 and the bottom of the hole reaches the semiconductor layer 21. Then, sacrificial members 64 are embedded in the holes corresponding to the lower memory pillars LMP. The sacrificial member 64 contains, for example, any of carbon, silicon, and a metal material. For the steps of forming various holes described in the present specification, anisotropic etching processing such as RIE (reactive ion etching) is used.

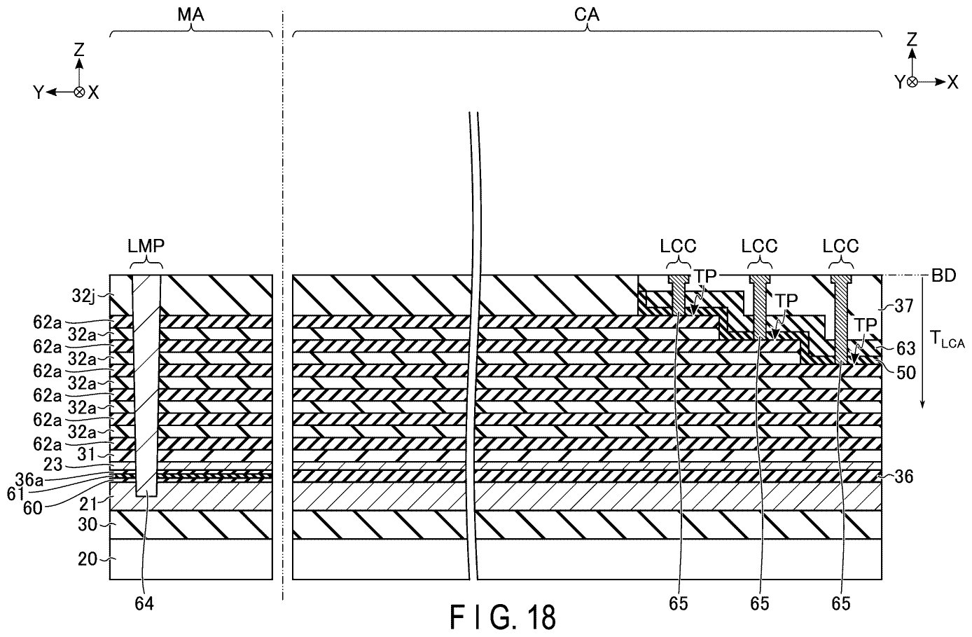

Next, as shown in FIG. 18, LCC processing and sacrificial member embedding are executed (step ST107). By the present processing, a structure corresponding to each of the lower contact plugs LCC of the contact plugs CCa is formed with a sacrificial member 65. Details of the present processing will be described later.

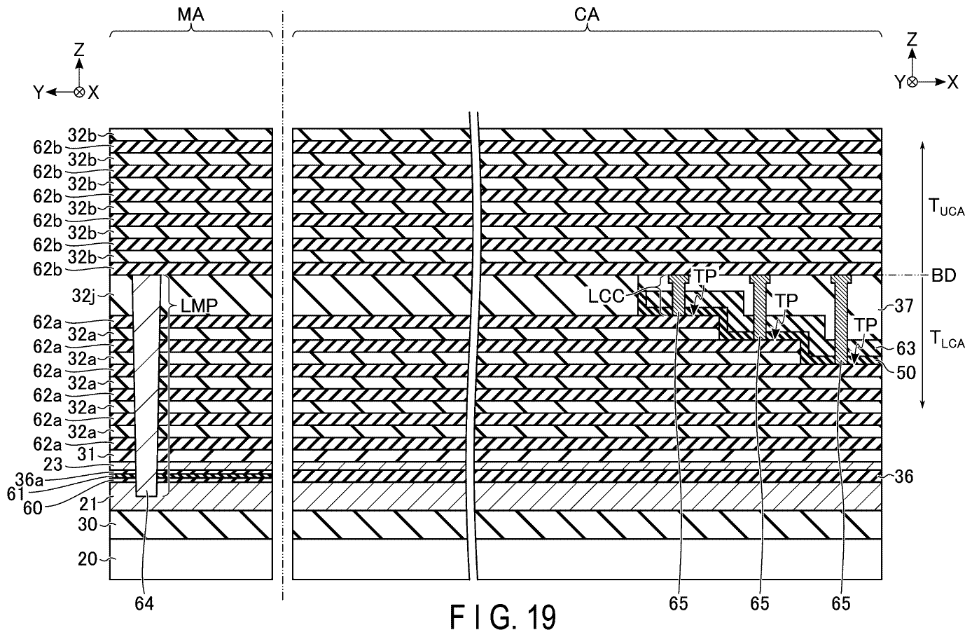

Next, as shown in FIG. 19, an upper layer stack is formed (step ST108). Specifically, as an upper layer stack, a plurality of sacrificial members 62b associated with a plurality of conductive layers 24b and a plurality of insulating layers 32b are alternately stacked one by one on the lower layer stack. The sacrificial member 62b contains the same material as the sacrificial member 62a, for example, contains silicon nitride. Note that a member to be used as a hard mask (protective film) in the subsequent staircase shaping may be provided on the uppermost insulating layer 32b.

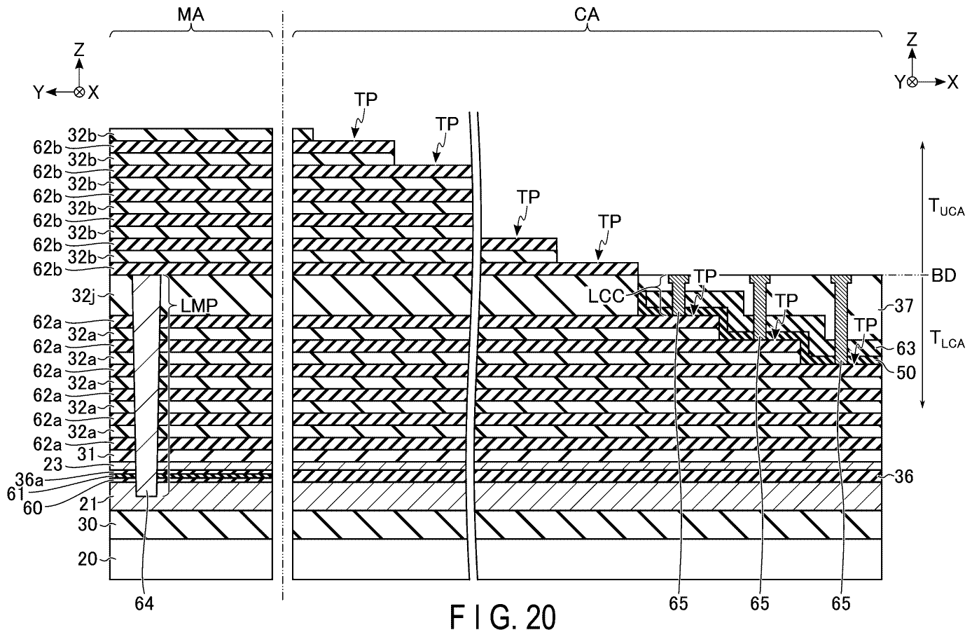

Next, as shown in FIG. 20, staircase shaping of the upper tier T_{UCA} is executed (step ST109). By the processing of step ST109, a staircase structure including a plurality of terrace portions TP of a plurality of sacrificial members 62b of the upper tier T_{UCA} is formed. The terrace portion TP of a sacrificial member 62b corresponds to a portion that does not overlap one or more upper sacrificial members 62b among the sacrificial members 62b. Further, by the present step, the upper surface of the insulating layer 37 and the upper surfaces of the sacrificial members 65 are exposed.

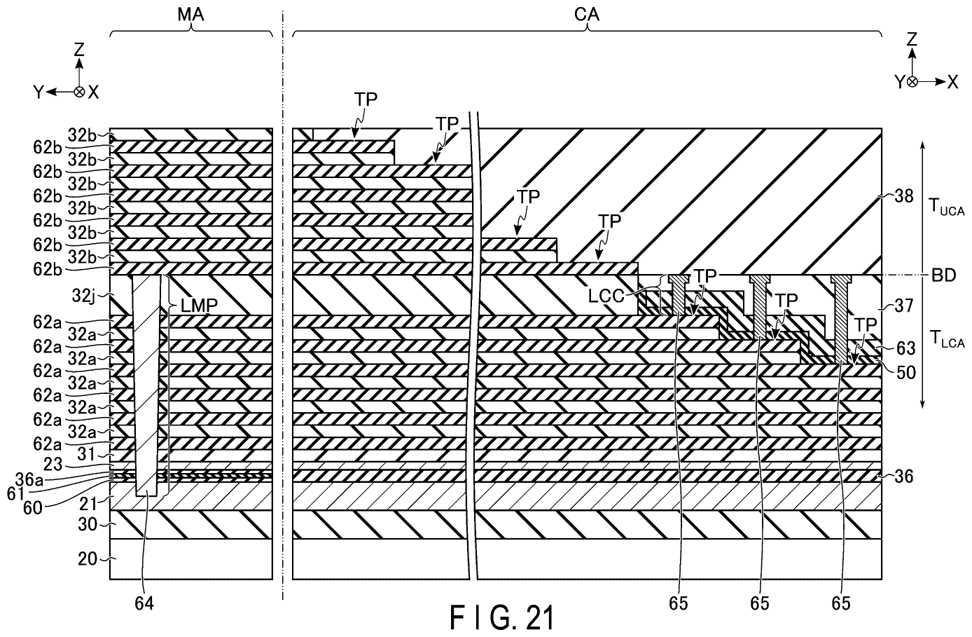

Next, as shown in FIG. 21, embedding and flattening step differences of the upper tier T_{UCA} are executed (step ST110). Specifically, first, an insulating layer 38 is formed such that the staircase structure included in the upper tier T_{UCA} is embedded. Then, part of the insulating layer 38 is removed by, for example, CMP processing. Thereby, for example, the upper surface of the uppermost insulating layer 32b and the upper surface of the insulating layer 38 are aligned (flattened). In a case where a member to be used as a hard mask was formed in the processing of step ST108, this member (hard mask) is removed by the processing of step ST110.

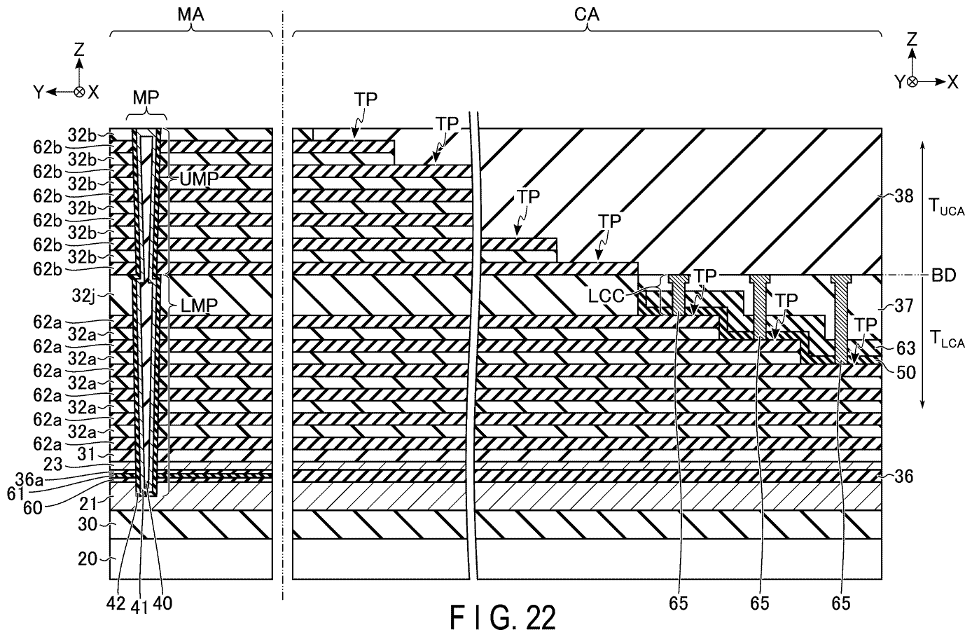

Next, as shown in FIG. 22, UMP processing and MP formation are executed (step ST111). Specifically, first, a plurality of holes corresponding to the upper memory pillars UMP are formed such that the hole penetrates the sacrificial members 62b and the insulating layers 32b and the bottom of the hole reaches the sacrificial member 64 in the associated lower memory pillar LMP. Then, the sacrificial members 64 formed in the holes corresponding to the lower memory pillars LMP are removed via the holes corresponding to the upper memory pillars UMP. Then, a stacked film 42, a semiconductor film 41, and a core member 40 are formed in each hole corresponding to the set of the upper memory pillar UMP and the lower memory pillar LMP (that is, a memory pillar MP). After that, an insulating layer 33 is formed on the uppermost insulating layer 32b and the insulating layer 38.

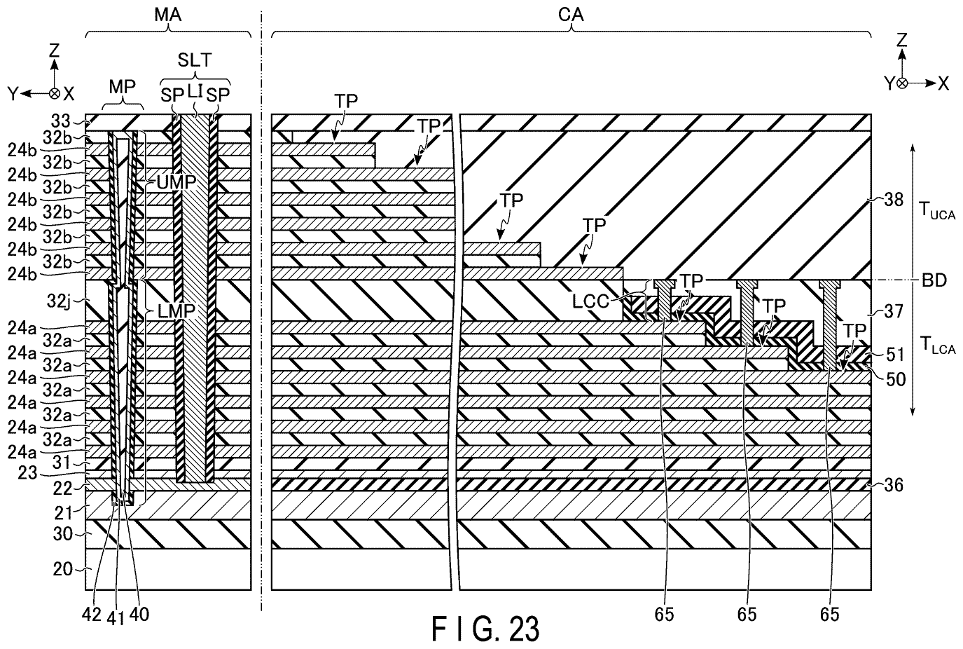

Next, the structure shown in FIG. 23 is formed by the pieces of processing of steps ST112, ST113, and ST114 being executed in this order.

In the processing of step ST112, SLT processing is executed. Specifically, slits corresponding to the members SLT are formed such that the slit penetrates the sacrificial members 62a, 62b, and 63, the semiconductor layer 23, the insulating layers 31, 32a, 32b, 32j, 33, and 36a, and the insulating film 50 and the bottom of the slit reaches the sacrificial member 61.

In the processing of step ST113, SL replacement and WL replacement are executed. Specifically, first, the insulating layers 60 and 36a and the sacrificial member 61 of the memory area MA are replaced with a semiconductor layer 22 by SL replacement. Then, by WL replacement, the sacrificial members 62a and 62b of the memory area MA and the contact area CA are replaced with conductive layers 24a and 24b, respectively.

In the SL replacement, first, an insulating film is formed on the side surface of the opened slit, and the insulating film at the bottom of the slit is removed. Then, the sacrificial member 61 is removed via the slit corresponding to the member SLT by wet etching. Subsequently, the insulating layers 60 and 36a are removed via the slit corresponding to the member SLT by wet etching. At this time, in each memory pillar MP, also the stacked film 42 located in the same layer as the sacrificial member 61 is removed simultaneously. Then, a semiconductor layer 22 is embedded in the areas (spaces) where the insulating layers 60 and 36a and the sacrificial member 61 have been removed. After that, the excess semiconductor layer 22 is removed on the side surface of the slit corresponding to the member SLT and above the insulating layer 33.

In the WL replacement, first, the insulating film on the side surface of the slit is removed. Then, the sacrificial members 62a, 62b, and 63 are removed via the slit corresponding to the member SLT by wet etching. Then, conductive layers 24 are embedded in the areas (spaces) where the sacrificial members 62a and 62b have been removed. The materials corresponding to the conductive layer 24 are formed also in the area where the sacrificial member 63 has been removed. After that, the excess conductive layer 24 is removed on the side surface and the bottom surface of the slit corresponding to the member SLT and above the insulating layer 33. At this time, also the conductive material of the conductive layer 24 formed in the area where the sacrificial member 63 has been removed is removed. After that, an insulating member 53 is embedded in the space where the sacrificial member 63 has been removed. Thereby, a structure corresponding to the insulating film 51 is formed. Details of the present processing will be described later.

In the processing of step ST114, SLT member embedding is executed. Specifically, first, an insulating film corresponding to the spacer SP is formed. Then, the insulating film at the bottom of the slit corresponding to the member SLT is removed. Then, a conductive member LI is formed such that each slit is embedded. After that, the excess conductive member LI is removed above the insulating layer 33.

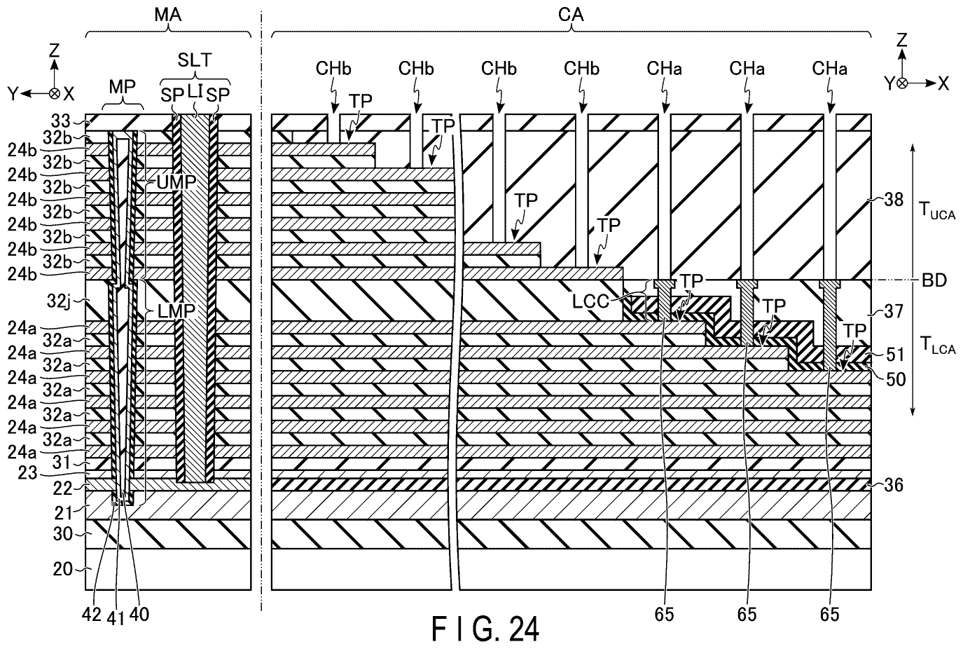

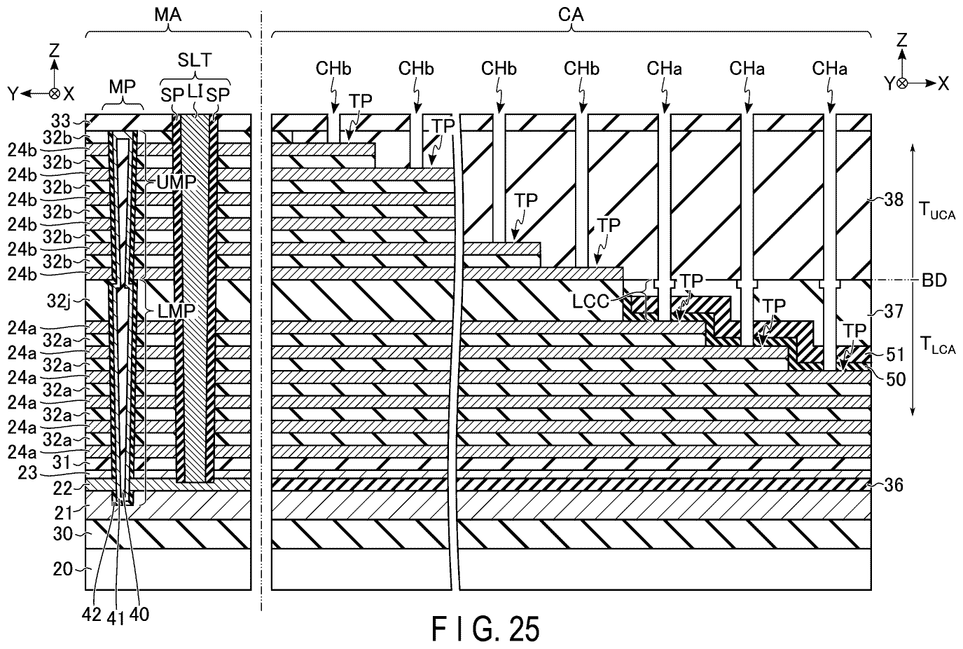

Next, UCC processing and LCC sacrificial member removal are executed (step ST115). Specifically, first, as shown in FIG. 24, pluralities of contact holes CHa and CHb are formed. The contact holes CHa are associated with the upper contact plugs UCC of the contact plugs CCa, and are formed to penetrate the insulating layers 33 and 38. The bottom of each contact hole CHa reaches an upper portion of the sacrificial member 65 associated with the lower contact plug LCC of the contact plug CCa. The contact holes CHb are associated with the contact plugs CCb, and are formed to penetrate the insulating layers 33 and 38. The bottom of each contact hole CHb reaches the terrace portion TP of the conductive layer 24b associated with the contact plug CCb. Then, as shown in FIG. 25, the sacrificial members 65 corresponding to the lower contact plugs LCC are removed via the contact holes CHa. Details of the present processing will be described later.

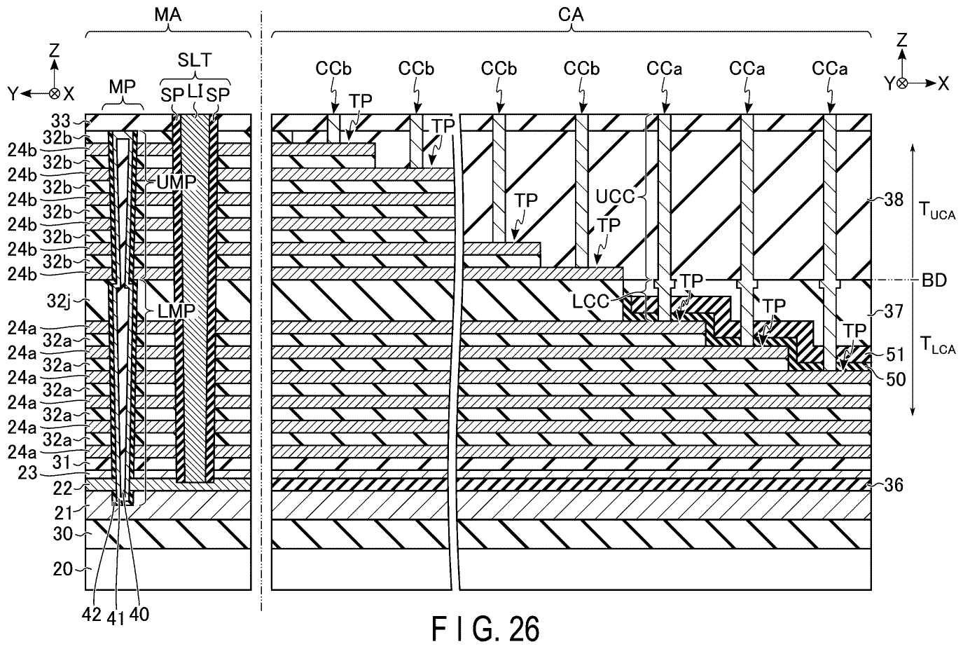

Next, as shown in FIG. 26, CC conductive member embedding is executed (step ST116). Specifically, conductive members are formed such that each of the contact holes CHa and the contact holes CHb is embedded. Then, the excess conductive member is removed outside the contact holes CHa and CHb. Thereby, structures corresponding to the contact plugs CCa and structures corresponding to the contact plugs CCb are formed.

By the processing described above being executed, the structure of the memory cell array 10 described using FIGS. 3 to 11 is completed.

### (1: Details of Step ST107)

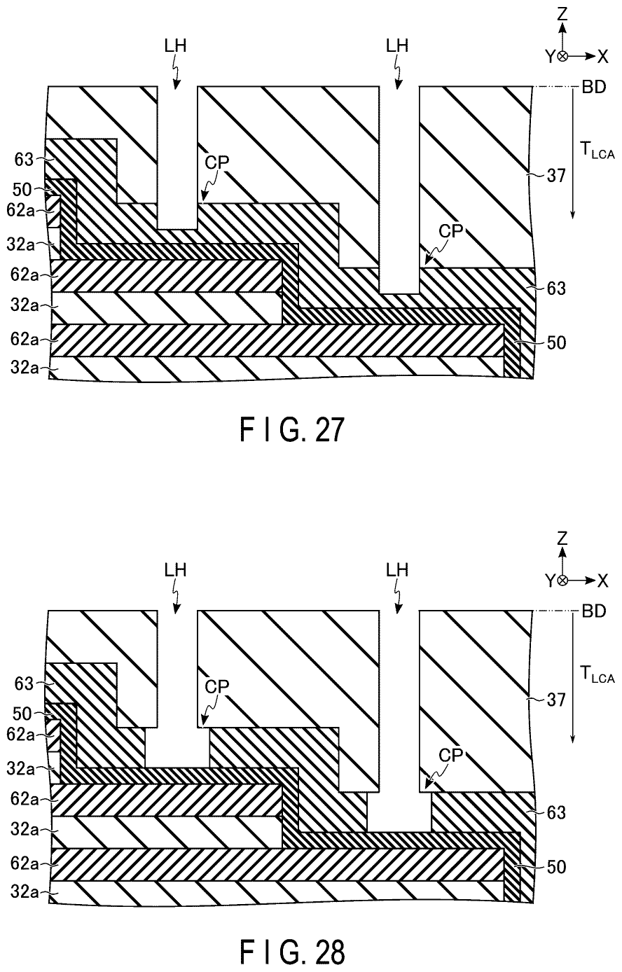

Details of step ST107 will now be described. Each of FIGS. 27, 28, 29, 30, and 31 is a cross-sectional view showing an example of a cross-sectional structure in the manufacturing process of the memory device 1 in step ST107. Each of FIGS. 27 to 31 shows an area corresponding to the area shown in FIG. 8. Hereinafter, a hole used to form the lower contact plug LCC is referred to as a “contact hole LH”.

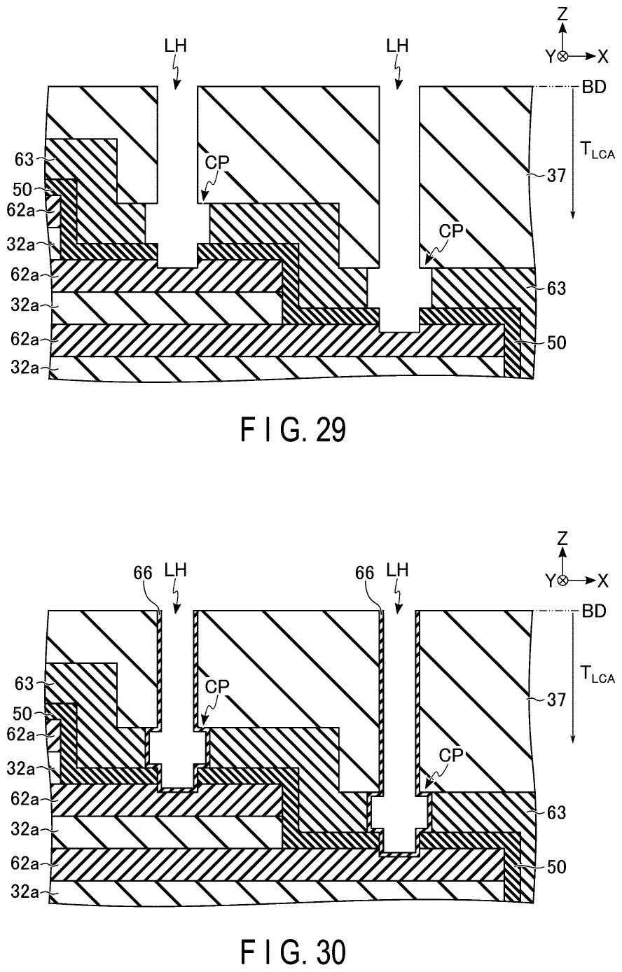

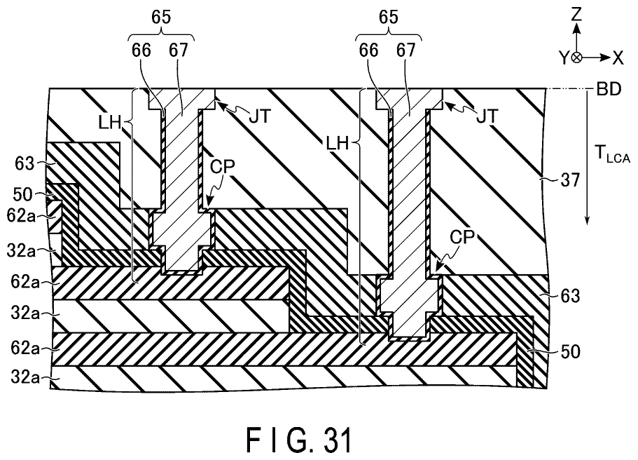

In the processing of step ST107, first, as shown in FIG. 27, a plurality of contact holes LH are formed by anisotropic etching processing such as RIE such that the contact hole LH penetrates the insulating layer 37 and the bottom of the contact hole LH reaches the sacrificial member 63. At this time, the sacrificial member 63 is used as a stopper film. Next, as shown in FIG. 28, part of the sacrificial member 63 is selectively removed via each contact hole LH by, for example, wet etching processing using phosphoric acid or the like. Thereby, a space corresponding to the crossing portion CP of the contact plug CCa is formed. Next, as shown in FIG. 29, by anisotropic etching processing such as RIE, the bottom of each contact hole LH is processed to penetrate the insulating film 50 and reach the sacrificial member 62a. Next, as shown in FIG. 30, a sacrificial film 66 is formed in each contact hole LH such that the contact hole LH is not completely embedded. The sacrificial film 66 contains, for example, silicon oxide. Next, as shown in FIG. 31, a space corresponding to the joint portion JT is formed in an upper portion of each contact hole LH, and an inside of the contact hole LH is embedded with a sacrificial member 67. The shape corresponding to the joint portion JT is formed by, for example, embedding part of the sacrificial member 67 in the contact hole LH and then using wet etching to expand an upper portion of the contact hole LH. After that, the remaining portion of the sacrificial member 67 is embedded in the contact hole LH. The sacrificial member 67 contains, for example, amorphous silicon.

### (2: Details of Step ST113)

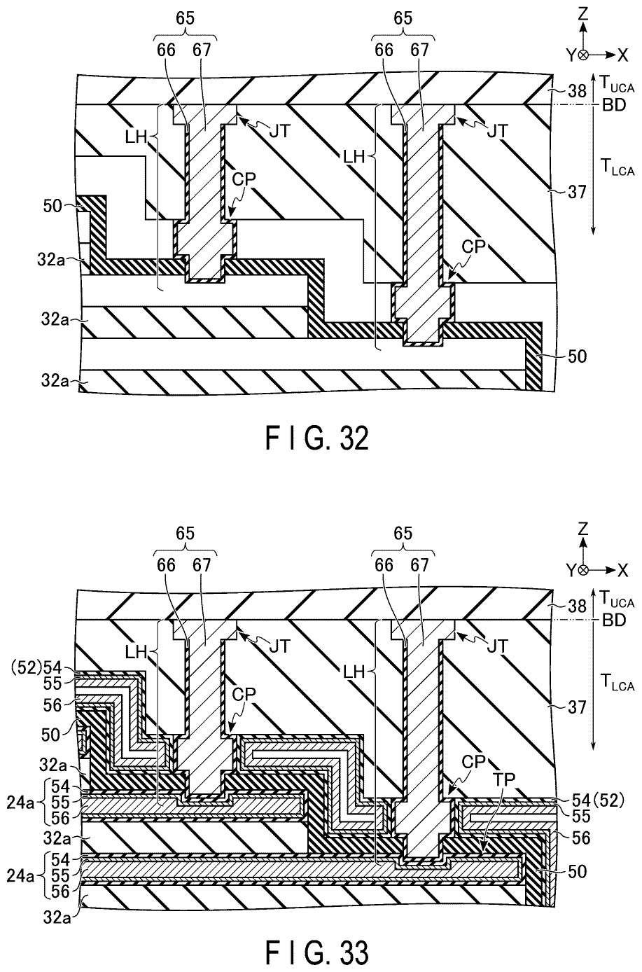

Details of step ST113 will now be described. Each of FIGS. 32, 33, 34, and 35 is a cross-sectional view showing an example of a cross-sectional structure in the manufacturing process of the memory device 1 in step ST113. Each of FIGS. 32 to 35 shows an area corresponding to the area shown in FIG. 8.

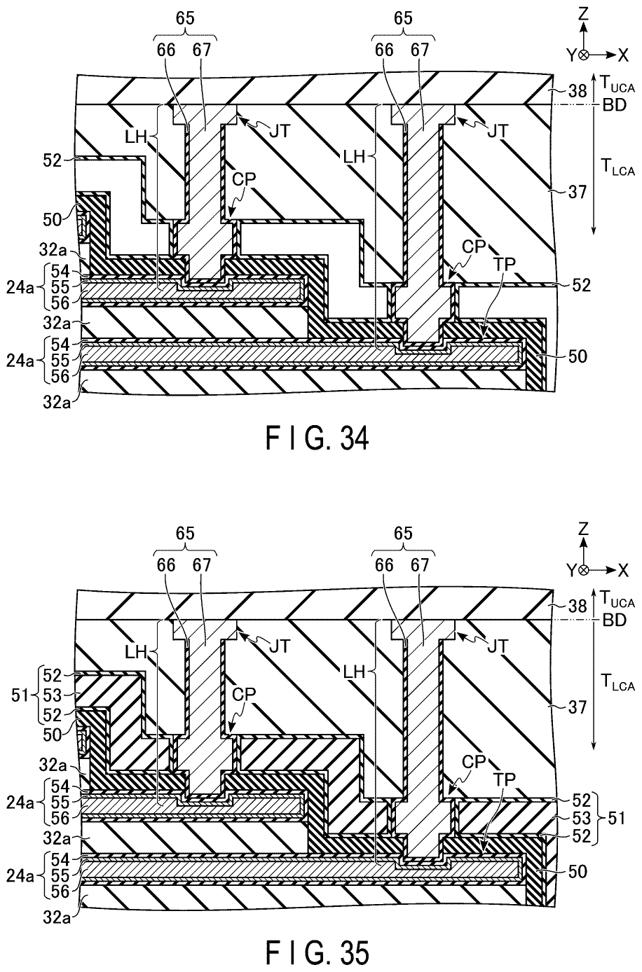

In the WL replacement of step ST113, in a case where the sacrificial members 62a, 62b, and 63 are removed via the slit corresponding to the member SLT, the structure shown in FIG. 32 is formed. In the space where the sacrificial member 63 has been removed, the side surface of the sacrificial film 66 in each contact hole LH is exposed. Next, conductive layers 24 are embedded in the areas (spaces) where the sacrificial members 62a and 62b have been removed. At this time, for the area where the sacrificial member 63, which is thicker than each of the sacrificial members 62a and 62b, has been removed, in the large space formed by the sacrificial member 63 being removed, as shown in FIG. 33, a high dielectric film 54, a barrier metal 55, and a conductive member 56 are formed in this order such that the space is not completely embedded. The high dielectric film 54 formed in the space where the sacrificial member 63 has been removed corresponds to the high dielectric film 52 shown in FIG. 8. After that, the excess conductive layer 24 is removed on the side surface of the slit corresponding to the member SLT, and on other places; as a result, as shown in FIG. 34, the barrier metal 55 and the conductive member 56 formed in the space where the sacrificial member 63 has been removed are removed via the slit corresponding to the member SLT. After that, as shown in FIG. 35, an insulating member 53 is embedded in an inside of the high dielectric film 52 in the area where the sacrificial member 63 has been removed; thus, a structure corresponding to the insulating film 51 shown in FIG. 8, etc. is completed.

### (3: Details of Step ST115)

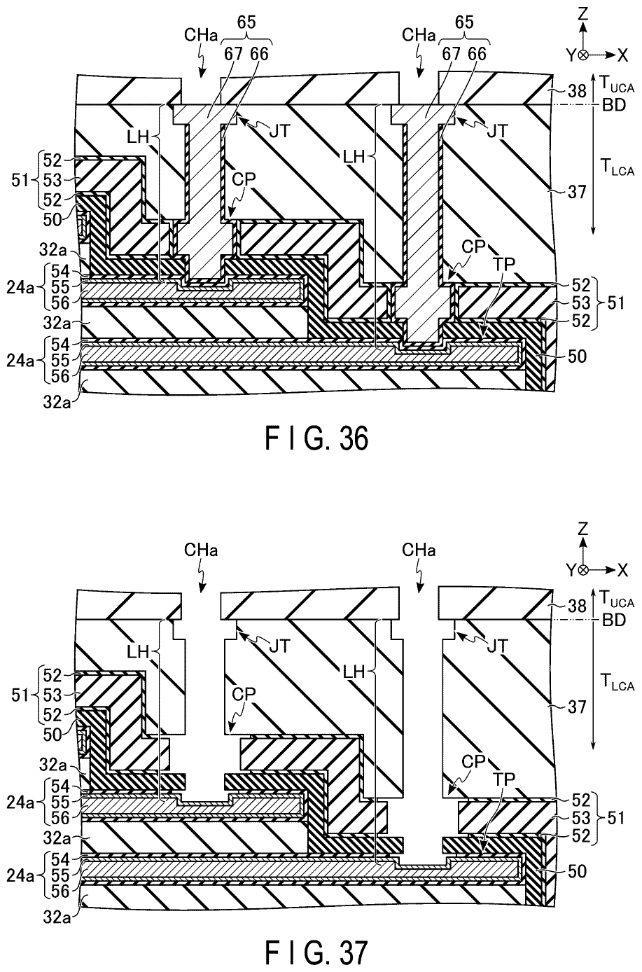

Details of step ST115 will now be described. Each of FIGS. 36 and 37 is a cross-sectional view showing an example of a cross-sectional structure in the manufacturing process of the memory device 1 in step ST115. Each of FIGS. 36 and 37 shows an area corresponding to the area shown in FIG. 8.

In the processing of step ST115, first, as shown in FIG. 36, a plurality of contact holes CHa are formed such that the contact hole CHa penetrates the insulating layer 38 and the bottom of the contact hole CHa reaches the sacrificial member 67 in the associated contact hole LH. Next, as shown in FIG. 37, the sacrificial films 66 and the sacrificial members 67 in the contact holes LH are selectively removed via the contact holes CHa. At this time, also part of the high dielectric film 52 in the insulating film 51 and parts of the high dielectric films 54 in the conductive layers 24a are removed via the contact holes LH. Thereby, the barrier metal 55 in the conductive layer 24a is exposed at the bottom of each contact hole LH. Further, the high dielectric film 52 in the insulating film 51 and the high dielectric films 54 in the conductive layers 24a are recessed in the planar direction via the contact holes LH. As a result, spaces corresponding to the first portion, the second portion, and the fourth portion of the barrier metal 57 of the contact plug CCa are formed in each contact hole LH.

### <1-3> Advantageous Effects of the First Embodiment

Next, advantageous effects of the memory device 1 according to the first embodiment are described.

In a three-dimensional stacked NAND flash memory, the degree of difficulty of an etching process for forming memory pillars MP, members SLT, support pillars HR, and contact plugs CC has been increased with increase in the number of word lines WL(wiring layers) stacked. Further, in contact hole processing for forming contact plugs CC, there are height differences according to the positions of the wiring layers of the connection destinations. In a case where the height difference of contact hole processing is increased with increase in the number of word lines WL stacked, the contact hole may penetrate according to the position of the wiring layer.

In this regard, the memory device 1 according to the first embodiment has a structure in which the contact plug CC is formed separately in two tiers (the lower tier T_{LCA} and the upper tier T_{UCA}). By the contact plug CC being divided into two tiers, the maximum height of contact hole processing in each tier is reduced, and the height difference of contact hole processing is reduced. Thereby, the controllability of contact hole processing in each tier is improved, and the occurrence of penetration of contact holes is suppressed. As a result, the occurrence of defects due to penetration of contact holes is suppressed, and the yield of memory devices 1 is improved. Thus, the memory device 1 according to the first embodiment can reduce the manufacturing cost of the memory device 1. Note that advantages of the structure of the stopper portion of the lower tier T_{LCA} will be described in detail in a fifth embodiment.

### <1-4> Modification Examples of the First Embodiment

The memory device 1 according to the first embodiment can be variously modified. Hereinbelow, a first modification example, a second modification example, a third modification example, and a fourth modification example of the first embodiment are described in order.

### First Modification Example of the First Embodiment

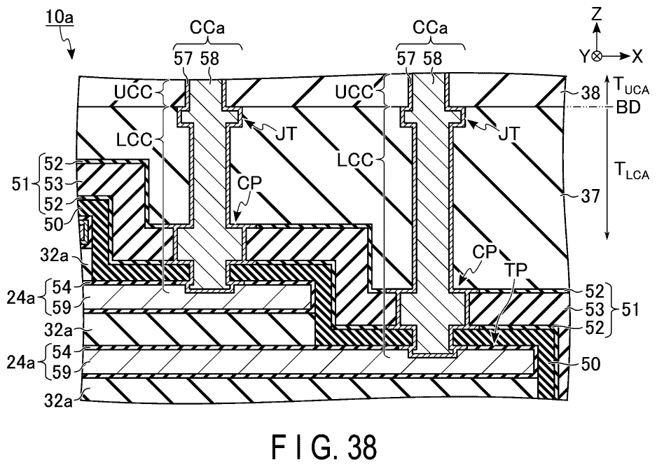

FIG. 38 is a cross-sectional view showing an example of a cross-sectional structure of a contact area CA of a memory cell array 10a in a first modification example of the first embodiment. As shown in FIG. 38, the conductive layer 24a of the memory cell array 10a has a configuration in which, in the memory cell array 10, the barrier metal 55 of the conductive layer 24a is omitted and the conductive member 56 is replaced with a conductive member 59. The conductive member 59 is provided on an inside of the high dielectric film 54. The conductive member 59 has a portion in contact with the high dielectric film 54 and a portion in contact with the barrier metal 57 of the contact plug CCa. The conductive member 59 contains, for example, molybdenum (Mo). As in the first modification example of the first embodiment, a conductive layer 24a not including the barrier metal 55 may be used as a stacked wiring line.

### Second Modification Example of the First Embodiment

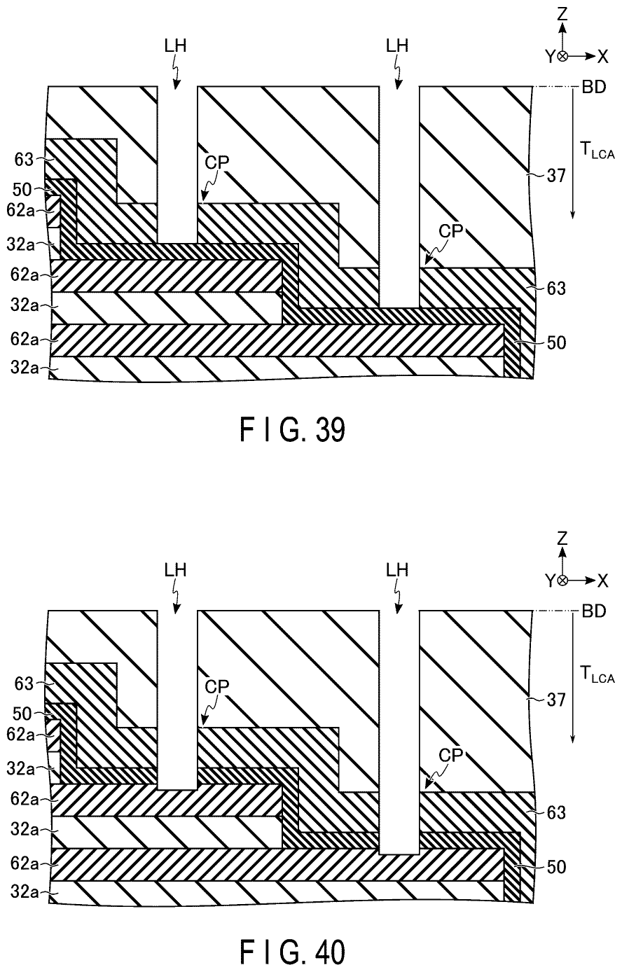

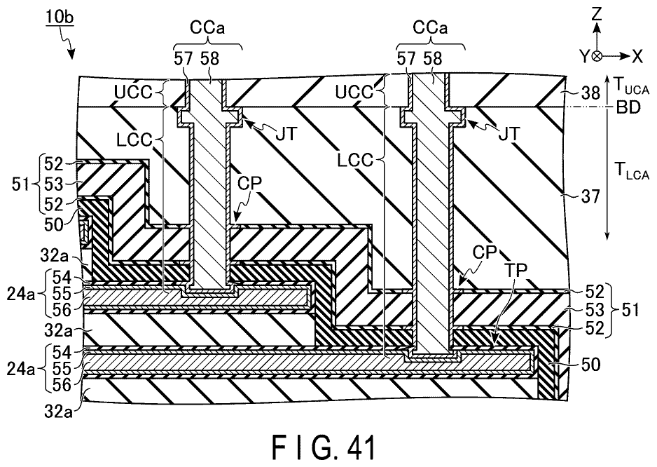

Each of FIGS. 39 and 40 is a cross-sectional view showing an example of a cross-sectional structure in the manufacturing process of a memory device 1 in a second modification example of the first embodiment. FIG. 41 is a cross-sectional view showing an example of a cross-sectional structure of a contact area CA of a memory cell array 10b in the second modification example of the first embodiment. In the second modification example of the first embodiment, the content of the processing of step ST107 is different. In the second modification example of the first embodiment, in the processing of step ST107, anisotropic etching processing is used in removal of the sacrificial member 63 at the bottom of each contact hole LH.

Specifically, in the processing of step ST107 of the second modification example of the first embodiment, first, a plurality of contact holes LH are formed by anisotropic etching processing such as RIE such that the contact hole LH penetrates the insulating layer 37 and the bottom of the contact hole LH reaches the sacrificial member 63. Then, as shown in FIG. 39, by anisotropic etching processing such as RIE, the sacrificial member 63 at the bottom of each contact hole LH is selectively removed. Then, as shown in FIG. 40, like in the first embodiment, by anisotropic etching processing such as RIE, the bottom of each contact hole LH is processed to penetrate the insulating film 50 and reach the sacrificial member 62a. Thus, in the second modification example of the first embodiment, in the contact hole LH, the side surface of the portion penetrating (passing through) the insulating layer 37, the side surface of the portion penetrating (passing through) the sacrificial member 63 (the crossing portion CP), and the side surface of the portion penetrating (passing through) the insulating film 50 are substantially aligned.

After that, the processing of steps ST108 to ST116 is executed like in the first embodiment; then, the structure shown in FIG. 41 is formed. The diameter (XY cross-sectional area) of the crossing portion CP of the contact plug CCa is smaller in the second modification example of the first embodiment than in the first embodiment. Further, the barrier metal 57 of the contact plug CCa of the memory cell array 10b can have, like in the first embodiment, a first portion, a second portion, and a fourth portion spreading in the planar direction.

### Third Modification Example of the First Embodiment

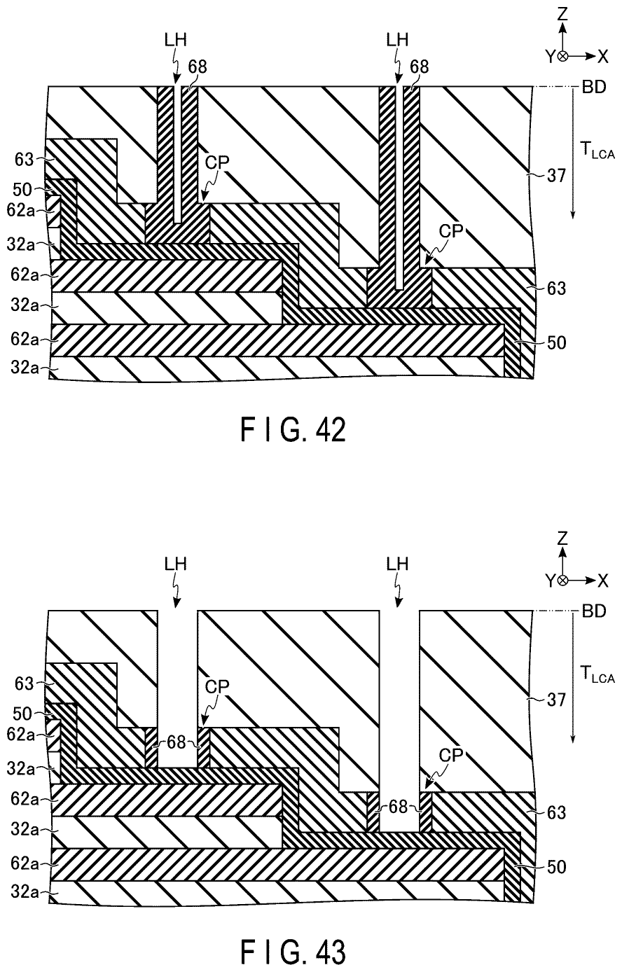

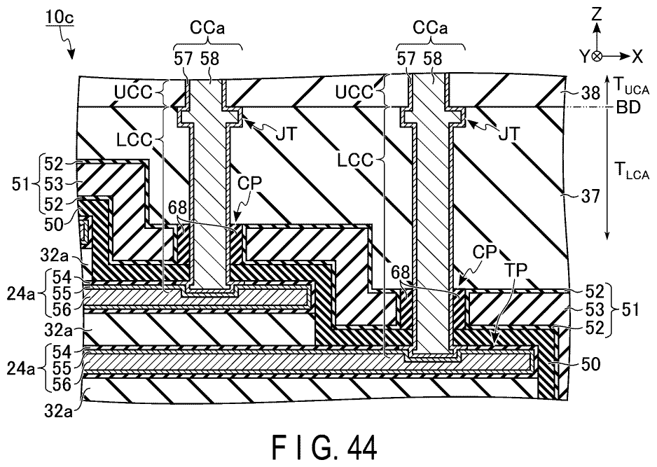

Each of FIGS. 42 and 43 is a cross-sectional view showing an example of a cross-sectional structure in the manufacturing process of a memory device 1 in a third modification example of the first embodiment. FIG. 44 is a cross-sectional view showing an example of a cross-sectional structure of a contact area CA of a memory cell array 10c in the third modification example of the first embodiment. In the third modification example of the first embodiment, the content of the processing of step ST107 is different. In the third modification example of the first embodiment, an insulating film is embedded in a portion of an inside of the contact hole LH that is recessed by isotropic etching processing such as wet etching processing.

Specifically, in the processing of step ST107 of the second modification example of the first embodiment, first, a plurality of contact holes LH are formed by anisotropic etching processing such as RIE such that the contact hole LH penetrates the insulating layer 37 and the bottom of the contact hole LH reaches the sacrificial member 63. Next, like in the first embodiment, by wet etching processing using phosphoric acid or the like, part of the sacrificial member 63 is selectively removed via each contact hole LH. Then, as shown in FIG. 42, an insulating film 68 is formed in each contact hole LH. At this time, the insulating film 68 is formed such that each contact hole LH is not completely embedded. The insulating film 68 is, for example, silicon oxide. Next, as shown in FIG. 43, the insulating film 68 provided on the side surface of the contact hole LH is removed. Thereby, in the crossing portion CP of each contact hole LH, the insulating film 68 remains in a portion spreading in the planar direction (the space where the sacrificial member 63 has been removed). After that, like in the first embodiment, by anisotropic etching processing such as RIE, the bottom of each contact hole LH is processed to penetrate the insulating film 50 and reach the sacrificial member 62a. Thus, in the third modification example of the first embodiment, in the contact hole LH, the side surface of the portion penetrating the insulating layer 37, the side surface of the portion penetrating the insulating film 68 (the crossing portion CP), and the side surface of the portion penetrating the insulating film 50 are substantially aligned.

After that, the processing of steps ST108 to ST116 is executed like in the first embodiment; then, the structure shown in FIG. 44 is formed. The diameter (XY cross-sectional area) of the crossing portion CP of the contact plug CCa is smaller in the third modification example of the first embodiment than in the first embodiment. Further, the barrier metal 57 of the contact plug CCa of the memory cell array 10c has, like in the first embodiment, a fourth portion spreading in the planar direction. On the other hand, unlike in the first embodiment, the barrier metal 57 of the contact plug CCa of the memory cell array 10c does not have a first portion or a second portion spreading in the planar direction.

### Fourth Modification Example of the First Embodiment

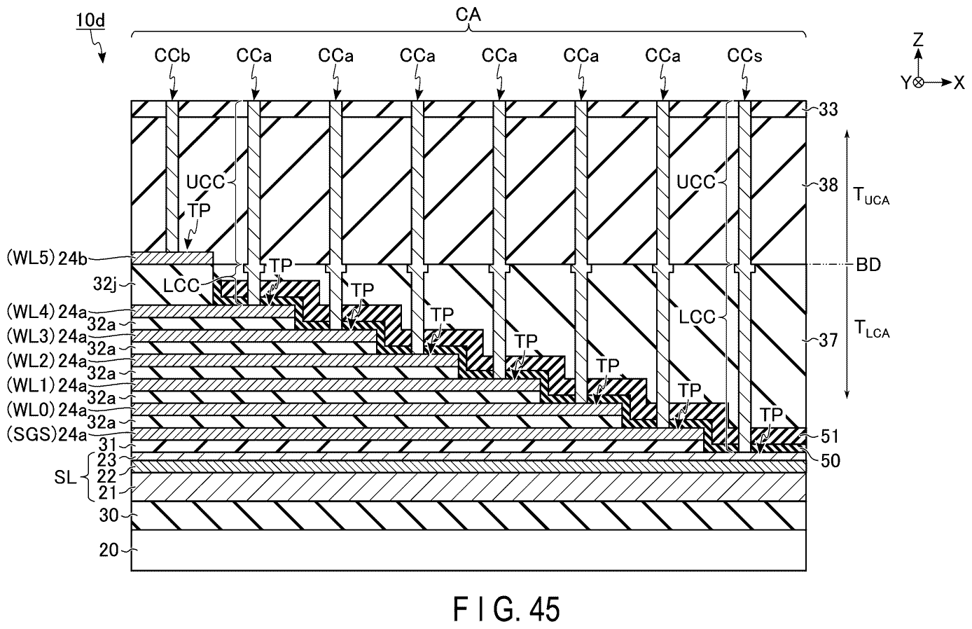

FIG. 45 is a cross-sectional view showing an example of a cross-sectional structure of a contact area CA of a memory cell array 10d in a fourth modification example of the first embodiment. As shown in FIG. 45, in the memory cell array 10d, in the contact area CA, a similar configuration to the source line SL in the memory area MA is provided, and a contact plug CCs is connected to the semiconductor layer 23. The contact plug CCs has a similar configuration to the contact plug CCa. The bottom of the contact plug CCs is, for example, connected to the semiconductor layer 23. Thereby, the memory device 1 can control the voltage of the source line SL via the contact plug CCs. The memory device 1 according to the fourth modification example of the first embodiment can control the voltage of the source line SL via the contact plug CCs in the contact area CA. In this case, the conductive member LI in each member SLT can be omitted.

### <2> Second Embodiment

A second embodiment relates to a case where the stacked wiring lines in the first embodiment are provided in three tiers. Details of the second embodiment will now be described with emphasis on differences from the first embodiment.

### <2-1> Configuration

First, a configuration of a memory device 1 according to the second embodiment is described.

### <2-1-1> Cross-Sectional Structure of the Memory Area MA

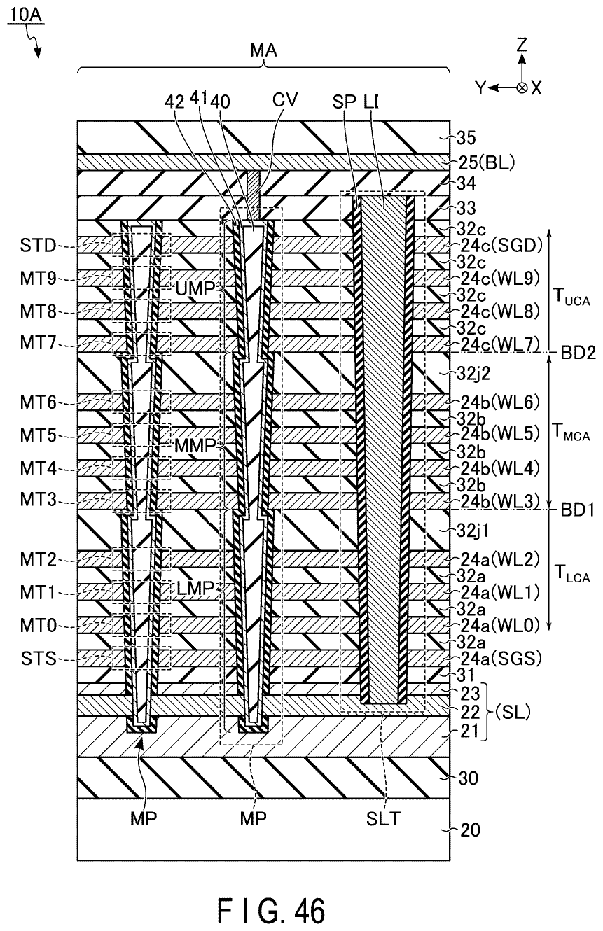

FIG. 46 is a cross-sectional view showing an example of a cross-sectional structure of a memory area MA of a memory cell array 10A included in the memory device 1 according to the second embodiment. As shown in FIG. 46, the memory cell array 10A includes stacked wiring lines formed separately in three tiers.

In the second embodiment, the tier on the lower side among the three tiers of the stacked wiring lines is referred to as a “lower tier T_{LCA}”. The tier on the upper side among the three tiers of the stacked wiring lines is referred to as an “upper tier T_{UCA}”. The tier between the lower tier T_{LCA} and the upper tier T_{UCA} among the three tiers of the stacked wiring lines is referred to as a “middle tier T_{MCA}”. The boundary between the lower tier T_{LCA} and the middle tier IMCA is referred to as a “boundary BD1”. The boundary between the middle tier T_{MCA} and the upper tier T_{UCA} is referred to as a “boundary BD2”.

In the memory cell array 10A, the stacked wiring lines (the conductive layers 24) are arranged over the lower tier T_{LCA}, the middle tier T_{MCA}, and the upper tier T_{UCA}.

In the second embodiment, the conductive layer 24 and the insulating layer 32 included in the lower tier T_{LCA} are referred to as a conductive layer 24a and an insulating layer 32a, respectively. The conductive layer 24 and the insulating layer 32 included in the middle tier T_{MCA} are referred to as a conductive layer 24b and an insulating layer 32b, respectively. The conductive layer 24 and the insulating layer 32 included in the upper tier T_{UCA} are referred to as a conductive layer 24c and an insulating layer 32c, respectively. In the present example, the boundary BD1 is located between the conductive layer 24a functioning as the word line WL2 and the conductive layer 24b functioning as the word line WL3. In other words, the boundary BD1 is located between the uppermost conductive layer 24a and the lowermost conductive layer 24b. The boundary BD2 is located between the conductive layer 24b functioning as the word line WL6 and the conductive layer 24c functioning as the word line WL7. In other words, the boundary BD2 is located between the uppermost conductive layer 24b and the lowermost conductive layer 24c.

Further, in the second embodiment, the insulating layer 32 (32a) corresponding to a position between the uppermost conductive layer 24a and the lowermost conductive layer 24b, that is, the boundary BD1 between the lower tier T_{LCA} and the middle tier IMCA is referred to as an “insulating layer 32j1”. The insulating layer 32 (32b) corresponding to a position between the uppermost conductive layer 24b and the lowermost conductive layer 24c, that is, the boundary BD2 between the middle tier T_{MCA} and the upper tier T_{UCA} is referred to as an “insulating layer 32j2”. The thickness in the Z direction of each of the insulating layers 32j1 and 32j2 is larger than that of each of the other insulating layers 32 (32a, 32b, and 32c). That is, the distance in the Z direction between the conductive layers 24a and 24b adjacent via the boundary BD1 is larger than the distance in the Z direction between two conductive layers 24 (24a, 24b, or 24c) not adjacent via the boundary BD1 or BD2. The distance in the Z direction between the conductive layers 24b and 24c adjacent via the boundary BD2 is larger than the distance in the Z direction between two conductive layers 24 (24a, 24b, or 24c) not adjacent via the boundary BD1 or BD2. Note that each of the insulating layers 32j1 and 32j2 may include a plurality of insulating layers.

In the second embodiment, each memory pillar MP is formed separately in three tiers. Specifically, each memory pillar MP includes a lower memory pillar LMP, a middle memory pillar MMP, and an upper memory pillar UMP connected in the Z direction. The lower memory pillar LMP, the middle memory pillar MMP, and the upper memory pillar UMP are included in the lower tier T_{LCA}, the middle tier T_{MCA}, and the upper tier T_{UCA}, respectively. The position of the boundary between the lower memory pillar LMP and the middle memory pillar MMP substantially coincides with the boundary BD1. The position of the boundary between the middle memory pillar MMP and the upper memory pillar UMP substantially coincides with the boundary BD2. The upper memory pillar UMP penetrates (passes through) the four conductive layers 24c (the word lines WL7 to WL9 and the select gate line SGD) and the four insulating layers 32c, and the bottom of the upper memory pillar UMP is connected to the upper end of the middle memory pillar MMP, for example. The middle memory pillar MMP penetrates (passes through) the four conductive layers 24b (the word lines WL3 to WL6), the three insulating layers 32b, and the insulating layer 32j2, and the bottom of the middle memory pillar MMP is connected to the upper end of the lower memory pillar LMP, for example. The lower memory pillar LMP penetrates (passes through) the four conductive layers 24a (the select gate line SGS and the word lines WL0 to WL2), the three insulating layers 32a, the insulating layers 31 and 32j1, and the semiconductor layers 22 and 23, and the bottom of the lower memory pillar LMP is located in the semiconductor layer 21, for example.

Each of the core member 40, the semiconductor film 41, and the stacked film 42 is continuously provided in the lower memory pillar LMP, the middle memory pillar MMP, and the upper memory pillar UMP. Each of the lower memory pillar LMP, the middle memory pillar MMP, and the upper memory pillar UMP has, for example, a tapered shape (forward tapered shape) in which the diameter (XY cross-sectional area) of the upper end is larger than the diameter (XY cross-sectional area) of the lower end. Thus, each of the boundaries BD1 and BD2 can be found by observing the cross-sectional shape of the memory pillar MP. Each of the lower memory pillar LMP, the middle memory pillar MMP, and the upper memory pillar UMP may be referred to as a sub-pillar of the memory pillar MP. The lower memory pillar LMP may have a shape in which the width is widened in a portion crossing the insulating layer 32j1. The middle memory pillar MMP may have a shape in which the width is widened in a portion crossing the insulating layer 32j2.

In the second embodiment, a stacked structure corresponding to the four conductive layers 24a, the three insulating layers 32a, and the insulating layer 32j1 included in the lower tier T_{LCA} is referred to as a “lower layer stack”. A stacked structure corresponding to the four conductive layers 24b, the three insulating layers 32b, and the insulating layer 32j2 included in the middle tier T_{MCA} is referred to as a “middle layer stack”. A stacked structure corresponding to the four conductive layers 24c and the four insulating layers 32c included in the upper tier T_{UCA} is referred to as an “upper layer stack”.

### <2-1-2> Cross-Sectional Structure of the Contact Area CA

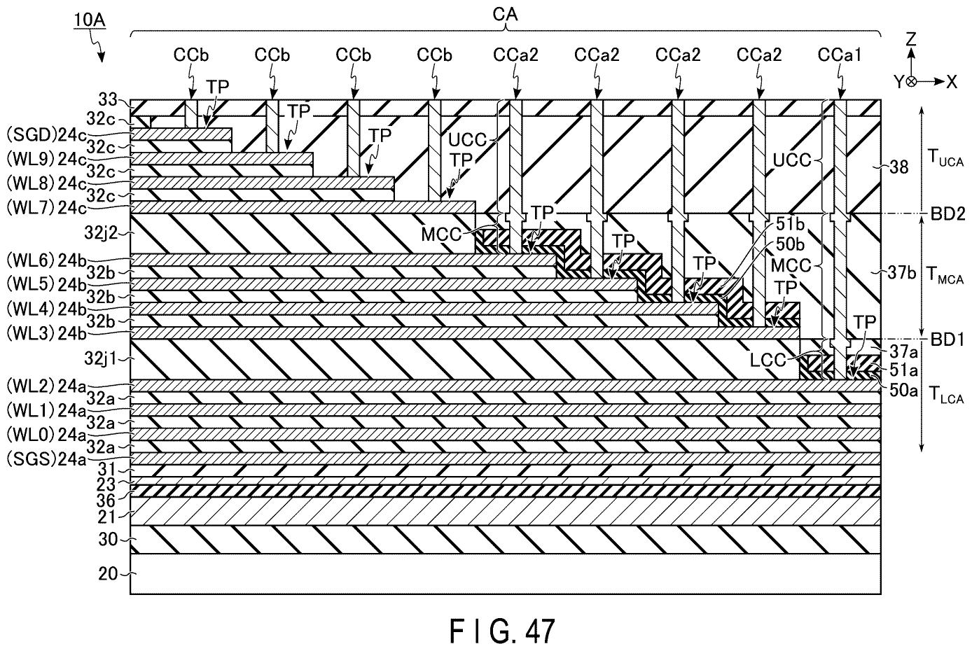

FIG. 47 is a cross-sectional view showing an example of a cross-sectional structure of a contact area CA of the memory cell array 10A included in the memory device 1 according to the second embodiment. FIG. 47 shows an XZ cross section including the contact area CA of the memory cell array 10A. As shown in FIG. 47, in the contact area CA, the memory cell array 10A includes, for example, insulating layers 37a, 37b, and 38 and insulating films 50a, 50b, 51a, and 51b. A plurality of contact plugs CC included in the memory cell array 10A include a plurality of contact plugs CCa1, a plurality of contact plugs CCa2, and a plurality of contact plugs CCb for each block BLK.

In the contact area CA, the insulating layer 37a is provided to fill the staircase portion formed by the terrace portions TP included in the lower tier T_{LCA}. In the contact area CA, the insulating layer 37b is provided to fill the staircase portion formed by the terrace portions TP included in the middle tier T_{MCA}. In the contact area CA, the insulating layer 38 is provided to fill the staircase portion formed by the terrace portions TP included in the upper tier T_{UCA}. Each of the insulating layers 37a, 37b, and 38 contains, for example, silicon oxide.

The insulating film 50a is provided such that its upper surface has step differences along the staircase shape formed by the terrace portions TP of the conductive layers 24a included in the lower tier T_{LCA}. The insulating film 50a is located below the boundary BD1. The insulating film 50b is provided such that its upper surface has step differences along the staircase shape formed by the terrace portions TP of the conductive layers 24b included in the middle tier T_{MCA}. The insulating film 50b is located between the boundaries BD1 and BD2. Each of the insulating films 50a and 50b contains, for example, silicon oxide.

The insulating film 51a is provided on the insulating film 50a to overlap the terrace portions TP of the conductive layers 24a included in the lower tier T_{LCA} in the Z direction. The upper surface of the insulating film 51a has step differences along the staircase shape formed by the terrace portions TP of the conductive layers 24a included in the lower tier T_{LCA}. The insulating film 51a is located below the boundary BD1. The insulating film 51b is provided on the insulating film 50b to overlap the terrace portions TP of the conductive layers 24b included in the middle tier T_{MCA} in the Z direction. The upper surface of the insulating film 51b has step differences along the staircase shape formed by the terrace portions TP of the conductive layers 24b included in the middle tier T_{MCA}. The insulating film 51b is located between the boundaries BD1 and BD2. Each of the insulating films 51a and 51b has a structure in which a member used as a stopper film in hole processing for contact plugs CC is replaced with an insulator. Each of the insulating films 51a and 51b contains, for example, silicon oxide. The film thickness of each of the insulating films 51a and 51b is larger than that of the conductive layer 24.

In the second embodiment, the contact plugs CCa1 are electrically connected respectively to the terrace portions TP of the conductive layers 24a included in the lower tier T_{LCA}. Each contact plug CCa1 is formed separately in three tiers. Specifically, each contact plug CCa1 includes a lower contact plug LCC, a middle contact plug MCC, and an upper contact plug UCC connected in the Z direction. The lower contact plug LCC, the middle contact plug MCC, and the upper contact plug UCC are included in the lower tier T_{LCA}, the middle tier T_{MCA}, and the upper tier T_{UCA}, respectively. The position of the boundary between the lower contact plug LCC and the middle contact plug MCC substantially coincides with the boundary BD1. The position of the boundary between the middle contact plug MCC and the upper contact plug UCC substantially coincides with the boundary BD2. In the contact plug CCa1, the upper contact plug UCC penetrates (passes through) the insulating layers 33 and 38, and the bottom of the upper contact plug UCC is connected to the upper end of the middle contact plug MCC. In the contact plug CCa1, the middle contact plug MCC penetrates (passes through) the insulating layer 37b, and the bottom of the middle contact plug MCC is connected to the upper end of the lower contact plug LCC. In the contact plug CCa1, the lower contact plug LCC penetrates (passes through) the insulating layer 37a and the insulating films 50a and 51a, and the bottom of the lower contact plug LCC is connected to the terrace portion TP of the associated conductive layer 24a.

In the second embodiment, the contact plugs CCa2 are respectively connected to the terrace portions TP of the conductive layers 24b included in the middle tier T_{MCA}. Each contact plug CCa2 is formed separately in two tiers. Specifically, each contact plug CCa2 includes a middle contact plug MCC and an upper contact plug UCC connected in the Z direction. In the contact plug CCa2, the upper contact plug UCC penetrates (passes through) the insulating layers 33 and 38, and the bottom of the upper contact plug UCC is connected to the upper end of the middle contact plug MCC. In the contact plug CCa2, the middle contact plug MCC penetrates (passes through) the insulating layer 37b and the insulating films 50b and 51b, and the bottom of the middle contact plug MCC is connected to the terrace portion TP of the associated conductive layer 24b. In the contact plug CCa2, the middle contact plug MCC may be referred to as a lower contact plug.

In the second embodiment, the contact plugs CCb are respectively connected to the terrace portions TP of the conductive layers 24c included in the upper tier T_{UCA}. Specifically, the contact plug CCb penetrates (passes through) the insulating layers 33 and 38, and the bottom of the contact plug CCb is connected to the terrace portion TP of the associated conductive layer 24c.

The configuration of the other parts of the memory device 1 according to the second embodiment is similar to that of the first embodiment.

### <2-2> Manufacturing Method

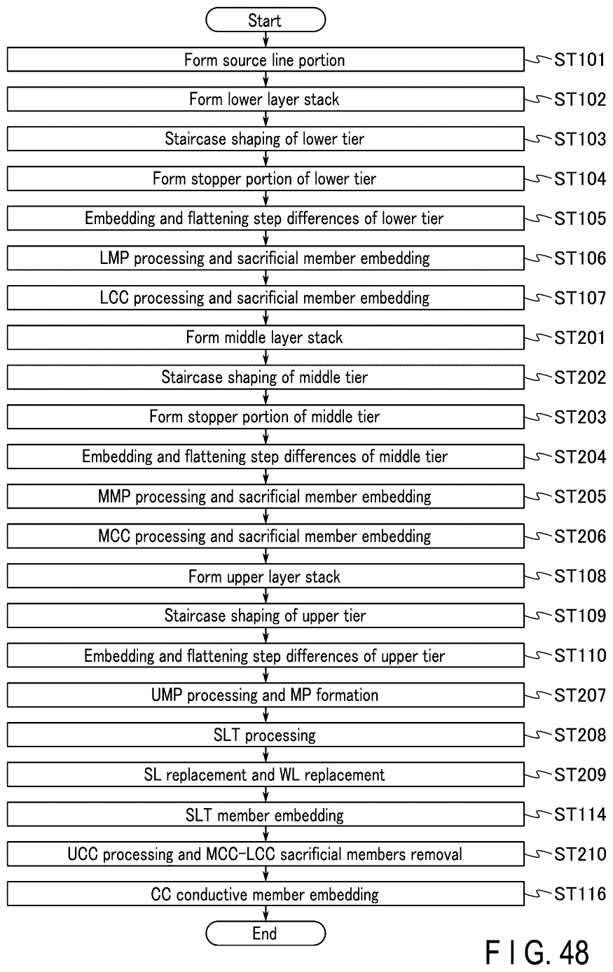

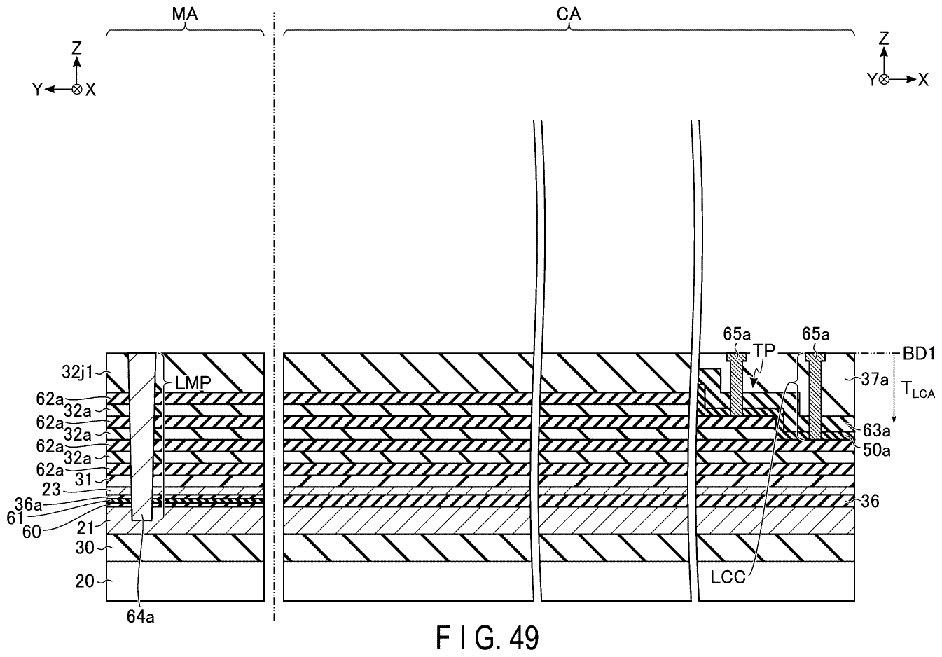

Next, as a method of manufacturing the memory device 1 according to the second embodiment, a method of forming stacked wiring lines and contact plugs CC corresponding to the memory cell array 10A is described with reference to FIG. 48 as appropriate. FIG. 48 is a flowchart showing an example of a method of manufacturing the memory device 1 according to the second embodiment. Each of FIGS. 49, 50, 51, 52, 53, 54, 55, and 56 is a cross-sectional view showing an example of a cross-sectional structure in the manufacturing process of the memory device 1 according to the second embodiment. Each of FIGS. 49 to 56 shows an area where the memory pillar MP and the member SLT are formed and part of the contact area CA.

First, like in the first embodiment, a source line portion is formed (step ST101), a lower layer stack is formed (step ST102), the staircase shaping of the lower tier T_{LCA} is executed (step ST103), a stopper portion of the lower tier T_{LCA} is formed (step ST104), embedding and flattening step differences of the lower tier T_{LCA} are executed (step ST105), LMP processing and sacrificial member embedding are executed (step ST106), and LCC processing and sacrificial member embedding are executed (step ST107). Thereby, the structure shown in FIG. 49 is formed. Note that, in the processing of steps ST101 to ST107 in the second embodiment, the insulating layers 32j and 37, the insulating film 50, and the sacrificial members 63, 64, and 65 in the first embodiment are replaced with insulating layers 32j1 and 37a, an insulating film 50a, and sacrificial members 63a, 64a, and 65a, respectively.

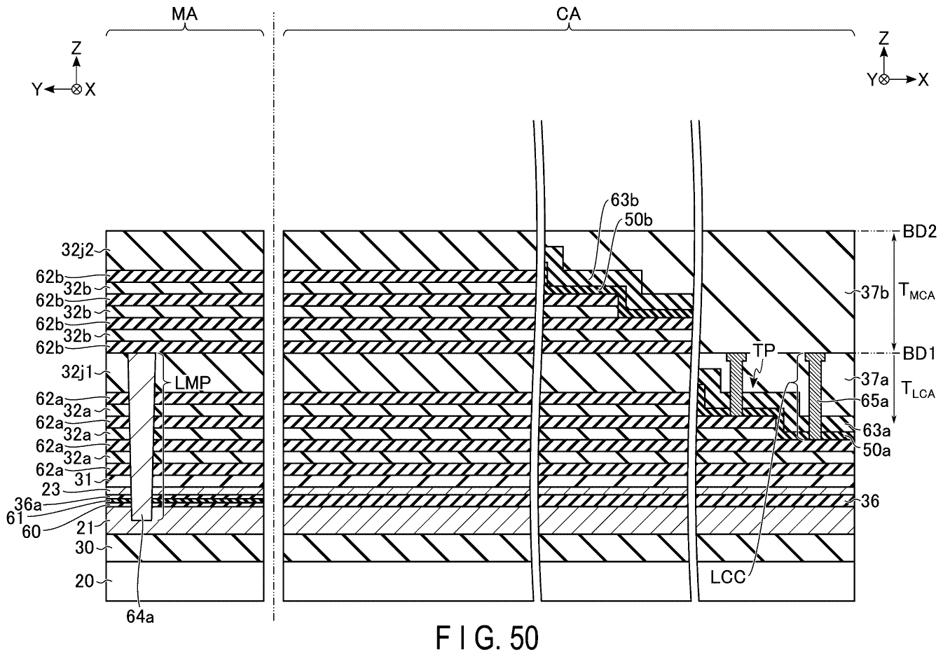

Next, the structure shown in FIG. 50 is formed by the pieces of processing of steps ST201, ST202, ST203, and ST204 being executed in this order.

In the processing of step ST201, a middle layer stack is formed. Specifically, as a middle layer stack, a plurality of sacrificial members 62b associated with a plurality of conductive layers 24b and a plurality of insulating layers 32b are alternately stacked one by one on the insulating layer 32j1. The sacrificial member 62b contains, for example, silicon nitride. Then, an insulating layer 32j2 is formed on the uppermost sacrificial member 62b. Note that a member to be used as a hard mask (protective film) in the subsequent staircase shaping may be provided on the insulating layer 32j2.

In the processing of step ST202, staircase shaping of the middle tier T_{MCA} is executed. By the processing of step ST202, a staircase structure including a plurality of terrace portions TP of a plurality of sacrificial members 62b of the middle tier T_{MCA} is formed. The terrace portion TP of a sacrificial member 62b corresponds to a portion that does not overlap one or more upper sacrificial members 62b among the sacrificial members 62b.

In the processing of step ST203, a stopper portion of the middle tier T_{MCA} is formed. The stopper portion of the middle tier IMCA includes a stopper film to be used in a step of forming a plurality of holes for forming middle contact plugs MCC described later. Specifically, first, an insulating film 50b and a sacrificial member 63b are formed in this order. Then, the insulating film 50b and the sacrificial member 63b are processed (removed) such that a portion covering the terrace portions TP of the sacrificial members 62b of the middle tier T_{MCA} remains. At this time, the insulating film 50b and the sacrificial member 63b formed in the memory area MA are removed, and the insulating film 50b and the sacrificial member 63b on the insulating layer 37a, and the insulating film 50b and the sacrificial member 63b on the insulating layer 32j2 are removed. The shape of the sacrificial member 63b corresponds to the shape of the insulating film 51b shown in FIG. 47. The sacrificial member 63b can be used as a stopper film. For example, the sacrificial member 63b contains, for example, a material that is the same as the sacrificial member 62b and that is different from the insulating layer 37b or 38, and is formed thicker than the sacrificial member 62b. The sacrificial member 63b contains, for example, silicon nitride.

In the processing of step ST204, embedding and flattening step differences of the middle tier T_{MCA} are executed. Specifically, an insulating layer 37b is formed such that the staircase structure included in the middle tier IMCA is embedded. Then, part of the insulating layer 37b is removed by, for example, CMP (chemical mechanical polishing) processing. Thereby, the upper surface of the insulating layer 32j2 and the upper surface of the insulating layer 37b are aligned (flattened). In a case where a member to be used as a hard mask was provided in the processing of step ST201, this member (hard mask) is removed by the processing of step ST204.

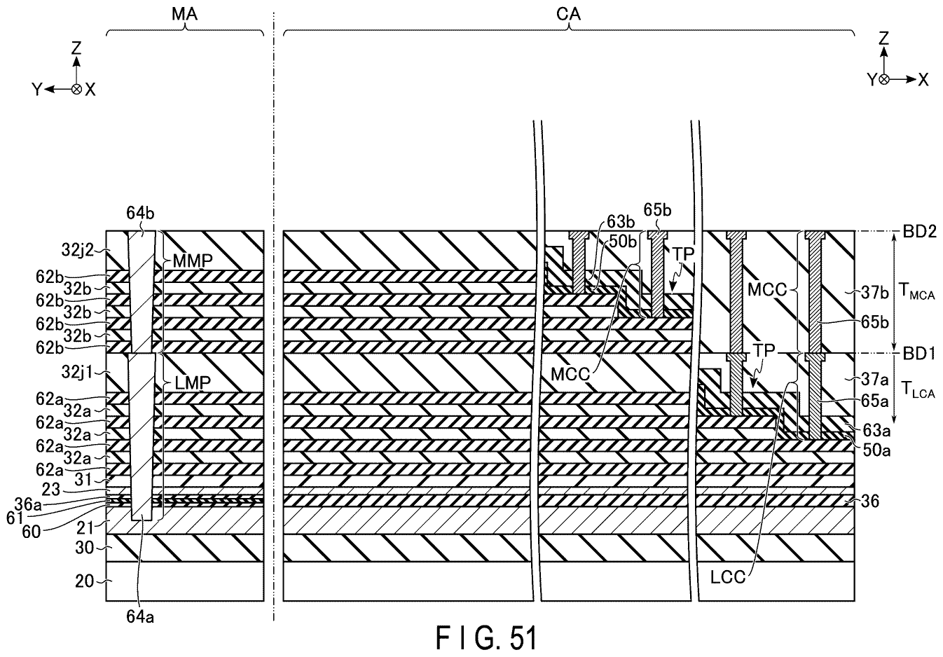

Next, the structure shown in FIG. 51 is formed by the pieces of processing of steps ST205 and ST206 being executed in this order.

In the processing of step ST205, MMP processing and sacrificial member embedding are executed. Specifically, first, a plurality of holes corresponding to the middle memory pillars MMP are formed such that the hole penetrates the sacrificial members 62b and the insulating layers 32b and 32j2 and the bottom of the hole reaches the corresponding one of the sacrificial members 64a corresponding to the lower memory pillars LMP. Then, sacrificial members 64b are embedded in the holes corresponding to the middle memory pillars MMP. The sacrificial member 64b contains, for example, any of carbon, silicon, and a metal material.

In the processing of step ST206, MCC processing and sacrificial member embedding are executed. By the present processing, a structure corresponding to each of the middle contact plugs MCC is formed with a sacrificial member 65b. Details of the present processing are similar to those of step ST107 of the first embodiment. Briefly, a plurality of holes associated with the middle contact plugs MCC of the contact plugs CCa1 and a plurality of holes associated with the middle contact plugs MCC of the contact plugs CCa2 are formed, and sacrificial members 65b are embedded in these holes. The bottoms of the sacrificial members 65b associated with the middle contact plugs MCC of the contact plugs CCa1 are respectively connected to the sacrificial members 65a associated with the lower contact plugs LCC of the contact plugs CCa1. The bottoms of the sacrificial members 65b associated with the middle contact plugs MCC of the contact plugs CCa2 are respectively connected to the terrace portions TP of the sacrificial members 62b.

Next, pieces of processing of steps ST108, ST109, and ST110, which are similar to those of the first embodiment, are executed in this order. That is, an upper layer stack is formed (step ST108), the staircase shaping of the upper tier T_{UCA} is executed (step ST109), and embedding and flattening step differences of the upper tier T_{UCA} are executed (step ST110). Note that, in the processing of steps ST108 to ST110 in the second embodiment, the insulating layer 32b and the sacrificial member 62b in the first embodiment are replaced with an insulating layer 32c and a sacrificial member 62c, respectively.

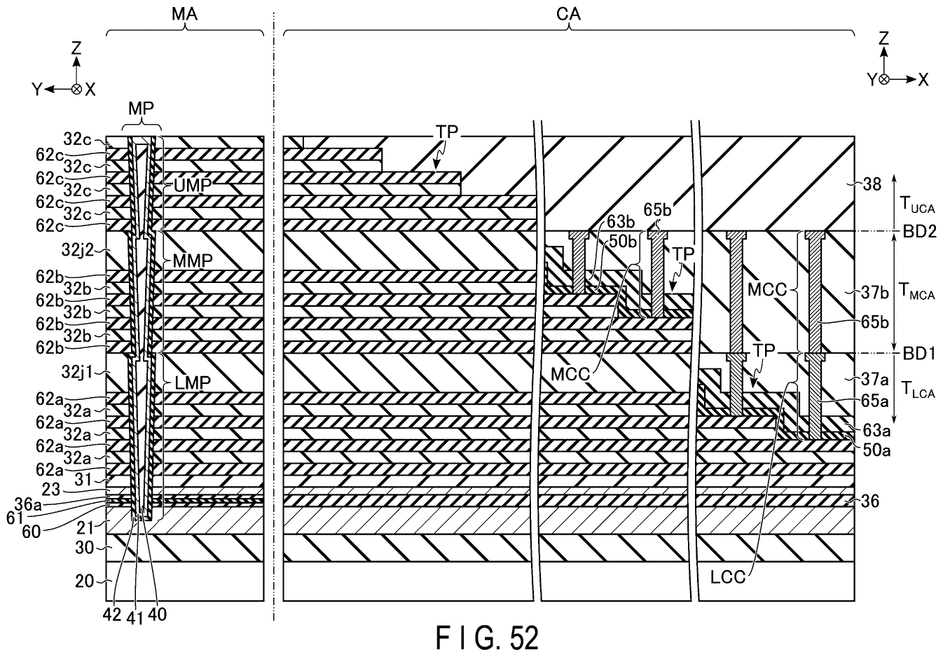

Next, as shown in FIG. 52, UMP processing and MP formation are executed (step ST207). Specifically, first, a plurality of holes corresponding to the upper memory pillars UMP are formed such that the hole penetrates the sacrificial members 62c and the insulating layers 32c and the bottom of the hole reaches the sacrificial member 64b in the associated middle memory pillar MMP. Then, the sacrificial members 64a formed in the holes corresponding to the lower memory pillars LMP and the sacrificial members 64b formed in the holes corresponding to the middle memory pillars MMP are removed via the holes corresponding to the upper memory pillars UMP. Then, a stacked film 42, a semiconductor film 41, and a core member 40 are formed in each hole corresponding to the set of the upper memory pillar UMP, the middle memory pillar MMP, and the lower memory pillar LMP (that is, a memory pillar MP). After that, an insulating layer 33 is formed on the uppermost insulating layer 32c and the insulating layer 38.

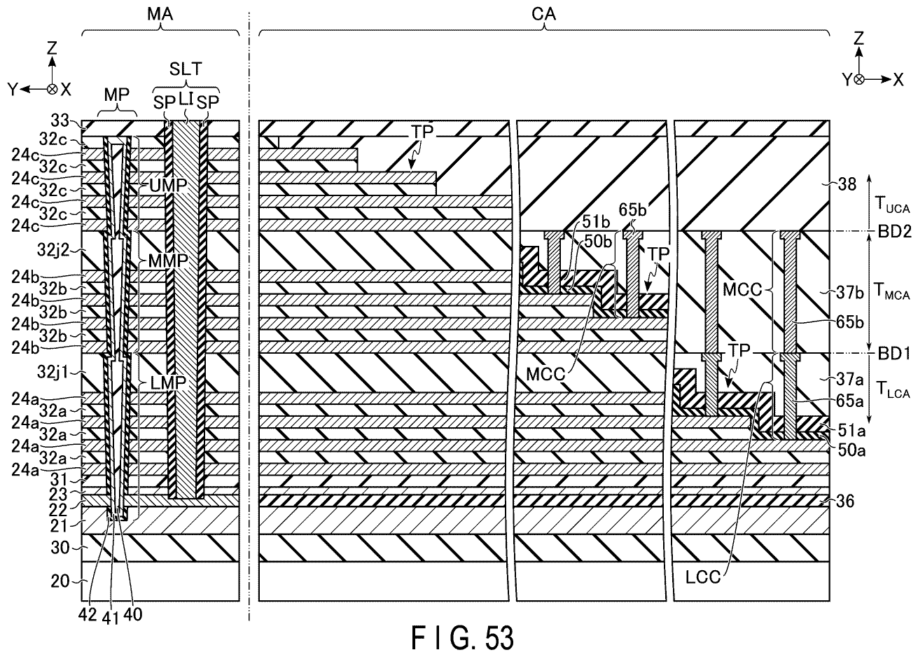

Next, the structure shown in FIG. 53 is formed by the pieces of processing of steps ST208, ST209, and ST114 being executed in this order.

In the processing of step ST208, SLT processing is executed. Specifically, slits corresponding to the members SLT are formed such that the slit penetrates the sacrificial members 62a, 62b, 62c, 63a, and 63b, the semiconductor layer 23, the insulating layers 31, 32a, 32b, 32c, 32j1, 32j2, 33, and 36a, and the insulating films 50a and 50b and the bottom of the slit reaches the sacrificial member 61.

In the processing of step ST209, SL replacement and WL replacement are executed. Specifically, first, by SL replacement, the insulating layers 60 and 36a and the sacrificial member 61 of the memory area MA are replaced with a semiconductor layer 22. Then, by WL replacement, the sacrificial members 62a, 62b, and 62c of the memory area MA and the contact area CA are replaced with conductive layers 24a, 24b, and 24c, respectively. Details of the SL replacement are similar to those of the first embodiment.

In the WL replacement, first, the insulating film on the side surface of the slit is removed. Then, by wet etching, the sacrificial members 62a, 62b, 62c, 63a, and 63b are removed via the slit corresponding to the member SLT. Then, conductive layers 24 are embedded in the areas (spaces) where the sacrificial members 62a, 62b, and 62c have been removed. The materials corresponding to the conductive layer 24 are formed also in the areas where the sacrificial members 63a and 63b have been removed. After that, the excess conductive layer 24 is removed on the side surface and the bottom surface of the slit corresponding to the member SLT and above the insulating layer 33. At this time, also the conductive material of the conductive layers 24 formed in the areas where the sacrificial members 63a and 63b have been removed is removed. After that, insulating members 53 are embedded individually in the areas where the sacrificial members 63a and 63b have been removed. Thereby, structures corresponding to the insulating films 51a and 51b are formed. After that, the processing of step ST114 is executed; thus, like in the first embodiment, a spacer SP and a conductive member LI are formed in each slit corresponding to the member SLT.

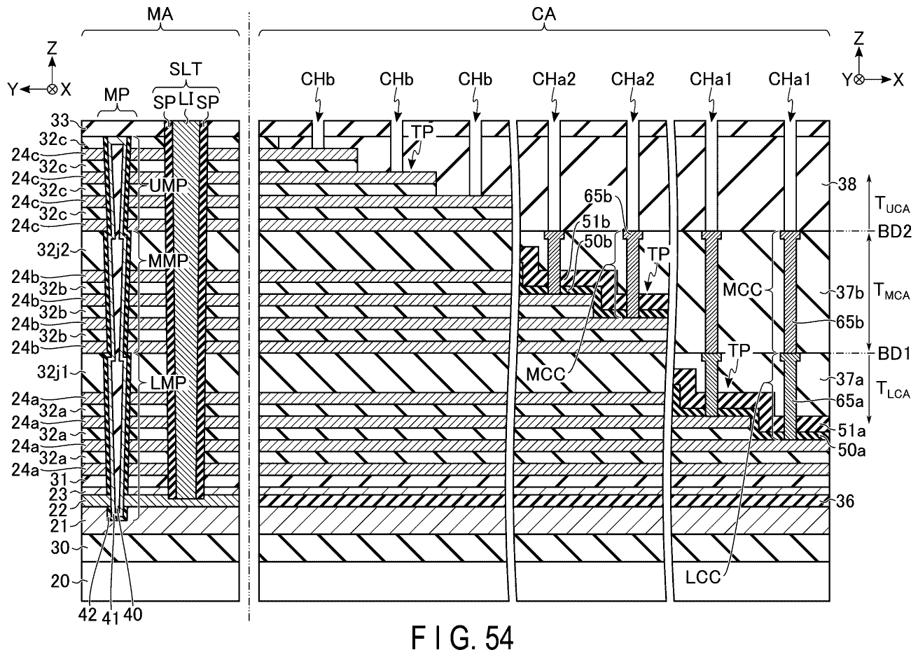

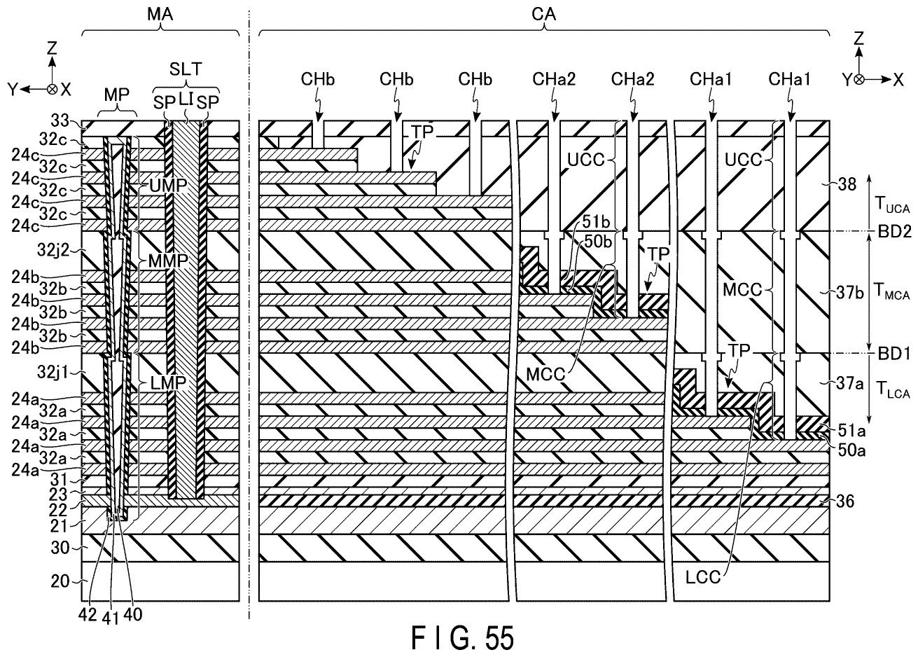

Next, UCC processing and MCC-LCC sacrificial member removal are executed (step ST210). Specifically, first, as shown in FIG. 54, pluralities of contact holes CHa1, CHa2, and CHb are formed to penetrate, for example, the insulating layers 33 and 38. The contact hole CHa1 is associated with the upper contact plug UCC of the contact plug CCa1. The bottoms of the contact holes CHa1 respectively reach the sacrificial members 65b associated with the middle contact plugs MCC of the contact plugs CCa1. The contact hole CHa2 is associated with the upper contact plug UCC of the contact plug CCa2. The bottoms of the contact holes CHa2 respectively reach the sacrificial members 65b associated with the middle contact plugs MCC of the contact plugs CCa2. The bottoms of the contact holes CHb respectively reach the terrace portions TP of the conductive layers 24c. Then, as shown in FIG. 55, via the contact holes CHa1 or CHa2, the sacrificial members 65a and 65b corresponding to the lower contact plugs LCC and the middle contact plugs MCC of the contact plugs CCa1 are removed, and the sacrificial members 65b corresponding to the middle contact plugs MCC of the contact plugs CCa2 are removed. Details of the present processing are similar to those of step ST115 of the first embodiment.

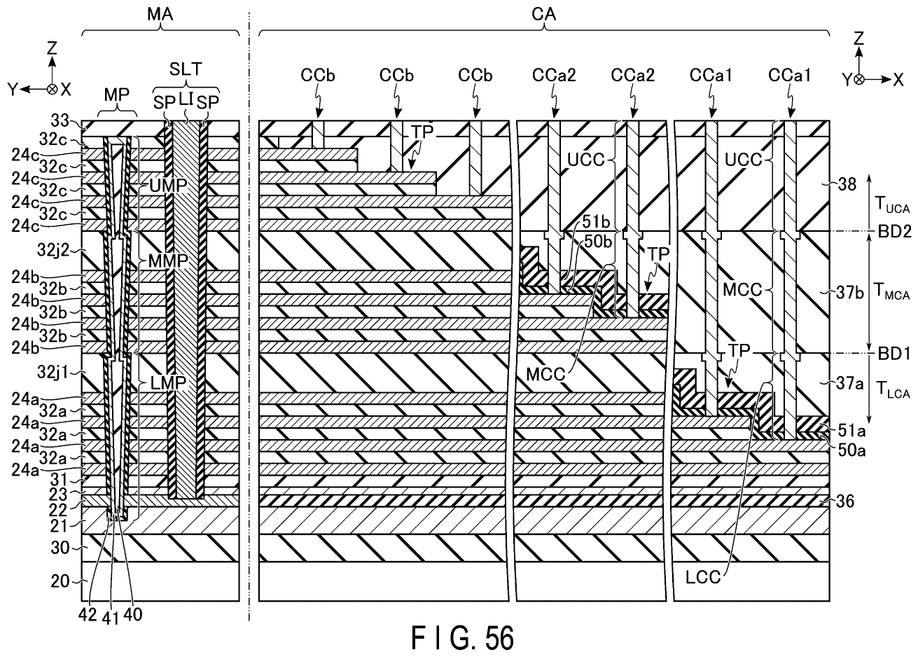

Next, as shown in FIG. 56, CC conductive member embedding is executed like in the first embodiment (step ST116). Specifically, first, conductive members are formed such that each of the contact holes CHa1, the contact holes CHa2, and the contact holes CHb is embedded. Then, the excess conductive member is removed outside the contact holes CHa1, CHa2, and CHb. Thereby, structures corresponding to the contact plugs CCa1, structures corresponding to the contact plugs CCa2, and structures corresponding to the contact plugs CCb are formed.

By the processing described above being executed, the structure of the memory cell array 10A described using FIGS. 46 and 47 is completed.

### <2-3> Advantageous Effects of the Second Embodiment

As described in the second embodiment, the contact plug CC may be formed in three tiers. By increasing the number of tiers of the contact plug CC according to the tiers of the wiring layers of the connection destinations, like in the first embodiment, the maximum height of contact hole processing in each tier is reduced, and the height difference of contact hole processing is reduced. Thereby, in the second embodiment, like in the first embodiment, the occurrence of defects due to penetration of contact holes is suppressed, and the yield of memory devices 1 is improved. Thus, like in the first embodiment, the memory device 1 according to the second embodiment can reduce the manufacturing cost of the memory device 1.

### <3> Third Embodiment

A third embodiment relates to a case where, in the memory cell array 10A described in the second embodiment, the number of tiers of the contact plug CCa is different from the number of tiers of the stacked wiring lines. Details of the third embodiment will now be described with emphasis on differences from the second embodiment.

### <3-1> Configuration

First, a configuration of a memory device 1 according to the third embodiment is described.

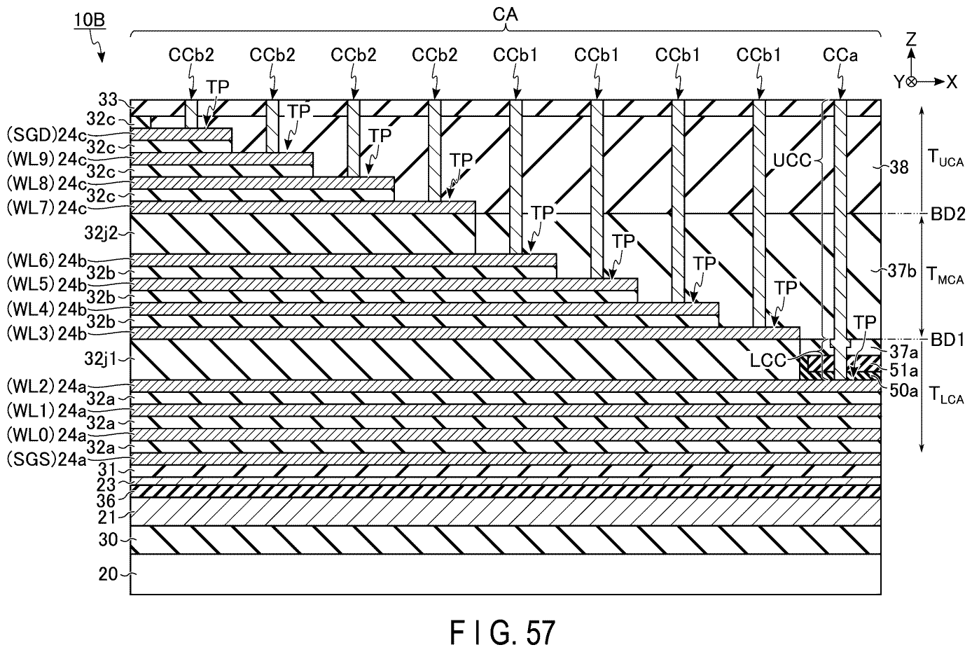

FIG. 57 is a cross-sectional view showing an example of a cross-sectional structure of a contact area CA of a memory cell array 10B included in the memory device 1 according to the third embodiment. As shown in FIG. 57, the contact plugs CC included in the memory cell array 10B include a plurality of contact plugs CCa, a plurality of contact plugs CCb1, and a plurality of contact plugs CCb2 for each block BLK.

In the third embodiment, the contact plugs CCa are electrically connected respectively to the terrace portions TP of the conductive layers 24a included in the lower tier T_{LCA}. Each contact plug CCa is arranged over the three tiers of the stacked wiring lines (the lower tier T_{LCA}, the middle tier T_{MCA}, and the upper tier T_{UCA}), and yet has a structure formed separately in two tiers. Specifically, each contact plug CCa includes a lower contact plug LCC and an upper contact plug UCC connected in the Z direction. In each contact plug CCa, the lower contact plug LCC is included in the lower tier T_{LCA}, and the upper contact plug UCC is included in the middle tier T_{MCA} and the upper tier T_{UCA}. In each contact plug CCa, the position of the boundary between the lower contact plug LCC and the upper contact plug UCC substantially coincides with the boundary BD1. In each contact plug CCa, the upper contact plug UCC penetrates (passes through) the insulating layers 33, 37b, and 38, and the bottom of the upper contact plug UCC is connected to the upper end of the lower contact plug LCC. In each contact plug CCa, the lower contact plug LCC penetrates (passes through) the insulating layer 37a and the insulating films 50a and 51a, and the bottom of the lower contact plug LCC is connected to the terrace portion TP of the associated conductive layer 24a.

In the third embodiment, the contact plugs CCb1 are electrically connected respectively to the terrace portions TP of the conductive layers 24b included in the middle tier T_{MCA}. The contact plugs CCb1 are arranged over two tiers (the middle tier T_{MCA} and the upper tier T_{UCA}), and yet have structures formed in one tier. Specifically, each contact plug CCb1 is included in the middle tier T_{MCA} and the upper tier T_{UCA}. Each contact plug CCb1 penetrates (passes through) the insulating layers 33, 37b, and 38, and the bottom of the contact plug CCb1 is connected to the terrace portion TP of the associated conductive layer 24b.

In the third embodiment, the contact plugs CCb2 are electrically connected respectively to the terrace portions TP of the conductive layers 24c included in the upper tier T_{UCA}. Each contact plug CCb2 is formed in one tier, and is included in the upper tier T_{UCA}. Each contact plug CCb2 penetrates (passes through) the insulating layers 33 and 38, and the bottom of the contact plug CCb2 is connected to the terrace portion TP of the associated conductive layer 24c.

The configuration of the other parts of the memory device 1 according to the third embodiment is similar to that of the second embodiment.

<3-2> Manufacturing method

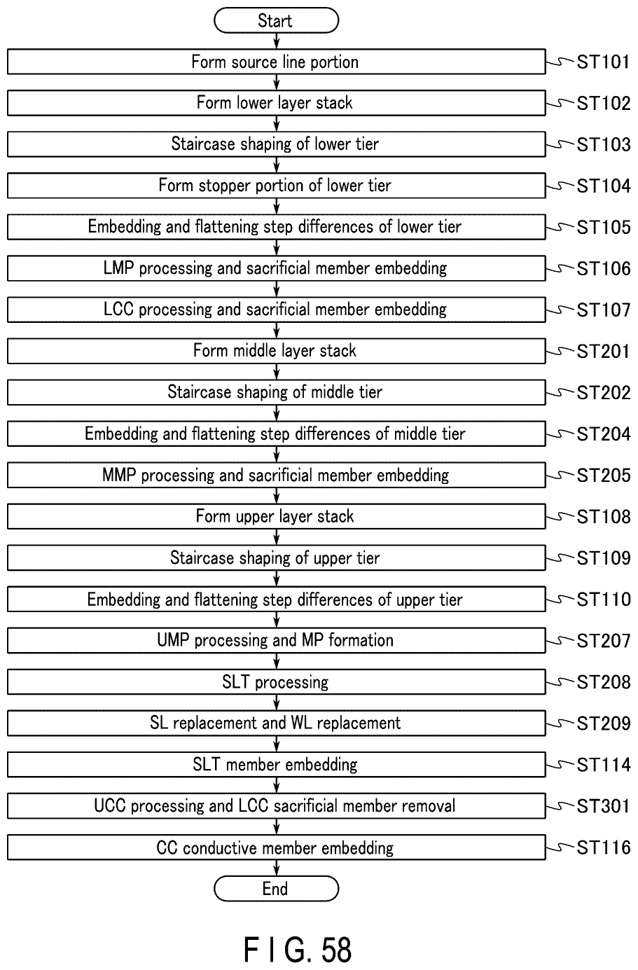

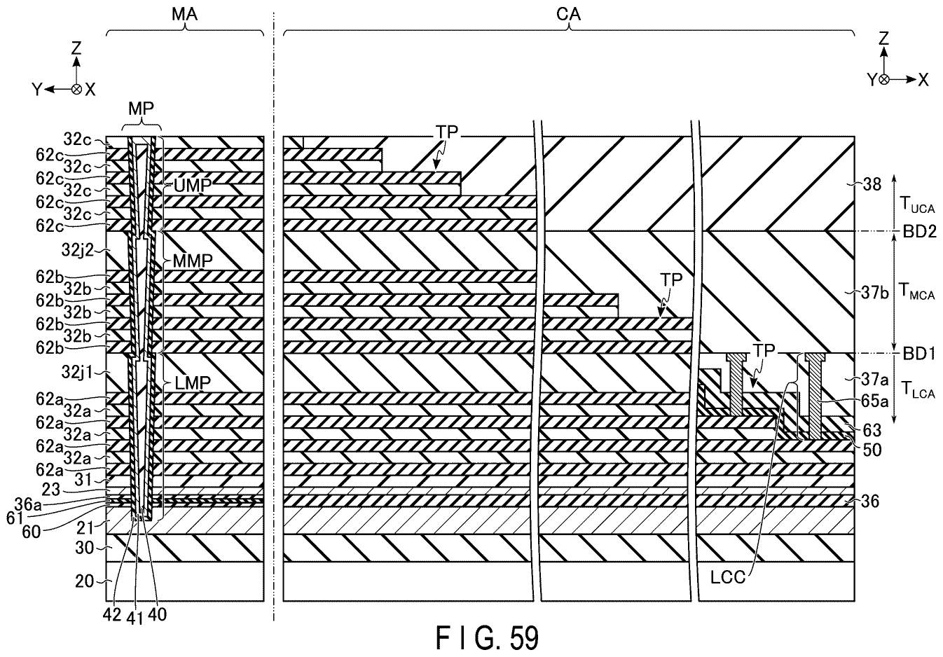

Next, as a method of manufacturing the memory device 1 according to the third embodiment, a method of forming stacked wiring lines and contact plugs CC corresponding to the memory cell array 10B is described with reference to FIG. 58 as appropriate. FIG. 58 is a flowchart showing an example of a method of manufacturing the memory device 1 according to the third embodiment. Each of FIGS. 59, 60, 61, and 62 is a cross-sectional view showing an example of a cross-sectional structure in the manufacturing process of the memory device 1 according to the third embodiment.

First, like in the second embodiment, a source line portion is formed (step ST101), a lower layer stack is formed (step ST102), the staircase shaping of the lower tier T_{LCA} is executed (step ST103), a stopper portion of the lower tier T_{LCA} is formed (step ST104), embedding and flattening step differences of the lower tier T_{LCA} are executed (step ST105), LMP processing and sacrificial member embedding are executed (step ST106), and LCC processing and sacrificial member embedding are executed (step ST107).

Next, like in the second embodiment, a middle layer stack is formed (step ST201), the staircase shaping of the middle T_{MCA} is executed (step ST202), embedding and flattening step differences of the middle T_{MCA} are executed (step ST204), and MMP processing and sacrificial member embedding are executed (step ST205). Thus, in the third embodiment, the processing of step ST203 is omitted. Therefore, a stopper portion of the middle tier T_{MCA} is not formed.

Next, like in the second embodiment, an upper layer stack is formed (step ST108), the staircase shaping of the upper tier T_{UCA} is executed (step ST109), embedding and flattening step differences of the upper tier T_{UCA} are executed (step ST110), and UMP processing and MP formation are executed (step ST207). Thereby, the structure shown in FIG. 59 is formed.

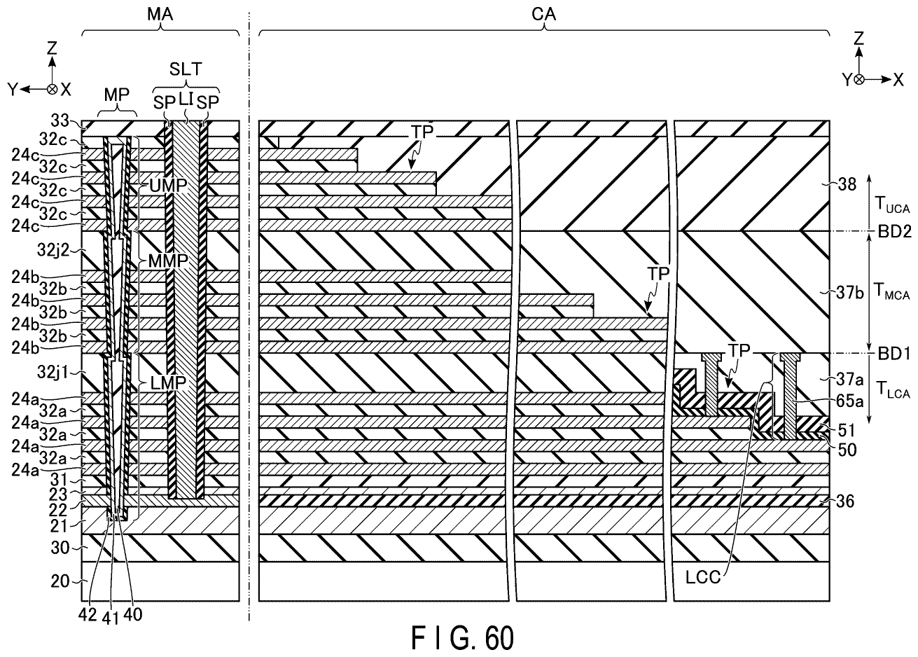

Next, like in the second embodiment, SLT processing is executed (step ST208), and SL replacement and WL replacement are executed (step ST209). The SLT processing and the WL replacement of the third embodiment are similar to those in which, in the SLT processing and the WL replacement of the second embodiment, processing related to the sacrificial member 63b is omitted. After that, SLT member embedding is executed like in the second embodiment (step ST114). Thereby, the structure shown in FIG. 60 is formed.

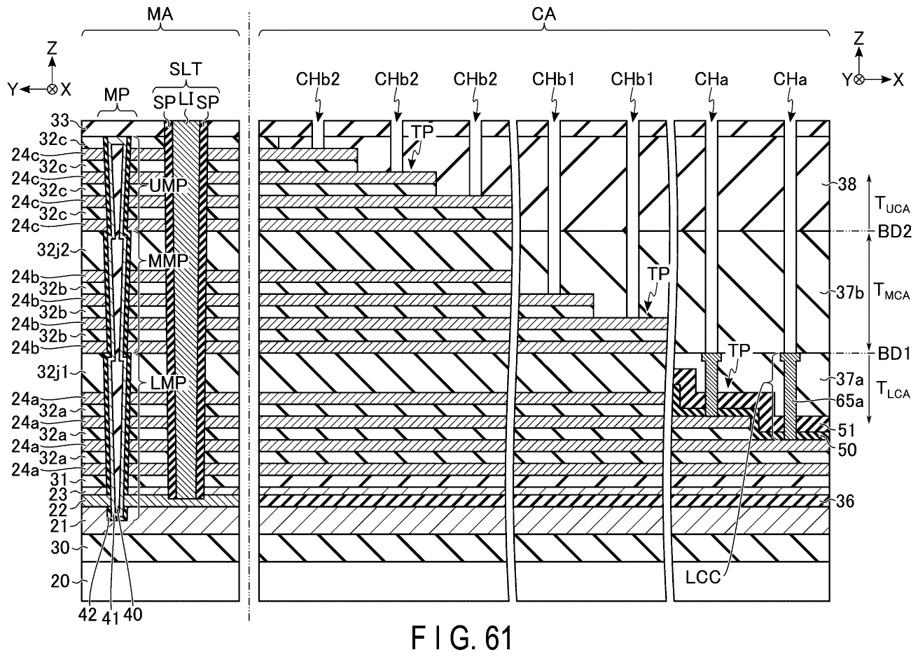

Next, UCC processing and LCC sacrificial member removal are executed (step ST301). Specifically, first, as shown in FIG. 61, pluralities of contact holes CHa, CHb1, and CHb2 are formed. The contact holes CHa are associated with the upper contact plugs UCC of the contact plugs CCa, and are formed to penetrate the insulating layers 33, 37b, and 38. The bottoms of the contact holes CHa respectively reach the sacrificial members 65a associated with the lower contact plugs LCC of the contact plugs CCa. The contact holes CHb1 are associated with the contact plugs CCb1, and are formed to penetrate the insulating layers 33, 37b, and 38. The bottoms of the contact holes CHb1 respectively reach the terrace portions TP of the conductive layers 24b. The contact holes CHb2 are associated with the contact plug CCb2, and are formed to penetrate the insulating layers 33 and 38. The bottoms of the contact holes CHb2 respectively reach the terrace portions TP of the conductive layers 24c. After that, the sacrificial members 65a corresponding to the lower contact plugs LCC of the contact plugs CCa are removed via the contact holes CHa. Details of the present processing are similar to those of step ST115 of the first embodiment.

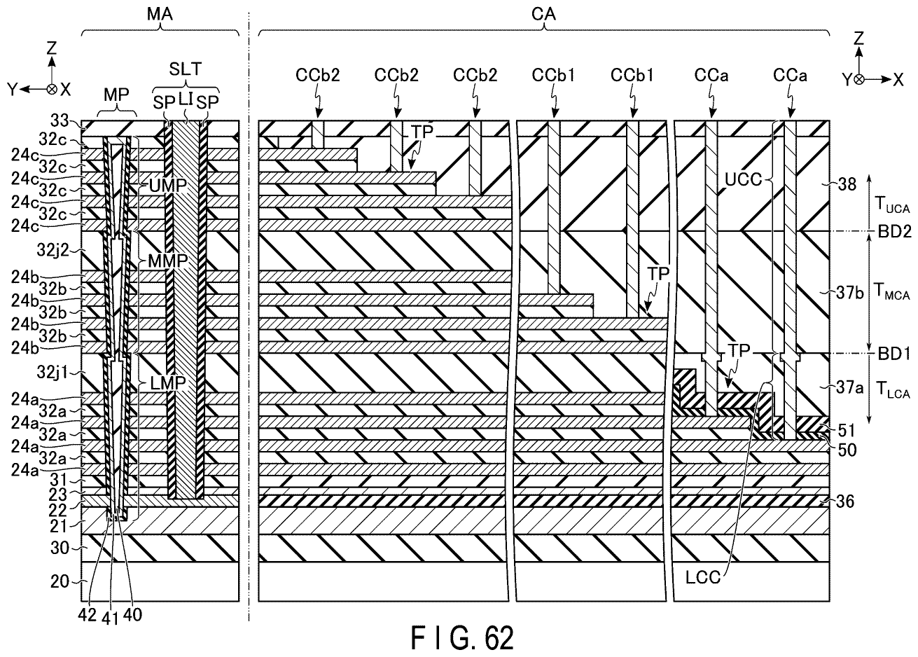

Next, as shown in FIG. 62, CC conductive member embedding is executed like in the first embodiment (step ST116). Specifically, first, conductive members are formed such that each of the contact holes CHa, the contact holes CHb1, and the contact holes CHb2 is embedded. Then, the excess conductive member is removed outside the contact holes CHa, CHb1, and CHb2. Thereby, structures corresponding to the contact plugs CCa, structures corresponding to the contact plugs CCb1, and structures corresponding to the contact plugs CCb2 are formed.

By the processing described above being executed, the structure of the memory cell array 10B described using FIG. 57 is completed.

### <3-3> Advantageous Effects of the Third Embodiment

As described in the third embodiment, the maximum number of tiers of the contact plug CC and the number of tiers of the stacked wiring lines may be different, and the number of divided pieces of the contact plug CC may be reduced according to the degree of difficulty of contact hole processing. Thereby, the memory device 1 according to the third embodiment can suppress the occurrence of defects due to penetration of contact holes, and furthermore can reduce the number of steps for forming contact plugs CC. As a result, the memory device 1 according to the third embodiment can reduce the manufacturing cost of the memory device 1 more than in the second embodiment.

### <4> Fourth Embodiment

In a fourth embodiment, the insulating films 50 and 51 in the first embodiment are provided not to cover at least one conductive layer 24a counted from the boundary BD side among the conductive layers 24a. Details of the fourth embodiment will now be described with emphasis on differences from the first embodiment.

### <4-1> Configuration

First, a configuration of a memory device 1 according to the fourth embodiment is described.

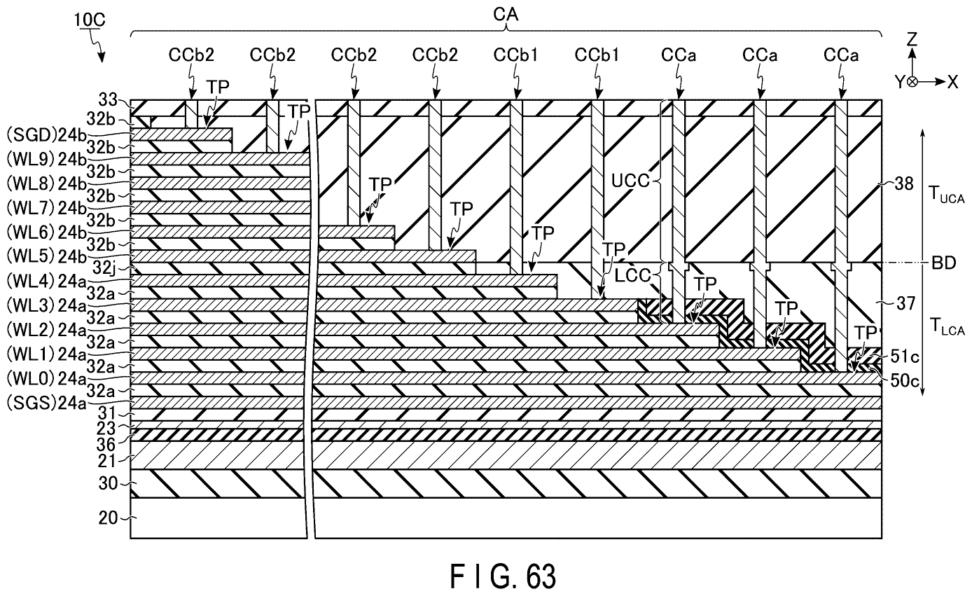

FIG. 63 is a cross-sectional view showing an example of a cross-sectional structure of a contact area CA of a memory cell array 10C included in the memory device 1 according to the fourth embodiment. FIG. 63 shows an XZ cross section including the contact area CA of the memory cell array 10C. As shown in FIG. 63, in the contact area CA, the memory cell array 10C includes, for example, insulating films 50c and 51c instead of the insulating films 50 and 51. Further, the contact plugs CC included in the memory cell array 10C include a plurality of contact plugs CCa, at least one contact plug CCb1, and a plurality of contact plugs CCb2 for each block BLK.

The insulating film 50c is provided to cover the terrace portions TP of a plurality of conductive layers 24a excluding at least one conductive layer 24a counted from the boundary BD side among the conductive layers 24a included in the lower tier T_{LCA}. In other words, the insulating film 50c has a structure in which the insulating film 50 described in the first embodiment is provided not to cover the terrace portion TP of at least one conductive layer 24a counted from the boundary BD side. In still other words, the conductive layers 24a included in the lower tier T_{LCA} include at least one intermediate conductive layer arranged near the boundary BD between the lower tier T_{LCA} and the upper tier T_{UCA}. The insulating film 50c is provided to cover the terrace portions TP of a plurality of conductive layers 24a excluding the intermediate conductive layer among the conductive layers 24a included in the lower tier T_{LCA}.

The insulating film 51c is provided on the insulating film 50c. The insulating film 51c overlaps the terrace portions TP of a plurality of conductive layers 24a excluding the intermediate conductive layer among the conductive layers 24a included in the lower tier T_{LCA} in the Z direction. In other words, the insulating film 51c has a structure in which the insulating film 51 described in the first embodiment is provided not to overlap the terrace portion TP of the intermediate conductive layer in the Z direction. The film thickness of the insulating film 51c is larger than that of the conductive layer 24.

In the fourth embodiment, the contact plugs CCa are electrically connected respectively to the terrace portions TP of, among the conductive layers 24a included in the lower tier T_{LCA}, a plurality of conductive layers 24a covered with the insulating films 50c and 51c. Each contact plug CCa is, like in the first embodiment, formed separately in two tiers. In each contact plug CCa, the upper contact plug UCC penetrates (passes through) the insulating layers 33 and 38, and the bottom of the upper contact plug UCC is connected to the upper end of the lower contact plug LCC. In each contact plug CCa, the lower contact plug LCC penetrates (passes through) the insulating layer 37 and the insulating films 50c and 51c, and the bottom of the lower contact plug LCC is connected to the terrace portion TP of the associated conductive layer 24a.

In the fourth embodiment, at least one contact plug CCb1 is electrically connected to the terrace portion TP of at least one conductive layer 24a (the intermediate conductive layer) not covered with the insulating film 50c or 51c among the conductive layers 24a included in the lower tier T_{LCA}. Each contact plug CCb1 is arranged over the two tiers of the stacked wiring lines (the lower tier T_{LCA} and the upper tier T_{UCA}), and yet has a structure formed in one tier. Specifically, each contact plug CCb1 is included in the lower tier T_{LCA} and the upper tier T_{UCA}. Each contact plug CCb1 penetrates (passes through) the insulating layers 33, 37, and 38, and the bottom of the contact plug CCb1 is connected to the terrace portion TP of the associated conductive layer 24a.

In the fourth embodiment, the contact plugs CCb2 are electrically connected respectively to the terrace portions TP of the conductive layers 24b included in the upper tier T_{UCA}. Each contact plug CCb2 is formed in one tier, and is included in the upper tier T_{UCA}. Each contact plug CCb2 penetrates (passes through) the insulating layers 33 and 38, and the bottom of the contact plug CCb2 is connected to the terrace portion TP of the associated conductive layer 24b.

The configuration of the other parts of the memory device 1 according to the fourth embodiment is similar to that of the first embodiment.

### <4-2> Manufacturing Method

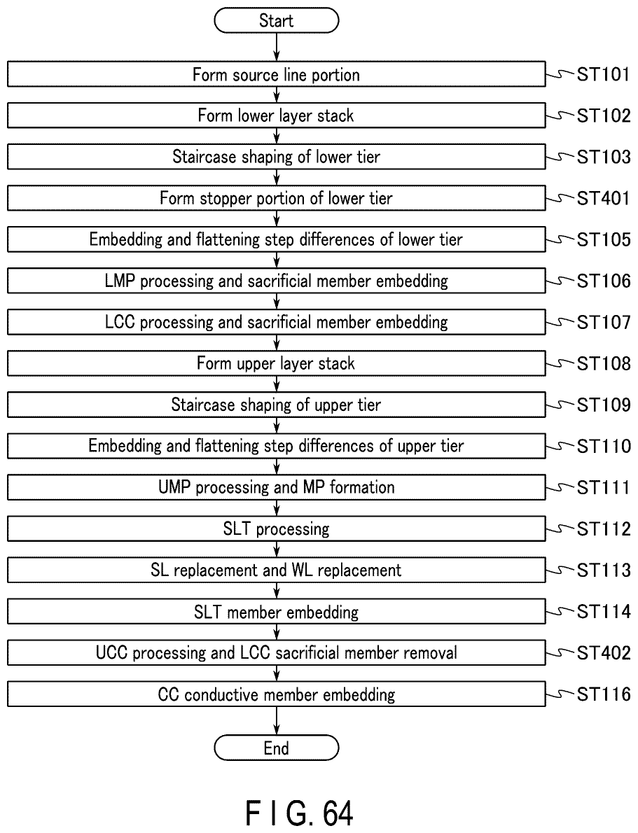

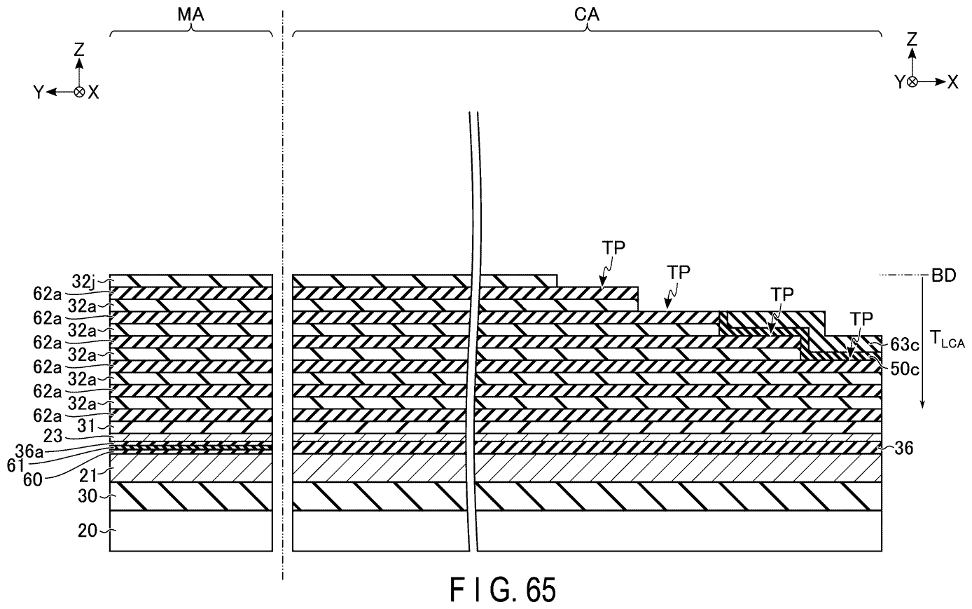

Next, as a method of manufacturing the memory device 1 according to the fourth embodiment, a method of forming stacked wiring lines and contact plugs CC corresponding to the memory cell array 10C is described with reference to FIG. 64 as appropriate. FIG. 64 is a flowchart showing an example of a method of manufacturing the memory device 1 according to the fourth embodiment. Each of FIGS. 65, 66, 67, 68, 69, 70, 71, and 72 is a cross-sectional view showing an example of a cross-sectional structure in the manufacturing process of the memory device according to the fourth embodiment. Each of FIGS. 65 to 72 shows an area where the memory pillar MP and the member SLT are formed and part of the contact area CA.

First, like in the first embodiment, a source line portion is formed (step ST101), a lower layer stack is formed (step ST102), and the staircase shaping of the lower tier T_{LCA} is executed (step ST103).

Next, a stopper portion of the lower tier T_{LCA} is formed (ST401). Specifically, first, an insulating film 50c and a sacrificial member 63c are formed in this order. Then, as shown in FIG. 65, the insulating film 50c and the sacrificial member 63c are processed (removed) such that a portion covering the staircase structure (the terrace portions TP) of a plurality of sacrificial members 62a excluding the sacrificial member 62 among the sacrificial members 62a of the lower tier T_{LCA} associated with the intermediate conductive layer remains. At this time, the insulating film 50c and the sacrificial member 63c formed in the memory area MA are removed, and the insulating film 50c and the sacrificial member 63c on the insulating layer 32j are removed.

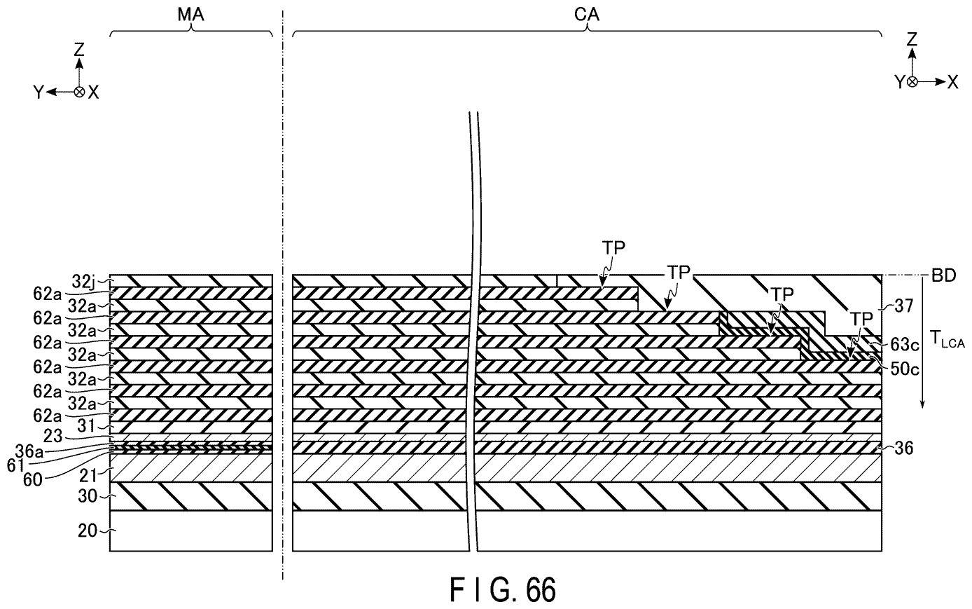

Next, like in the first embodiment, embedding and flattening step differences of the lower tier T_{LCA} are executed (step ST105). Thereby, as shown in FIG. 66, an insulating layer 37 is formed.

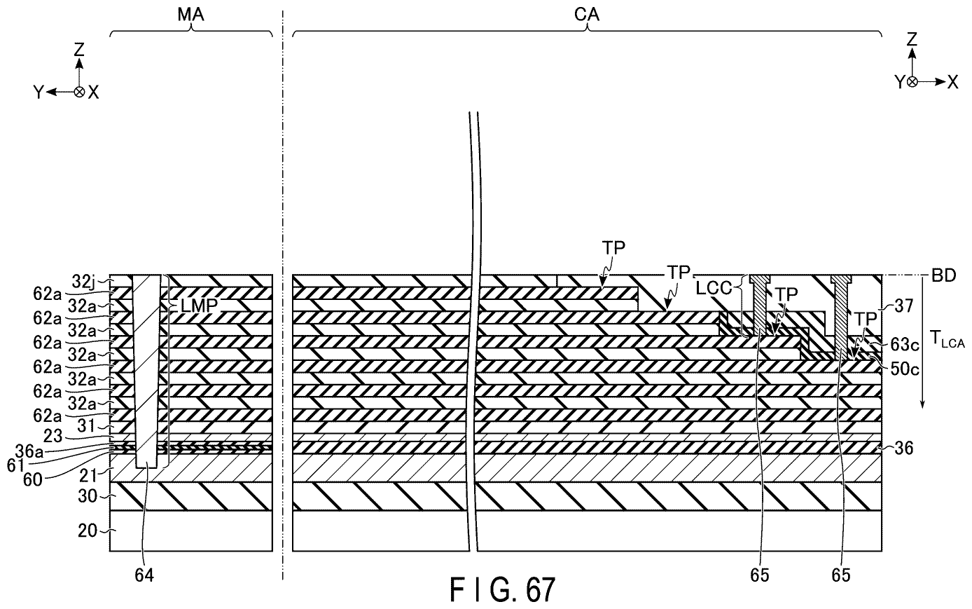

Next, like in the first embodiment, LMP processing and sacrificial member embedding are executed (step ST106), and LCC processing and sacrificial member embedding are executed (step ST107). Thereby, as shown in FIG. 67, sacrificial members 64 are embedded in a plurality of holes corresponding to the lower memory pillars LMP, and sacrificial members 65 are embedded in a plurality of holes corresponding to the lower contact plugs LCC. Note that, in the processing of step ST106 of the fourth embodiment, the sacrificial member 65 is not formed on the terrace portion TP of at least one sacrificial member 62a not covered with the insulating film 50c or the sacrificial member 63c.

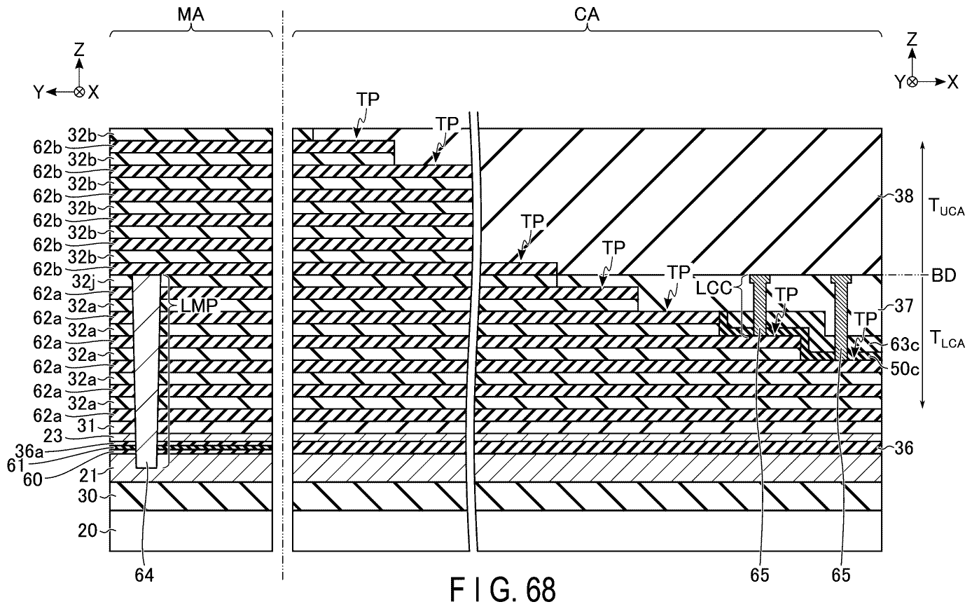

Next, like in the first embodiment, an upper layer stack is formed (step ST108), the staircase shaping of the upper tier T_{UCA} is executed (step ST109), and embedding and flattening step differences of the upper tier T_{UCA} are executed (step ST110). Thereby, as shown in FIG. 68, a plurality of terrace portions TP of a plurality of sacrificial members 62b are formed, and an insulating layer 38 is formed.

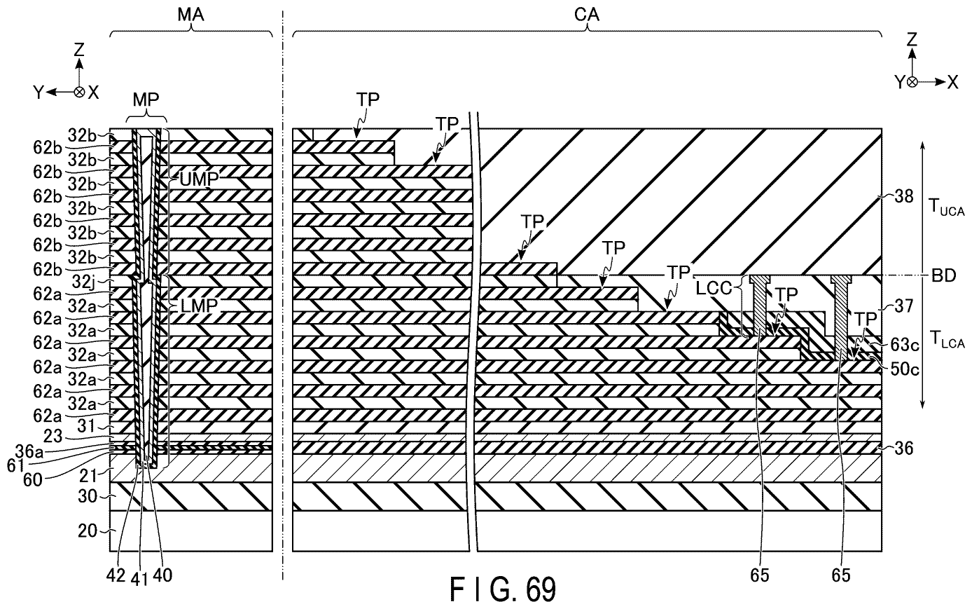

Next, UMP processing and MP formation are executed like in the first embodiment (step ST111). Thereby, as shown in FIG. 69, memory pillars MP are formed.

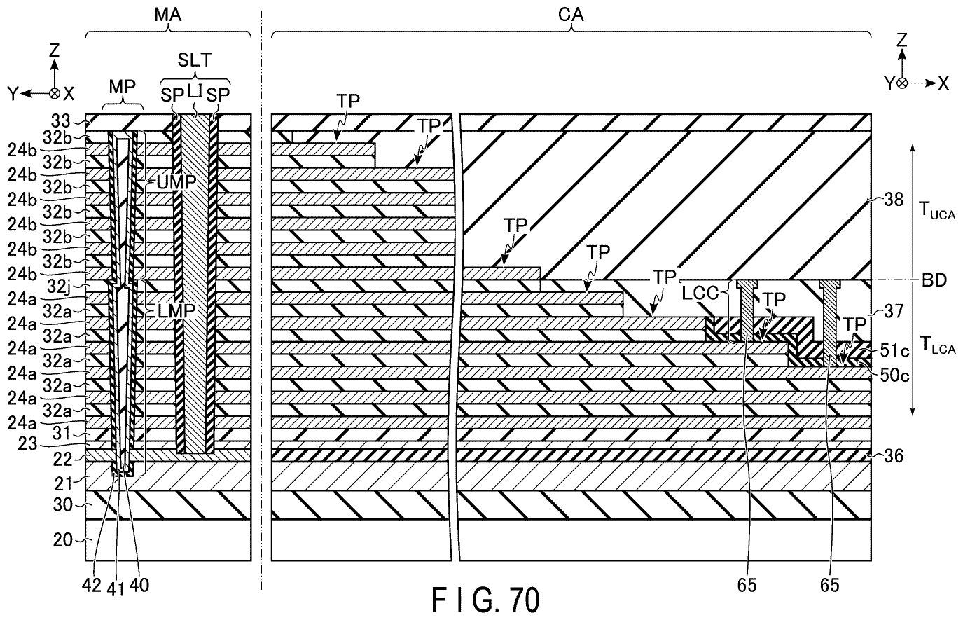

Next, like in the first embodiment, SLT processing is executed (step ST112), SL replacement and WL replacement are executed (step ST113), and SLT member embedding is executed (step ST114). Thereby, as shown in FIG. 70, the semiconductor layer 22 is connected to the semiconductor film 41 of the memory pillar MP, stacked wiring lines (conductive layers 24a and 24b) are formed, an insulating film 51c is formed, and members SLT are formed.

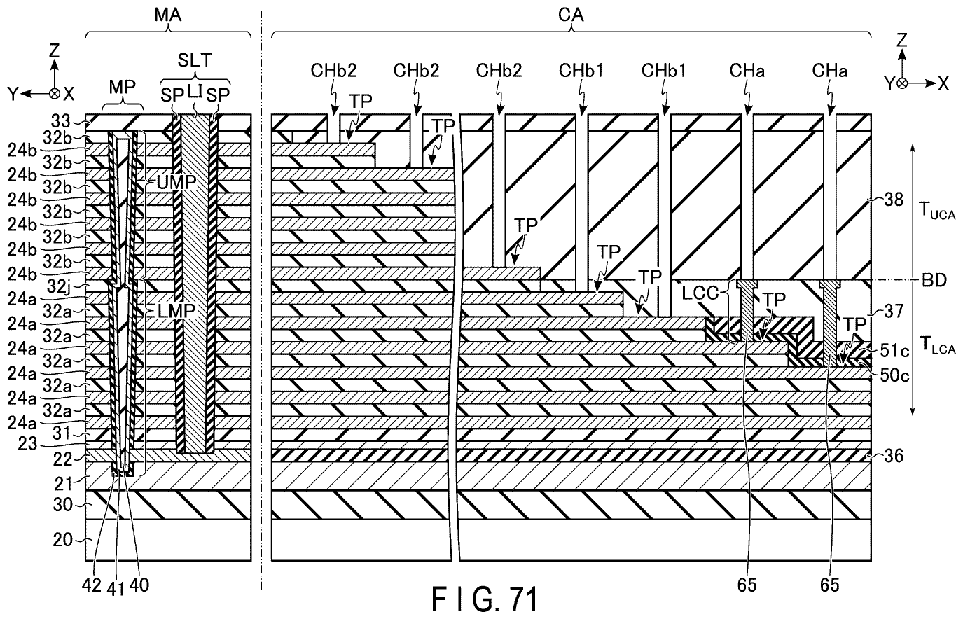

Next, UCC processing and LCC sacrificial member removal are executed (step ST402). Specifically, first, as shown in FIG. 71, pluralities of contact holes CHa, CHb1, and CHb2 are formed. The contact holes CHa are associated with the upper contact plugs UCC of the contact plugs CCa, and are formed to penetrate the insulating layers 33 and 38. The bottoms of the contact holes CHa respectively reach the sacrificial members 65 associated with the lower contact plugs LCC of the contact plugs CCa. The contact holes CHb1 are associated with the contact plugs CCb1, and are formed to penetrate the insulating layers 33, 37, and 38. The bottom of each contact hole CHb1 reaches the terrace portion TP of the conductive layer 24a (the intermediate conductive layer) not covered with the insulating film 50c or 51c in the lower tier T_{LCA}. The contact holes CHb2 are associated with the contact plug CCb2, and are formed to penetrate the insulating layers 33 and 38. The bottoms of the contact holes CHb2 respectively reach the terrace portions TP of the conductive layers 24b. After that, the sacrificial members 65 corresponding to the lower contact plugs LCC of the contact plugs CCa are removed via the contact holes CHa. Details of the present processing are similar to those of step ST115 of the first embodiment.

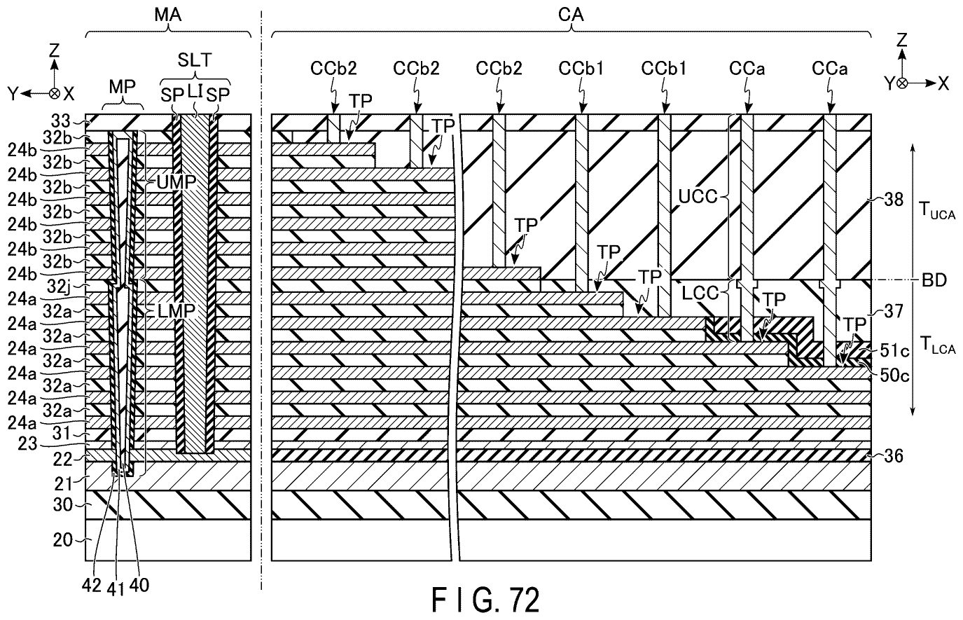

Next, as shown in FIG. 72, CC conductive member embedding is executed (step ST116). Specifically, first, conductive members are formed such that each of the contact holes CHa, the contact holes CHb1, and the contact holes CHb2 is embedded. Then, the excess conductive member is removed outside the contact holes CHa, CHb1, and CHb2. Thereby, structures corresponding to the contact plugs CCa, one or more structures corresponding to the at least one contact plug CCb1, and structures corresponding to the contact plugs CCb2 are formed.

By the processing described above being executed, the structure of the memory cell array 10C described using FIG. 63 is completed.

### <4-3> Advantageous Effects of the Fourth Embodiment

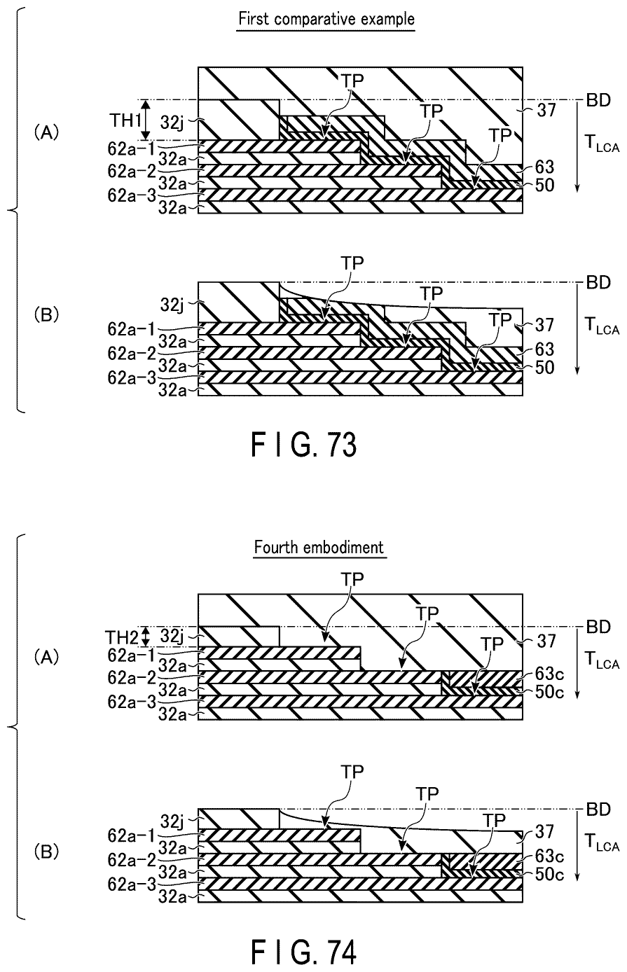

Next, advantageous effects of the memory device 1 according to the fourth embodiment are described using a first comparative example. The first comparative example corresponds to a case where, in the memory device 1 according to the first embodiment, the film thickness of the insulating layer 32j is TH1. FIG. 73 is cross-sectional views showing examples of cross-sectional structures of the vicinity of a boundary BD of a layer stack in the manufacturing process of a memory device 1 according to the first comparative example. In the present item, the top three sacrificial members 62a included in the lower layer stack are referred to as sacrificial members 62a-1, 62a-2, and 62a-3 in order from the top.

In the first comparative example, as shown in (A) of FIG. 73, in a case where step difference filling of the lower tier T_{LCA} is executed, the terrace portion TP of each of the sacrificial members 62a-1, 62a-2, and 62a-3 in an upper portion of the lower tier T_{LCA} is covered with the insulating film 50 and the sacrificial member 63. After that, in a case where flattening (CMP processing) of the lower tier T_{LCA} is executed, dishing can occur in the portion of the insulating layer 37. Then, in a case where the CMP processing reaches the surface of the insulating layer 32j as a target, as shown in (B) of FIG. 73, part of the sacrificial member 63 above the terrace portion TP of the sacrificial member 62a-1 may be scraped off due to dishing.

Thus, in a staircase structure of a plurality of tiers, the shape of the sacrificial member 63 in an upper portion of the lower tier T_{LCA} may not be maintained due to a factor of the manufacturing process. In a case where the film thickness of the sacrificial member 63 is reduced, in the step of forming contact holes LH, the bottom of a contact hole LH can penetrate the sacrificial member 62a-1 and reach the sacrificial member 62a-2, and this can cause a short circuit between adjacent conductive layers 24. To suppress the influence of dishing on the sacrificial member 63, a measure of increasing the film thickness of the insulating layer 32j can be taken. However, increasing the film thickness of the insulating layer 32j causes an increase in the channel resistance of the memory pillar MP. Thus, the film thickness of the insulating layer 32j is preferably formed thin to the extent possible.

In this regard, in the memory device 1 according to the fourth embodiment, the sacrificial member 63 used as a stopper portion is provided not to cover at least one sacrificial member 62a provided in an upper portion of the lower tier T_{LCA}. FIG. 74 is cross-sectional views showing examples of cross-sectional structures of the vicinity of the boundary BD of the layer stack in the manufacturing process of the memory device 1 according to the fourth embodiment.

In the fourth embodiment, in a case where step difference filling of the lower tier T_{LCA} is executed, for example, the structure shown in (A) of FIG. 74 is formed. In the present example, the insulating film 50 and the sacrificial member 63 are provided to cover the sacrificial member 62a-3 and not to cover the sacrificial member 62a-1 or 62a-2. Therefore, in the fourth embodiment, the distance between the upper end of the sacrificial member 63 and the upper end of the insulating layer 32j is increased. In a case where flattening (CMP processing) of the lower tier T_{LCA} is executed in this state, even in a case where the CMP processing reaches the surface of the insulating layer 32j as a target, the influence of dishing does not reach the sacrificial member 63, as shown in (B) of FIG. 74.

Thus, in the memory device 1 according to the fourth embodiment, by changing the range in which the sacrificial member 63 is formed in the lower tier T_{LCA}, a situation where the film thickness of the sacrificial member 63 is reduced in the flattening of the lower tier T_{LCA} can be suppressed. Then, contact hole processing on the sacrificial member 62a not covered with the insulating film 50 or the sacrificial member 63 in the lower tier T_{LCA} (for example, the sacrificial members 62a-1 and 62a-2) is executed collectively with contact hole processing on the sacrificial member 62b included in the upper tier T_{UCA}.

As a result, the memory device 1 according to the fourth embodiment allows the contact plug CCa to be formed in a plurality of tiers like in the first embodiment, and furthermore allows the film thickness TH2 of the insulating layer 32j to be set smaller than TH1. As a result, the memory device 1 according to the fourth embodiment can have, in addition to similar advantageous effects to those of the first embodiment, the advantageous effect of reducing the channel resistance of the memory pillar MP, and can improve the operating characteristics of the memory device 1.

Further, in the memory device 1 according to the fourth embodiment, since the distance between the upper end of the sacrificial member 63 and the upper end of the insulating layer 32j can be increased, the sacrificial member 63 can be formed thicker than in the first embodiment. As a result, the memory device 1 according to the fourth embodiment can improve the tolerance of the stopper film in the lower tier T_{LCA}, and can reduce the degree of difficulty of contact hole processing in the lower tier T_{LCA}.

Further, in the memory device 1 according to the fourth embodiment, the reaching targets of the contact holes CHb1 and CHb2 in the UCC processing of step ST402 are a metal (the terrace portion TP of the conductive layer 24a or 24b). Thus, in the UCC processing, etching selectivity can be increased between the insulating layers 33, 38, and 37, and the conductive layers 24a and 24b. For example, in UCC processing, the bottom of the contact hole CHb2 associated with the uppermost conductive layer 24b, although this bottom is the first to reach the target conductive layer 24b, can be restrained from penetrating the uppermost conductive layer 24b (over-etching) by virtue of the large etching selectivity. Further, in UCC processing, the bottom of the contact hole CHb1 can be restrained from causing over-etching because this bottom is the last to reach the target, i.e., the intermediate conductive layer. Thus, even in a case where a stopper portion like the sacrificial member 63 formed in the lower tier T_{LCA} is not used, by being executed after WL replacement, the UCC processing of the fourth embodiment can be restrained from over-etching of the contact holes CHb1 and CHb2. Therefore, the memory device 1 according to the fourth embodiment can reduce the degree of difficulty of contact hole processing in the upper tier T_{UCA}. The advantage of thus executing contact hole processing after WL replacement can be similarly applied to other embodiments.

Note that, in the formation of a stopper portion of the lower tier T_{LCA} of step ST401, an insulating film 51c that is different in material from any of the sacrificial members 62a and 62b and the insulating layer 37 may be formed instead of the sacrificial member 63c in the memory device 1 according to the fourth embodiment. The insulating film 51c in the present example is not removed by WL replacement, but remains in the memory cell array 10C. The insulating film 51c in the present example does not include the high dielectric film 52, and contains a material having etching selectivity with respect to the insulating layer 37. The insulating film 51c in the present example may not be formed thicker than the conductive layer 62a. Also in such a case, the memory device 1 according to the fourth embodiment can obtain similar advantageous effects to the advantageous effects of the fourth embodiment described above.

### <5> Fifth Embodiment

A fifth embodiment relates to a case where the stacked wiring lines in the first embodiment are provided in one tier and two memory areas MA are arranged to sandwich a contact area CA in the X direction. Details of the fifth embodiment will now be described with emphasis on differences from the first embodiment.

### <5-1> Configuration

First, a configuration of a memory device 1 according to the fifth embodiment is described.

### <5-1-1> Planar Layout of a Memory Cell Array 10D

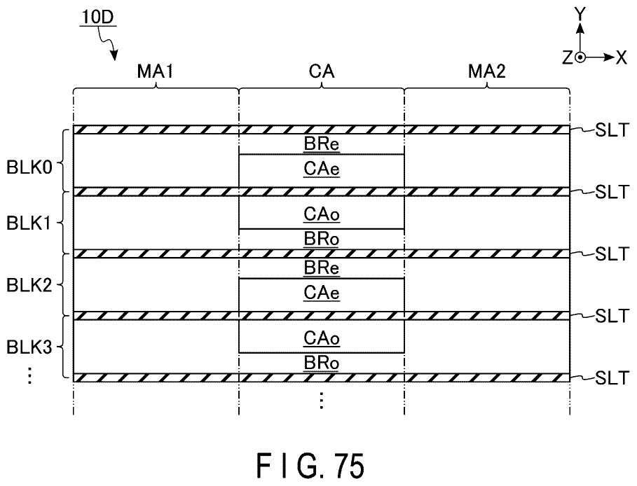

FIG. 75 is a plan view showing an example of a planar layout of a memory cell array 10D included in the memory device 1 according to the fifth embodiment. As shown in FIG. 75, the memory cell array 10D includes memory areas MA1 and MA2 and a contact area CA. The contact area CA of the memory cell array 10D is sandwiched between the memory areas MA1 and MA2 in the X direction. The contact area CA of the memory cell array 10D includes a sub-contact area CAe and a bridge area BRe in an even-numbered block BLK (BLK0, BLK2, . . . ), and includes a sub-contact area CAo and a bridge area BRo in an odd-numbered block BLK (BLK1, BLK3, . . . ).

In each even-numbered block BLK, the sub-contact area CAe and the bridge area BRe are arranged in the Y direction. In the sub-contact area CAe, a staircase structure of stacked wiring lines like that described using FIGS. 3 and 6 is provided, and a plurality of contact plugs CC are arranged. In each even-numbered block BLK, for the stacked wiring lines provided in the memory area MA1 and the stacked wiring lines provided in the memory area MA2, wiring layers (conductive layers 24) provided in the same layer of both sets of stacked wiring lines are continuously provided via the bridge area BRe.

In each odd-numbered block BLK, the sub-contact area CAo and the bridge area BRo are arranged in the Y direction. In the sub-contact area CAo, a staircase structure of stacked wiring lines like that described using FIGS. 3 and 6 is provided, and a plurality of contact plugs CC are arranged. In each odd-numbered block BLK, for the stacked wiring lines provided in the memory area MA1 and the stacked wiring lines provided in the memory area MA2, wiring layers (conductive layers 24) provided in the same layer of both sets of stacked wiring lines are continuously provided via the bridge area BRO.

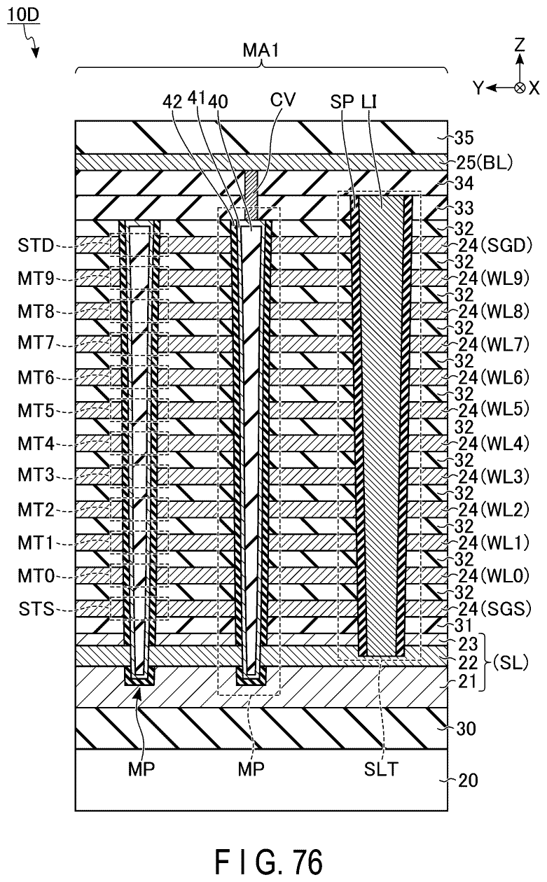

In an even-numbered block BLK and an odd-numbered block BLK adjacent in the Y direction, the sub-contact areas CAe and CAo, or the bridge areas BRe and BRo are adjacent via a member SLT. The stacked wiring lines in sub-contact areas CAe and CAo adjacent via a member SLT have a structure of, for example, being provided plane-symmetrical with respect to the member SLT between the adjacent sub-contact areas CAe and CAo. Note that the conductive layer 24 used as a select gate line SGD may be separated between the memory areas MA1 and MA2 in the memory cell array 10D.

<5-1-2> Cross-Sectional Structure of the Memory Area MA FIG. 76 is a cross-sectional view showing an example of a cross-sectional structure of the memory area MAL of the memory cell array 10D included in the memory device 1 according to the fifth embodiment. As shown in FIG. 76, the memory cell array 10D includes stacked wiring lines formed in one tier.

Specifically, the memory cell array 10D has a configuration in which, in the memory cell array 10 shown in FIG. 4, the conductive layers 24a and 24b are replaced with one kind of conductive layer 24 and the insulating layers 32a, 32b, and 32j are replaced with one kind of insulating layer 32. Thus, since the stacked wiring lines of the memory cell array 10D are configured by a stacked structure of one tier, the memory cell array 10D does not have the boundary BD between tiers shown in FIG. 4, nor does it include the insulating layer 32j corresponding to the boundary BD between adjacent tiers shown in FIG. 4. Further, in the memory cell array 10D, the memory pillar MP is formed in one tier similarly to the stacked wiring lines. In the fifth embodiment, a stacked structure corresponding to the conductive layers 24 and the insulating layers 32 is referred to as a “layer stack”.

### <5-1-3> Cross-Sectional Structure of the Contact Area CA

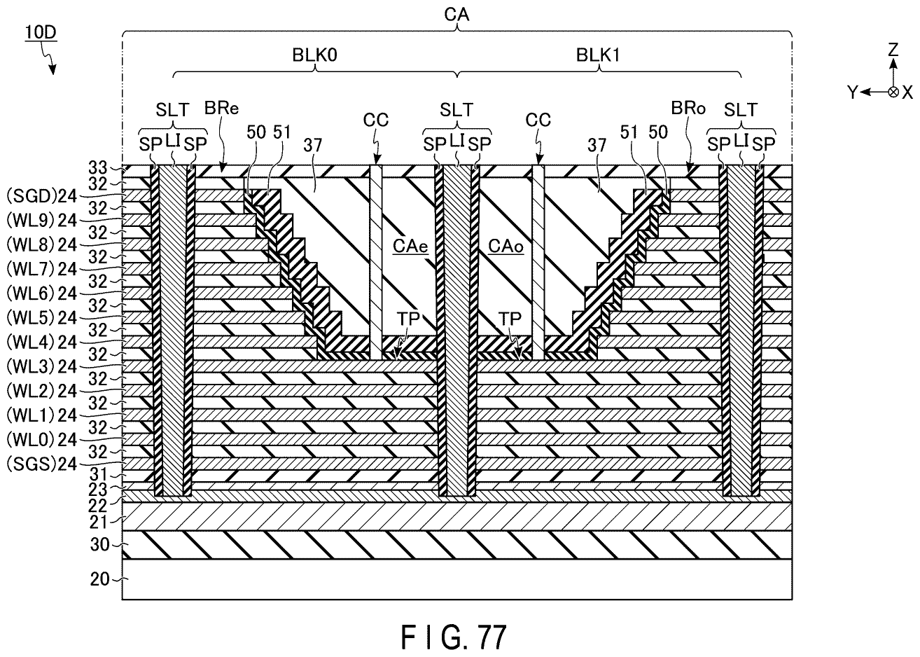

FIG. 77 is a cross-sectional view showing an example of a cross-sectional structure of the contact area CA of the memory cell array 10D included in the memory device 1 according to the fifth embodiment. FIG. 77 shows a YZ cross section including the blocks BLK0 and BLK1 in the contact area CA of the memory cell array 10D and including the terrace portion TP of the conductive layer 24 corresponding to the word line WL3. As shown in FIG. 77, a dummy staircase structure that is formed as a side effect in staircase shaping of stacked wiring lines is provided in each of a region between the sub-contact area CAe and the bridge area BRe and a region between the sub-contact area CAo and the bridge area BRO. Each of the insulating films 50 and 51 is provided to cover the dummy staircase structure together with the staircase structure of the stacked wiring lines (the staircase structure formed by the terrace portions TP of the conductive layers 24).

Note that a case where, like in the fourth embodiment, the insulating films 50 and 51 are provided to cover the staircase structure of a plurality of conductive layers 24 excluding the top one conductive layer 24 among the conductive layers 24 is shown as an example in FIG. 77. The configuration is not limited thereto, and the insulating films 50 and 51 in the fifth embodiment may be provided to cover the terrace portions TP of all the conductive layers 24, or may be provided to cover the terrace portions TP of a plurality of conductive layers 24 excluding the terrace portions TP of the top two or more conductive layers 24.

The configuration of the other parts of the memory device 1 according to the fifth embodiment is similar to that of the first embodiment.

### <5-2> Manufacturing Method

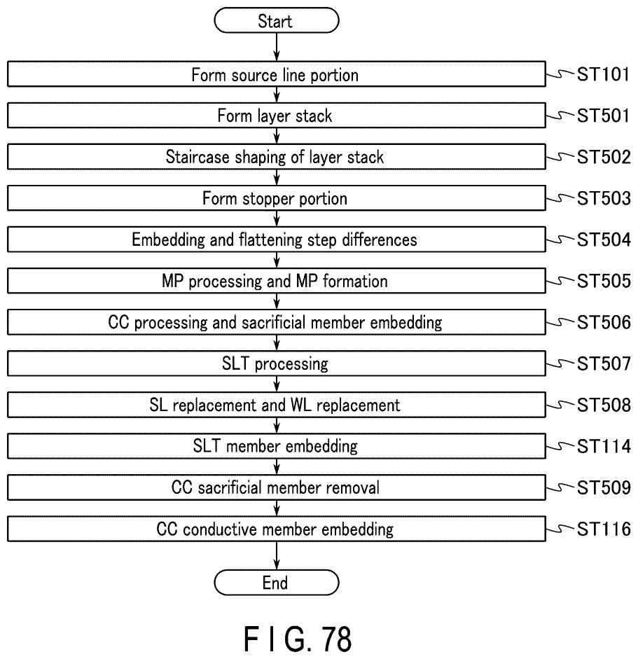

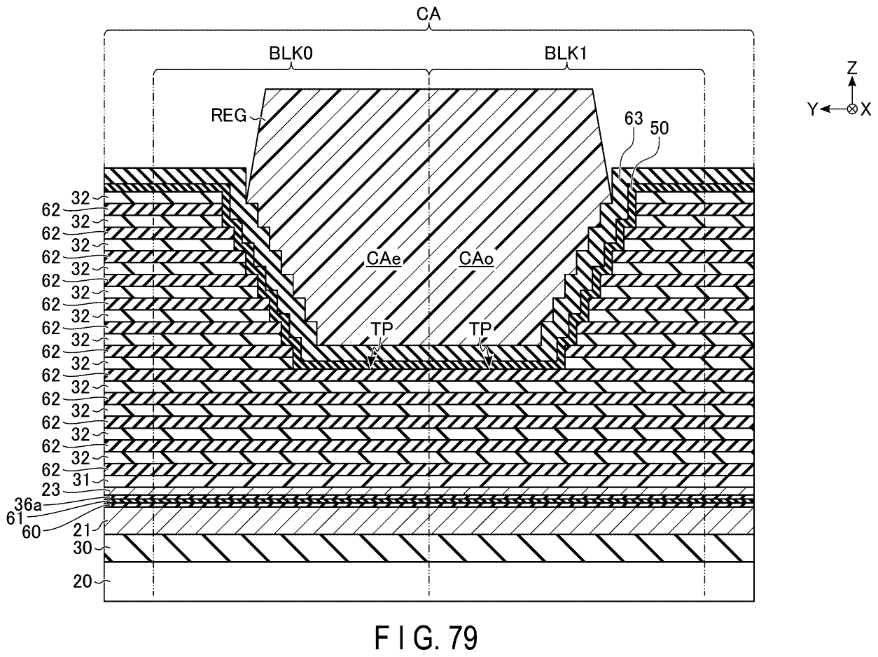

Next, as a method of manufacturing the memory device 1 according to the fifth embodiment, a method of forming stacked wiring lines and contact plugs CC corresponding to the memory cell array 10D is described with reference to FIG. 78 as appropriate. FIG. 78 is a flowchart showing an example of a method of manufacturing the memory device 1 according to the fifth embodiment. Each of FIGS. 79, 80, 81, 82, and 83 is a cross-sectional view showing an example of a cross-sectional structure in the manufacturing process of the memory device 1 according to the fifth embodiment. Each of FIGS. 79 to 83 shows an area corresponding to the area shown in FIG. 77.

First, a source line portion is formed like in the first embodiment (step ST101). Then, a layer stack is formed (step ST501), and staircase shaping of the layer stack is executed (step ST502). The processing of steps ST501 and ST502 is similar to processing in which, in steps ST102 and ST103 of the first embodiment, the lower layer stack is replaced with a layer stack, the insulating layers 32a and 32j are replaced with insulating layers 32, and the sacrificial member 62a is replaced with a sacrificial member 62. By the processing of step ST502, in the sub-contact areas CAe and CAo, a staircase structure configured by a plurality of terrace portions TP of a plurality of sacrificial members 62 is formed, and also a dummy staircase structure is formed as a side effect.

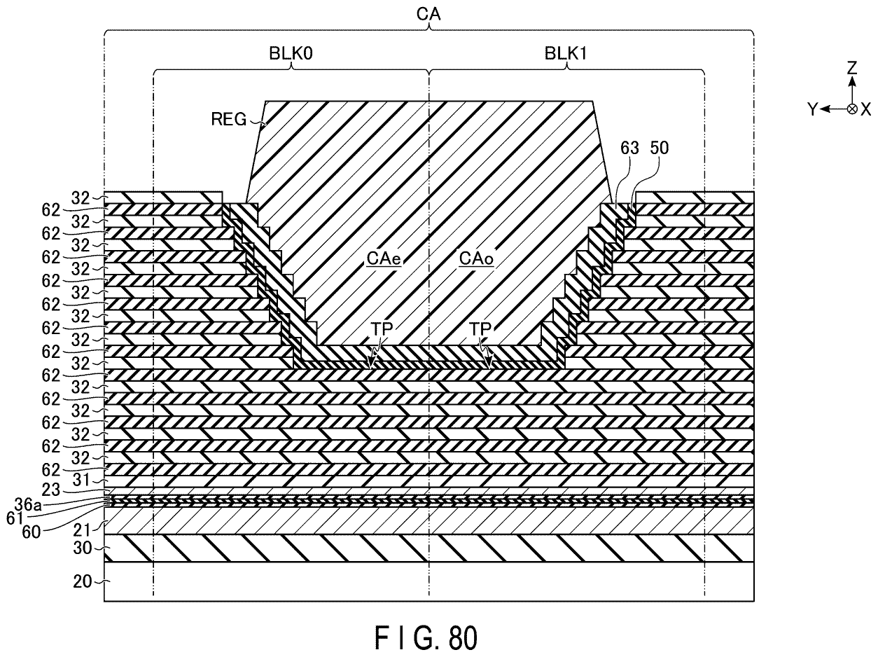

Next, a stopper portion is formed (step ST503). Specifically, first, an insulating film 50 and a sacrificial member 63 are formed in this order. Then, as shown in FIG. 79, a resist REG is formed by photolithography processing. The resist REG is provided to cover the sub-contact areas CAe and CAo. Then, as shown in FIG. 80, by etching processing, portions of the insulating film 50 and the sacrificial member 63 not covered with the resist REG are removed. After that, the resist REG is removed.

Next, embedding and flattening step differences are executed (step ST504). Specifically, an insulating layer 37 is formed such that the staircase structure formed by step ST502 is embedded. Then, part of the insulating layer 37 is removed by, for example, CMP processing. Thereby, the upper surface of the uppermost insulating layer 32 and the upper surface of the insulating layer 37 are aligned (flattened).

Next, MP processing and MP formation are executed (step ST505). Specifically, first, a plurality of holes corresponding to the memory pillars MP are formed such that the hole penetrates the sacrificial members 61 and 62, the semiconductor layer 23, and the insulating layers 31, 32, 36a, and 60 and the bottom of the hole reaches the semiconductor layer 21. Then, a stacked film 42, a semiconductor film 41, and a core member 40 are formed in each hole corresponding to the memory pillar MP. After that, an insulating layer 33 is formed on the uppermost insulating layer 32 and the insulating layer 37.

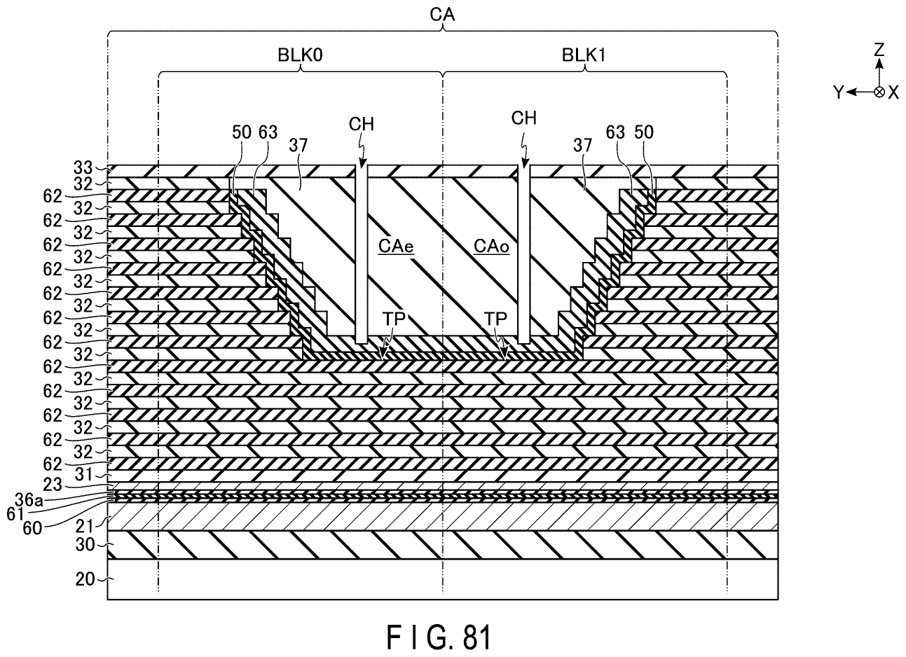

Next, CC processing and sacrificial member embedding are executed (step ST506). Specifically, first, as shown in FIG. 81, a plurality of contact holes CH are formed using the sacrificial member 63 as a stopper film. After that, like in step ST107 of the first embodiment, a structure corresponding to the crossing portion CP of the contact plug CC is formed, and the bottom of the contact hole CH is processed to penetrate the insulating film 50 and reach the sacrificial member 62. Then, an insides of the contact holes CH are embedded with sacrificial members 65.

Next, SLT processing is executed (step ST507). Specifically, slits TR corresponding to the members SLT are formed such that the slit TR penetrates the sacrificial members 62 and 63, the semiconductor layer 23, the insulating layers 31, 32, 33, and 36a, and the insulating film 50 and the bottom of the slit TR reaches the sacrificial member 61.

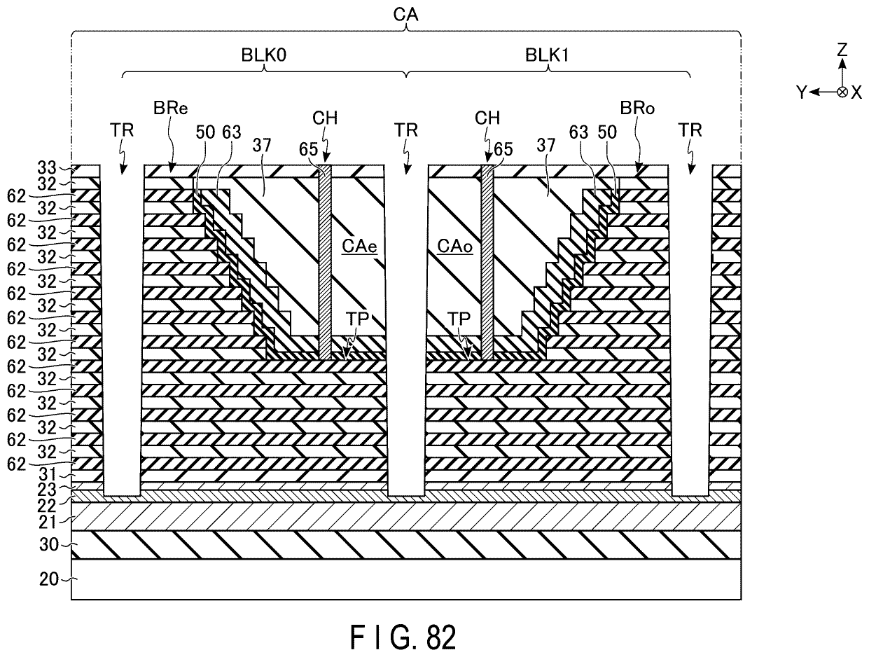

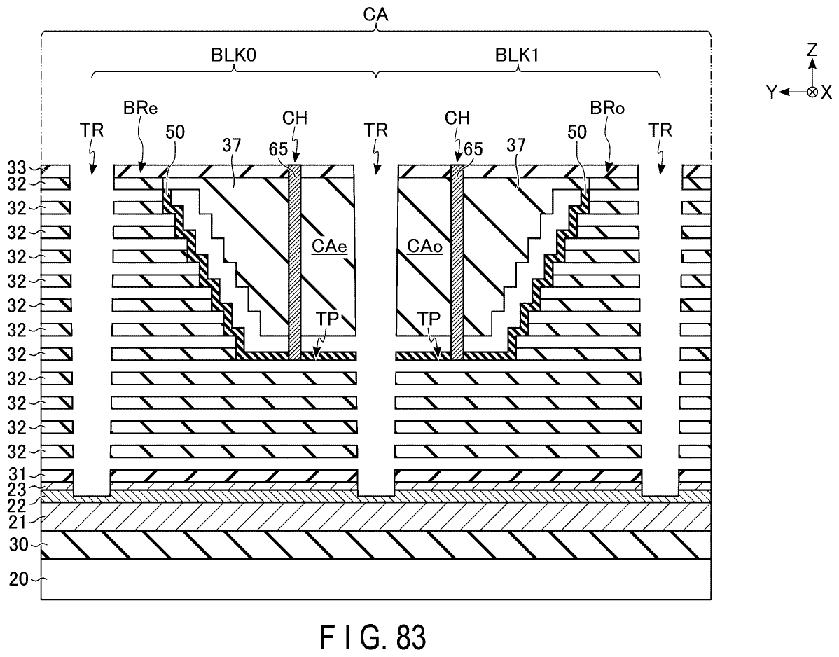

Next, SL replacement and WL replacement are executed (step ST508). Specifically, first, as shown in FIG. 82, the insulating layers 60 and 36a and the sacrificial member 61 of the memory area MA are replaced with a semiconductor layer 22 by SL replacement. Then, each sacrificial member 62 is replaced with a conductive layer 24 by WL replacement. Specifically, in WL replacement, first, the insulating film on the side surface of the slit TR is removed. Then, as shown in FIG. 83, by wet etching, the sacrificial members 62 and 63 are removed via the slit TR corresponding to the member SLT. Then, conductive layers 24 are embedded in the areas (spaces) where the sacrificial members 62 have been removed. The materials corresponding to the conductive layer 24 are formed also in the area where the sacrificial member 63 has been removed. After that, the excess conductive layer 24 is removed on the side surface and the bottom surface of the slit TR and above the insulating layer 33. At this time, also the conductive material of the conductive layer 24 formed in the area where the sacrificial member 63 has been removed is removed. After that, insulating members 53 are embedded in the areas where the sacrificial members 63 have been removed. Thereby, a structure corresponding to the insulating film 51 is formed.

Next, SLT member embedding is executed like in the first embodiment (step ST114). Specifically, first, an insulating film corresponding to the spacer SP is formed. Then, the insulating film at the bottom of the slit TR corresponding to the member SLT is removed. Then, a conductive member LI is formed such that each slit TR is embedded. After that, the excess conductive member LI is removed above the insulating layer 33.

Next, CC sacrificial member removal is executed (step ST509). Specifically, the sacrificial members 65 in the contact holes CH are selectively removed by, for example, wet etching or the like.

Next, CC conductive member embedding is executed like in the first embodiment (step ST116). That is, conductive members are formed such that the contact holes CH are embedded, and the excess conductive member is removed outside the contact hole CH. Thereby, structures corresponding to the contact plugs CC are formed.

By the processing described above being executed, the structure of the memory cell array 10D described using FIGS. 75 to 77 is completed.

### <5-3> Advantageous Effects of the Fifth Embodiment

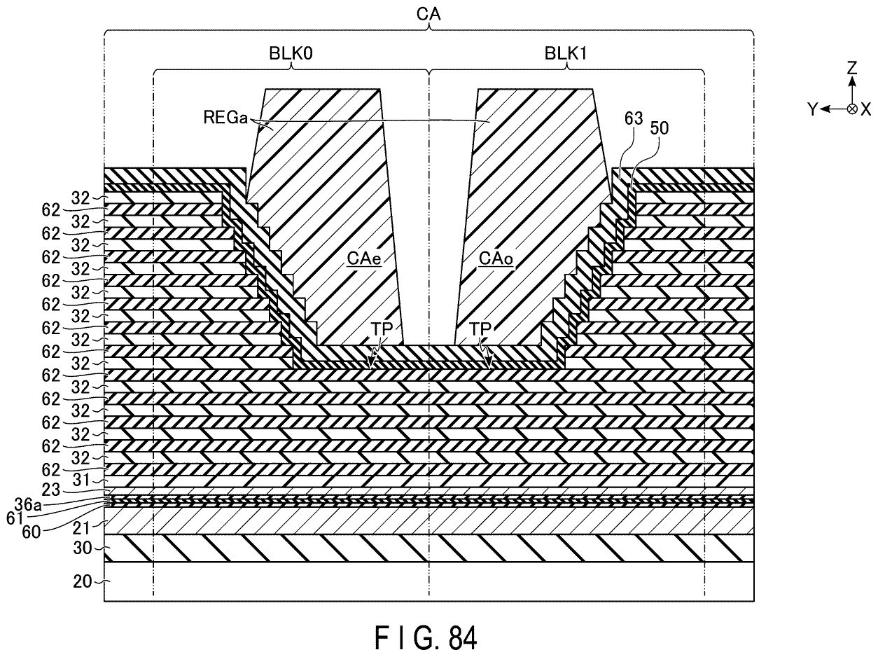

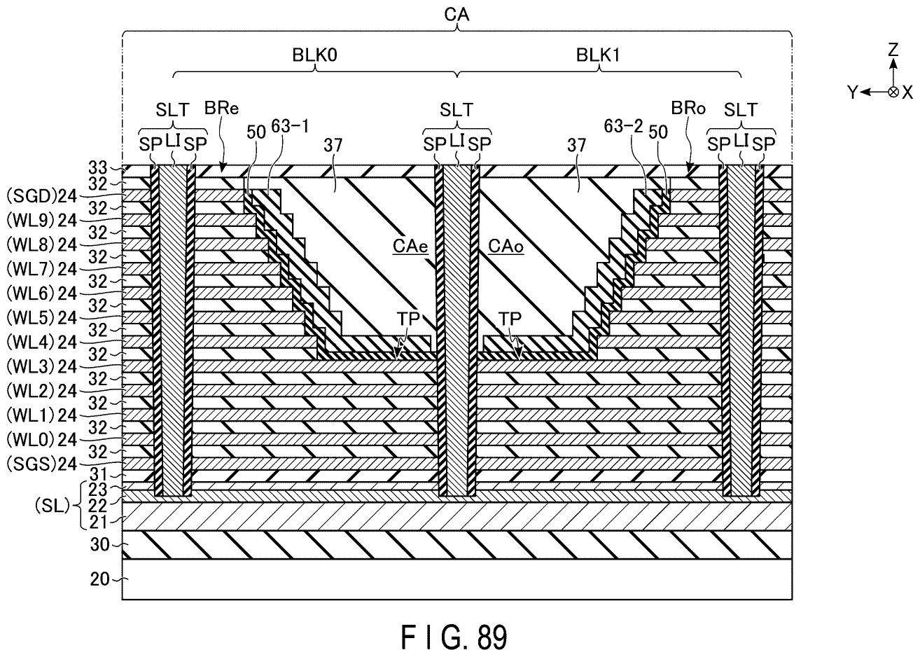

Advantageous effects of the fifth embodiment will now be described using a second comparative example. Unlike the fifth embodiment, the second comparative example has a structure in which a member corresponding to a stopper film in processing of contact holes CH is not in contact with the member SLT, and is designed such that processing of contact holes CH is executed after WL replacement. Each of FIGS. 84, 85, 86, 87, 88, and 89 is a cross-sectional view showing an example of a cross-sectional structure in the manufacturing process of a memory device 1 according to the second comparative example.

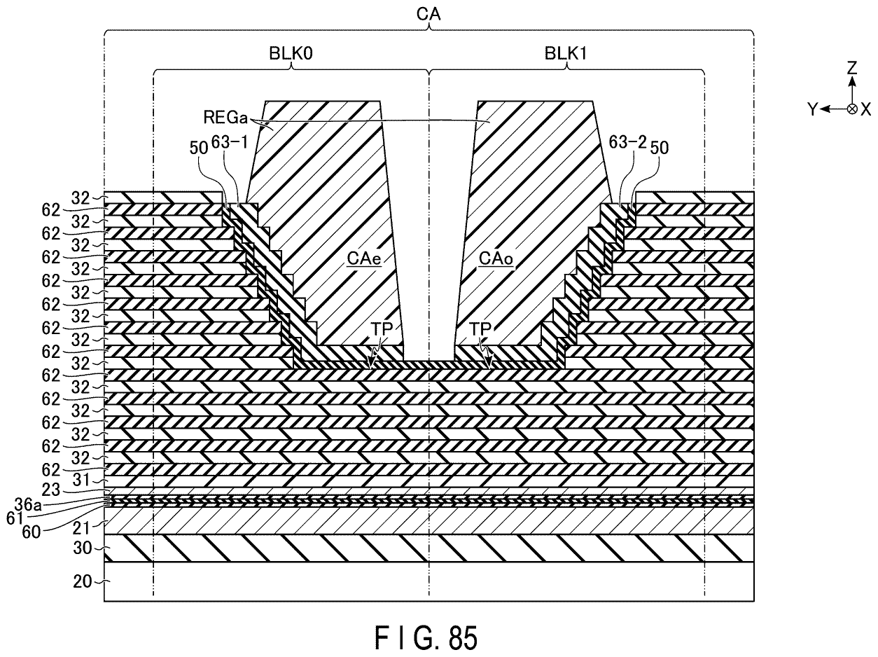

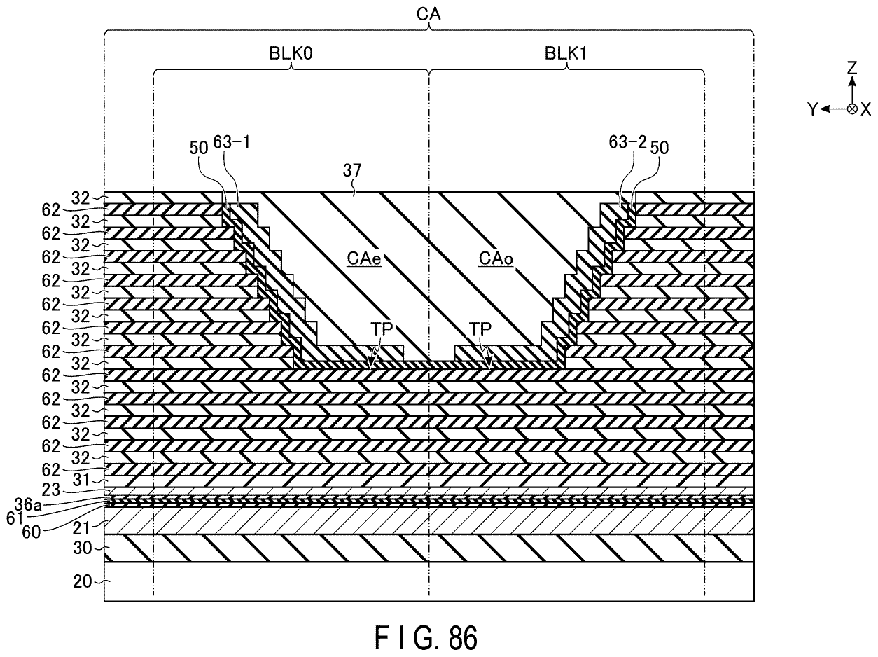

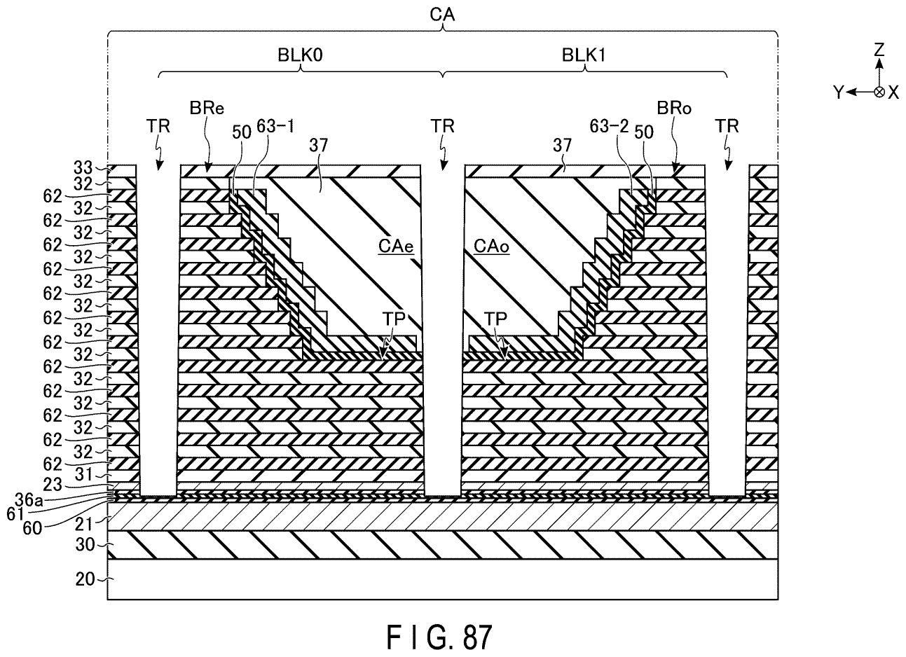

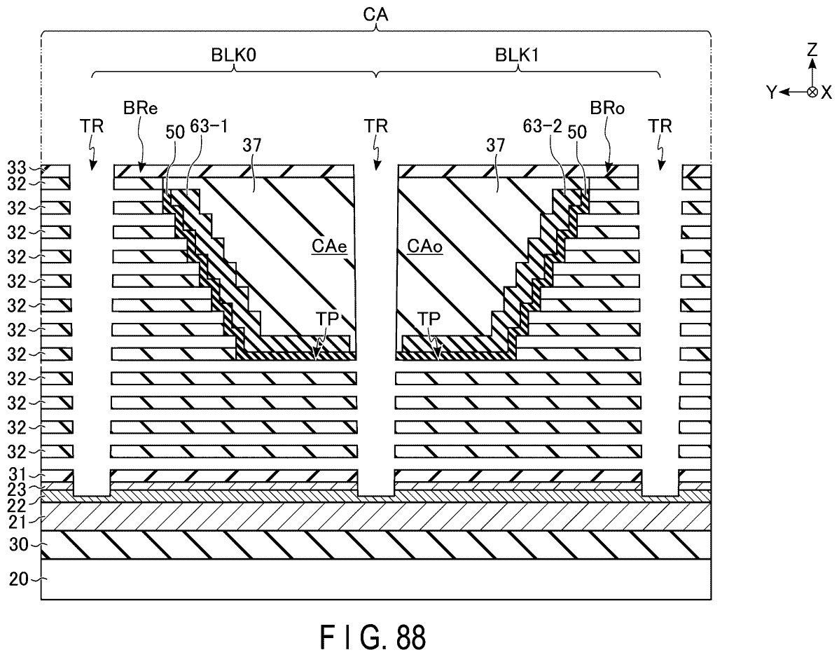

In the second comparative example, in the formation of a stopper portion, first, a resist REGa is formed as shown in FIG. 84. The resist REGa is provided such that the sub-contact areas CAe and CAo are covered and an area in the vicinity of the member SLT between the sub-contact areas CAe and CAo is opened. Then, as shown in FIG. 85, by etching processing, portions of the insulating film 50 and the sacrificial member 63 not covered with the resist REGa are removed, and the sacrificial member 63 between the sub-contact areas CAe and CAo is removed. Thereby, the sacrificial member 63 is divided into a sacrificial member 63-1 in the sub-contact area CAe and a sacrificial member 63-2 in the sub-contact area CAo. After the resist REGa is removed, as shown in FIG. 86, an insulating layer 37 is embedded in the sub-contact areas CAe and CAo. After that, in SLT processing of the second comparative example, as shown in FIG. 87, slits TR are formed not to be in contact with the sacrificial member 63-1 or 63-2. Thus, in the SL replacement and the WL replacement of the second comparative example, as shown in FIG. 88, the sacrificial members 63-1 and 63-2 are not removed but remain in the step of removing the sacrificial members 62. After that, WL replacement and SLT member embedding are executed; then, the structure shown in FIG. 88 is formed. After that, the sacrificial members 63-1 and 63-2 are used as stopper films to execute contact hole processing. Then, a structure corresponding to a contact plug is formed in the contact hole.

In the second comparative example thus designed, in a case where the aspect ratio of a portion of the resist REGa that is opened in the vicinity of the member SLT is increased with increase in the number of stacked wiring lines, the pattern of the resist REGa may fall. Further, the dimensional control of the resist REGa is difficult; to arrange the ends of the sacrificial members 63-1 and 63-2 between the member SLT and the contact plugs CC, a higher level of tapered shape of the dummy staircase structure is required.

In this regard, in the fifth embodiment, the resist REG in processing of the sacrificial member 63 is continuously formed between the adjacent sub-contact areas CAe and CAo. As a result, the sacrificial member 63 is not divided between the adjacent sub-contact areas CAe and CAo. Then, before executing WL replacement, processing of contact holes CH corresponding to the contact plugs CC like that described in step ST107 of the first embodiment is executed using the sacrificial member 63 as a stopper film. Then, after a sacrificial member 65 is embedded in the formed contact hole CH, SLT processing is executed. In the fifth embodiment, the sacrificial member 63 is exposed on the side surface of a slit TR formed by SLT processing. On the other hand, in the fifth embodiment, since the sacrificial member 63 is formed thicker than the sacrificial member 62, after WL replacement is executed, the space where the sacrificial member 63 has been removed is not completely embedded with a conductive member. Thereby, in the fifth embodiment, the conductive member can be removed from the space where the sacrificial member 63 has been removed, and an insulating member 53 can be embedded in this space. As a result, a short circuit between contact plugs CC due to the structure of the stopper portion is avoided.

As described hereinabove, in the memory device 1 according to the fifth embodiment, dimensional control of the resist REGa like that in the second comparative example is not needed in the formation of the resist REG. As a result, the memory device 1 according to the fifth embodiment can reduce the degree of difficulty of processing of the sacrificial member 63, and can improve the yield. Therefore, the memory device 1 according to the fifth embodiment can reduce the manufacturing cost of the memory device 1. Note that the advantageous effects described in the fifth embodiment are similarly obtained in the first to fourth embodiments.

### <5-4> Modification Examples of the Fifth Embodiment

The memory device 1 according to the fifth embodiment can be variously modified. For example, in the memory cell array 10D of the fifth embodiment, the insulating films 50 and 51 may be provided to cover the stacked wiring lines in the memory area MA.

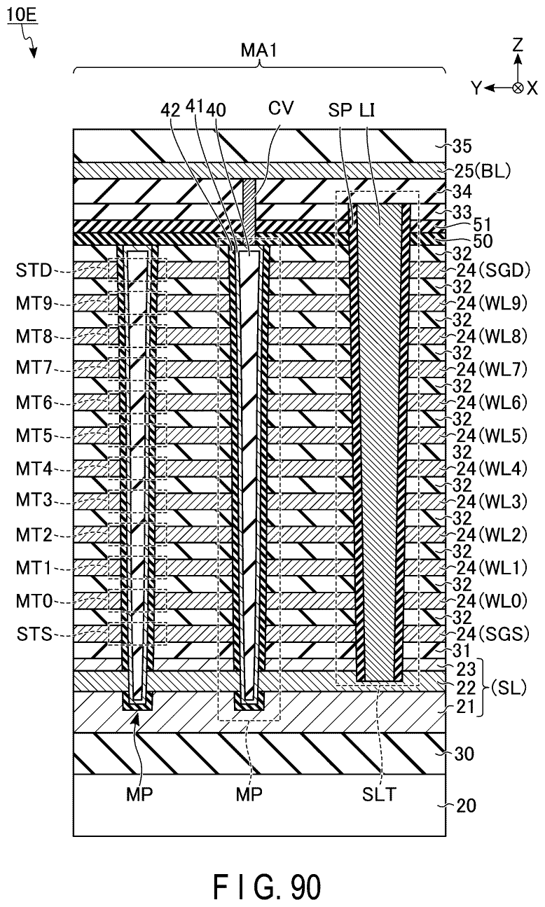

FIG. 90 is a cross-sectional view showing an example of a cross-sectional structure of a memory area MA of a memory cell array 10E included in a memory device 1 according to a modification example of the fifth embodiment. As shown in FIG. 90, in the memory cell array 10E, the insulating films 50 and 51 are, for example, provided between the uppermost insulating layer 32 and the insulating layer 33. In this case, the contact plug CV has a portion provided to penetrate the insulating films 50 and 51. Although illustration is omitted, the insulating films 50 and 51 may be provided to cover the bridge areas BRe and BRO.

### <6> Others

The memory device 1 described hereinabove can be variously modified.

In the above embodiments, each of the circuit configuration, the planar layout, and the cross-sectional structure of the memory device 1 can be changed as appropriate. A plurality of conductive layers 24 functioning as a select gate line SGS or SGD may be provided. The numbers of wiring layers and contact plugs included in the memory device 1 can be changed according to circuit design as appropriate. The XY cross-sectional structure of each of the memory pillar MP, the support pillar HR, and the contact plug CC may be a substantially circular shape or a substantially elliptical shape. Although the above embodiments describe, as an example, a case where the semiconductor film 41 of the memory pillar MP and the source line SL (the semiconductor layer 22) are connected via the side surface of the memory pillar MP, the configuration is not limited thereto. The semiconductor film 41 of the memory pillar MP and the source line SL (the semiconductor layer 22) may be electrically connected via the bottom of the memory pillar MP. The memory device 1 may be a structure in which a chip on which the memory cell array 10 is provided and a chip on which a circuit or the like other than the memory cell array 10 is provided are bonded together.

Although the above embodiments describe a case where each of the lower memory pillar LMP, the middle memory pillar MMP, and the upper memory pillar UMP has a forward tapered shape in which the diameter (XY cross-sectional area) of the upper end is larger than the diameter (XY cross-sectional area) of the lower end, the shape of each sub-pillar of the memory pillar MP is not limited thereto. For example, each sub-pillar may have a straight shape provided to have a substantially fixed diameter, may have a reverse tapered shape in which the diameter (XY cross-sectional area) of the lower end is larger than the diameter (XY cross-sectional area) of the upper end, or may have a bowing shape in which the diameter (XY cross-sectional area) of an intermediate portion in the Z direction is maximized. Similarly to the memory pillar MP, each sub-contact plug of the contact plug CCa may have a straight shape, a reverse tapered shape, or a bowing shape. Further, the shape of the crossing portion CP of the contact plug CCa may be a forward tapered shape in which the diameter (XY cross-sectional area) of the upper end is larger than the diameter (XY cross-sectional area) of the lower end.

Although the above embodiments describe, as an example, a case where staircase shaping of two tiers and three tiers is used, each embodiment can be applied also to staircase shaping of four or more tiers. The memory pillar MP may be a structure of four or more tiers. That is, the memory pillar MP may be processed by four or more divided rounds. The member SLT may be a structure of two or more tiers. That is, the member SLT may be processed by two or more divided rounds. The support pillar HR may be a structure of two or more tiers. That is, the support pillar HR may be processed by two or more divided rounds. The ideas described in the first to fourth embodiments can be applied as long as the contact plug CCa has a structure of a plurality of tiers and staircase shaping of a plurality of tiers is used. The idea described in the fifth embodiment can be applied to any of the first to fourth embodiments.

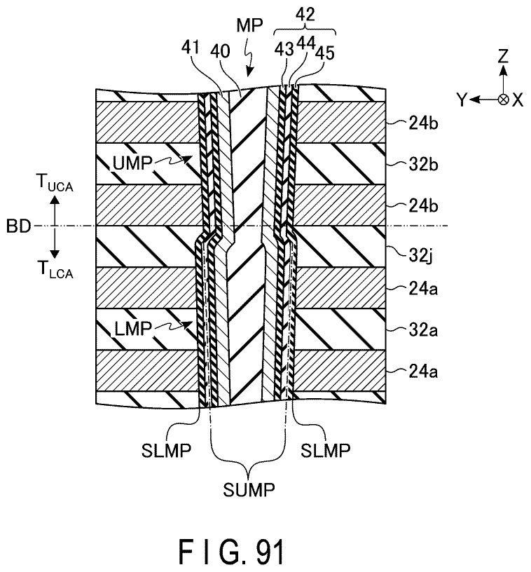

FIG. 91 is a cross-sectional view showing an example of a cross-sectional structure that includes a memory pillar MP and is located in the vicinity of a boundary BD. FIG. 91 extracts and shows the vicinity of the boundary BD between the lower tier T_{LCA} and the upper tier T_{UCA}. As shown in FIG. 91, for example, in the YZ cross section, the upper end of the lower memory pillar LMP may have a rounded shape instead of an angular shape. In this case, it cannot be said that the XY cross-sectional area of the upper end of the lower memory pillar LMP is clearly larger than the XY cross-sectional area of the lower end of the upper memory pillar UMP. However, the shape of the side surface of the memory pillar MP is discontinuous in a boundary portion between the lower memory pillar LMP and the upper memory pillar UMP. Specifically, for example, in the YZ cross section, the side surface SLMP of the lower memory pillar LMP deviates from the extension line of the side surface SUMP of the upper memory pillar UMP indicated by the one-dot chain line in FIG. 91. The misalignment of the two side surfaces SLMP and SUMP may occur for any cross-section including the Z direction, such as an XZ cross-section. In the present specification, the boundary portion of the memory pillar MP in two tiers adjacent in the Z direction can be specified based on a discontinuous portion in the shape of the side surface of the memory pillar MP. The memory pillar MP may have a structure in which three or more sub-pillars each provided to extend along the Z direction are coupled. Also in such a case, the memory pillar MP can have a structure like that shown in FIG. 91 in a boundary portion between adjacent tiers. For the support pillar HR, the contact plug CC, and the member SLT, similarly to the memory pillar MP, boundary portions in two tiers adjacent in the Z direction can be specified.

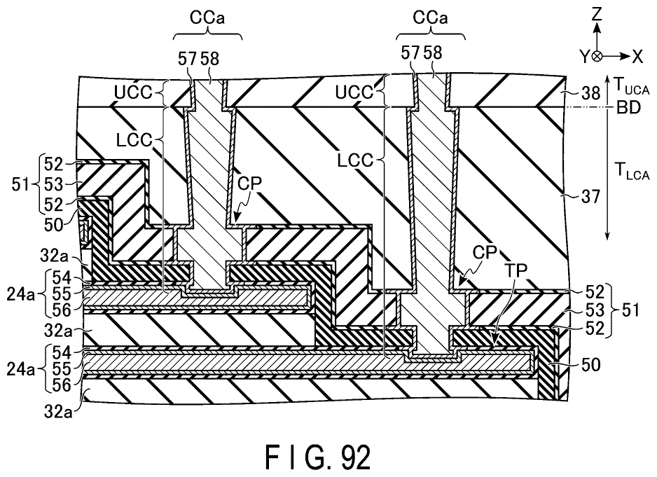

FIG. 92 is a cross-sectional view showing an example of a cross-sectional structure that includes contact plugs CCa and is located in the vicinity of a boundary BD. FIG. 92 extracts and shows the vicinity of the boundary BD between the lower tier T_{LCA} and the upper tier T_{UCA}. As shown in FIG. 92, the joint portion JT may be omitted from the contact plug CCa. In this case, the diameter (XY cross-sectional area) of the upper end of the lower contact plug LCC is larger than the diameter (XY cross-sectional area) of the lower end of the upper contact plug UCC. Also in a case where the joint portion JT is not formed, by the diameter of the upper end of the lower contact plug LCC being designed large, the degree of difficulty of superimposition of the lower contact plug LCC and the upper contact plug UCC can be reduced. In a case where the contact plug CCa has a structure of two or more tiers and does not have the joint portion JT, a boundary portion of the contact plug CCa between two tiers adjacent in the Z direction can be specified based on a discontinuous portion of the shape of the side surface, like in the memory pillar MP.

The manufacturing processes described in the above embodiments are merely examples. As long as a similar structure to the memory device 1 described in the above embodiments can be formed, the order of processing may be changed. For example, the order of processing and member embedding of the lower memory pillar LMP, and processing and member embedding of the lower contact plug LCC may be changed. Although a step of manufacturing support pillars HR is omitted in the manufacturing processes described in the above embodiments, a step of forming holes for forming support pillars HR may be combined with another step. For example, a step of forming holes for forming support pillars HR may be integrated with a step of forming holes for forming memory pillars MP.

In the present specification, the “high dielectric film” is referred to also as a High-k (a high dielectric constant film). The high dielectric film has a higher dielectric constant than a silicon oxide. The high dielectric film can achieve insulating properties substantially equal to those of a silicon oxide with a film thickness smaller than that of the silicon oxide. As each of the high dielectric films 52 and 54, a hafnium (Hf)-based oxide or a zirconium (Zr)-based oxide may be used. The “barrier metal” may be referred to as a “barrier film” or a “metal film”.

In the present specification, “connection” refers to being electrically connected, and does not exclude, for example, being connected via another element. “Electrically connected” may be connection via an insulator as long as operations similar to those in a case of being electrically connected can be performed. The “area” may be regarded as a configuration included by a substrate. For example, in a case where it is provided that a substrate 20 (a semiconductor substrate) includes a memory area MA and a contact area CA, the memory area MA and the contact area CA are associated with different areas above the substrate 20. The “height” corresponds to, for example, the distance in the Z direction between a configuration of a measurement object and the substrate 20. As a reference of “height”, a configuration other than the substrate 20 may be used. The “top (planar) view” corresponds to, for example, viewing the surface of the substrate 20 from the vertical direction of the substrate 20. The “diameter” refers to the inner diameter of a hole or the outer diameter of a pillar in a cross section (an XY cross section) parallel to the surface of the substrate 20. The “thickness” corresponds to, for example, the thickness along the Z direction of a measurement object.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device, comprising:
a plurality of conductive layers provided in a first area and a second area arranged in a first direction, the conductive layers being apart from each other in a second direction intersecting the first direction, the conductive layers being arranged over a plurality of tiers including a first tier and a second tier above the first tier, each of the conductive layers having a terrace portion that does not overlap a conductive layer arranged in an upper layer in a same tier among the conductive layers in the second area, each of the conductive layers including a first high dielectric film;
a memory pillar provided to pass through the conductive layers in the second direction in the first area, in which a portion where the memory pillar and one of the conductive layers intersect each other functions as a memory cell;
an insulating film, an upper surface of the insulating film having step differences along a staircase shape formed by terrace portions of a plurality of first conductive layers included in the first tier among the conductive layers, the insulating film being provided thicker than each of the first conductive layers, the insulating film including a second high dielectric film that is a same in material as the first high dielectric film; and
a plurality of contact plugs respectively connected to the terrace portions included in the conductive layers in the second area, wherein
the contact plugs include a plurality of first contact plugs respectively connected to the first conductive layers, and
each of the first contact plugs includes a first sub-contact plug and a second sub-contact plug, the first sub-contact plug having a portion that passes through the first tier including the insulating film in the first tier, the second sub-contact plug having a portion that passes through the second tier.

2. The memory device according to claim 1, wherein
film thicknesses of the first high dielectric film and the second high dielectric film are substantially equal.

3. The memory device according to claim 1, wherein
the insulating film further includes a first insulating member having a portion surrounded by the second high dielectric film, and
the first sub-contact plug has a portion sandwiching the first insulating member in the second direction in a crossing portion with the insulating film.

4. The memory device according to claim 1, wherein
the first sub-contact plug has a portion provided to extend along the first direction with substantially a same thickness as the first high dielectric film in a connection portion with a corresponding first conductive layer among the first conductive layers.

5. The memory device according to claim 1, wherein
each of the conductive layers further includes a metal film provided on an inside of the first high dielectric film and a conductive member that is provided on an inside of the metal film and that is different from the metal film, and
the conductive member contains tungsten.

6. The memory device according to claim 1, wherein
each of the conductive layers further includes a conductive member provided on an inside of the first high dielectric film, and
the conductive member contains molybdenum.

7. The memory device according to claim 1, wherein
the insulating film further includes a first insulating member having a portion surrounded by the second high dielectric film, and
in cross sections along a direction orthogonal to the second direction, a cross-sectional area of a crossing portion of the first sub-contact plug with the first insulating member is larger than a cross-sectional area of a portion of the first sub-contact plug between the crossing portion and a first conductive layer connected to the first sub-contact plug among the first conductive layers.

8. The memory device according to claim 1, wherein
the insulating film further includes a first insulating member having a portion surrounded by the second high dielectric film, and
in cross sections along a direction orthogonal to the second direction, a cross-sectional area of a crossing portion of the first sub-contact plug with the first insulating member is substantially equal to a cross-sectional area of a portion of the first sub-contact plug between the crossing portion and a first conductive layer connected to the first sub-contact plug among the first conductive layers.

9. The memory device according to claim 1, further comprising:
a second insulating member provided between the first sub-contact plug and the second high dielectric film.

10. The memory device according to claim 1, wherein
a side surface shape of each of the first contact plugs is discontinuous in a boundary portion between the first tier and the second tier.

11. The memory device according to claim 10, wherein
the tiers further include a third tier above the second tier,
the conductive layers further include a plurality of second conductive layers included in the second tier and a plurality of third conductive layers included in the third tier,
the contact plugs further include a plurality of second contact plugs respectively connected to the second conductive layers, each of the second contact plugs having a portion that passes through the second tier and the third tier,
the second sub-contact plug of each of the first contact plugs further has a portion that passes through the third tier, and
in a boundary portion between the second tier and the third tier, a side surface shape of each of the second contact plugs is continuous and a side surface shape of the second sub-contact plug is continuous.

12. The memory device according to claim 1, wherein
in cross sections along a direction orthogonal to the second direction, a cross-sectional area of an end portion of the first sub-contact plug on a side of a boundary portion between the first tier and the second tier is larger than a cross-sectional area of an end portion of the second sub-contact plug on the side of the boundary portion.

13. A memory device, comprising:
a plurality of conductive layers provided in a first area and a second area arranged in a first direction, the conductive layers being apart from each other in a second direction intersecting the first direction, the conductive layers being arranged over a plurality of tiers including a first tier and a second tier above the first tier, each of the conductive layers having a terrace portion that does not overlap a conductive layer arranged in an upper layer in a same tier among the conductive layers in the second area, the conductive layers including a plurality of first conductive layers and at least one intermediate conductive layer, the first conductive layers and the at least one intermediate conductive layer being included in the first tier, the at least one intermediate conductive layer being arranged nearer to a boundary portion between the first tier and the second tier than the first conductive layers;
a memory pillar provided to pass through the conductive layers in the second direction in the first area, in which a portion where the memory pillar and one of the conductive layers intersect each other functions as a memory cell;
an insulating film, an upper surface of the insulating film being provided to have step differences along a staircase shape formed by terrace portions of the first conductive layers; and
a plurality of contact plugs respectively connected to the terrace portions included in the conductive layers in the second area, wherein
the contact plugs include a plurality of first contact plugs respectively connected to the first conductive layers, and at least one second contact plug respectively connected to the at least one intermediate conductive layer,
each of the first contact plugs includes a first sub-contact plug and a second sub-contact plug, the first sub-contact plug having a portion that passes through the first tier including the insulating film in the first tier, the second sub-contact plug having a portion that passes through the second tier, and
each of the at least one second contact plug has a portion that passes through the first tier and the second tier, the second contact plug being provided apart from the insulating film.

14. The memory device according to claim 13, wherein
in a boundary portion between the first tier and the second tier, a side surface shape of each of the first contact plugs is discontinuous, and a side surface shape of the at least one second contact plug is continuous.

15. The memory device according to claim 13, further comprising:
a first insulating layer provided to fill step differences formed by the terrace portions of the first conductive layers and the terrace portion of the at least one intermediate conductive layer, the first insulating layer being different in material from the insulating film.

16. The memory device according to claim 15, further comprising:
a second insulating layer provided to fill step differences formed by the terrace portions of a plurality of second conductive layers included in the second tier among the conductive layers, wherein
an insulating film that is different in material from the second insulating layer is not provided between the terrace portions of the second conductive layers and the second insulating layer.

17. A memory device, comprising:
a plurality of conductive layers provided in a first area and a second area arranged in a first direction, the conductive layers being apart from each other in a second direction crossing the first direction, each of the conductive layers having a terrace portion that does not overlap a conductive layer arranged in an upper layer among the conductive layers in the second area, each of the conductive layers including a first high dielectric film;
a memory pillar provided to pass through the conductive layers in the second direction in the first area, in which a portion where the memory pillar and one of the conductive layers intersect each other functions as a memory cell;
an insulating film, an upper surface of the insulating film having step differences along a staircase shape formed by terrace portions of the conductive layers, the insulating film being provided thicker than each of the conductive layers, the insulating film including a second high dielectric film that is a same in material as the first high dielectric film; and
a plurality of contact plugs that pass through the insulating film in the second area, the plurality of contact plugs being connected to the terrace portions included in the conductive layers, respectively.

18. The memory device according to claim 17, wherein
film thicknesses of the first high dielectric film and the second high dielectric film are substantially equal.

19. The memory device according to claim 17, wherein
the insulating film further includes a first insulating member having a portion surrounded by the second high dielectric film, and
each of the contact plugs passing through the insulating film has a portion sandwiching the first insulating member in the second direction in a crossing portion with the insulating film.

20. The memory device according to claim 17, wherein
each of the contact plugs passing through the insulating film has a portion provided to extend along the first direction with substantially a same thickness as the first high dielectric film in a connection portion with a corresponding conductive layer among the conductive layers.
